(19) United States
(12) Patent Application Publication
(10) Pub. No.: US 2026/0321211 A1
(43) Pub. Date: Oct. 15, 2026

(54) Display Substrate and Display Apparatus

(71) Applicants: Beijing BOE Technology Development Co., Ltd., Beijing (CN); BOE Technology Group Co., Ltd., Beijing (CN)

(72) Inventors: Miao LIU, Beijing (CN); Xuehuan FENG, Beijing (CN); Jingquan WANG, Beijing (CN); Jingbo XU, Beijing (CN); Xing YAO, Beijing (CN)

(21) Appl. No.: 18/845,890

(22) PCT Filed: Nov. 24, 2023
(86) PCT No.: PCT/CN2023/134124

§ 371 Date: Sep. 11, 2024

(51) Int. Cl. G09G 3/3266; G09G 3/3233; H10K 59/131

(52) U.S. Cl. CPC G09G 3/3266; G09G 3/3233; H10K 59/131; G09G 2300/0426; G09G 2300/0452; G09G 2300/0842; G09G 2310/0286

(57) ABSTRACT

A display substrate and a display apparatus, the display substrate includes: a first area and a second area provided with a gate drive circuit, the gate drive circuit includes: multiple shift registers, at least one stage of shift register includes: a pre-circuit and a drive output circuit, the drive output circuit includes: N drive output sub-circuits, an n-th drive output sub-circuit is electrically connected to an n-th drive signal output terminal, in at least one display frame, start time of a drive signal output from an N-th drive signal output terminal is later than start time of a drive signal output from at least one of a first drive signal output terminal to an (N−1)-th drive signal output terminal, and an area of an N-th drive output sub-circuit is larger than an area of at least one of a first drive output sub-circuit to an (N−1)-th drive output sub-circuit.

### CROSS-REFERENCE TO RELATED APPLICATION

The present application is a U.S. National Phase Entry of International Application PCT/CN 2023/134124 having an international filing date of Nov. 24, 2023, and entitled “Display Substrate and Display Apparatus”, the contents of which should be interpreted as being incorporated herein by reference.

### TECHNICAL FIELD

The present disclosure relates to, but is not limited to, the field of display technologies, and more particularly, to a display substrate and a display apparatus.

### BACKGROUND

An Organic Light Emitting Diode (OLED for short) and a Quantum dot Light Emitting Diode (QLED for short) are active light emitting display devices and have advantages such as self-luminescence, wide viewing angle, high contrast ratio, low power consumption, very high response speed, lightness and thinness, flexibility, and low cost. With constant development of display technologies, a flexible display apparatus (Flexible Display) in which an OLED or a QLED is used as a light emitting device and signal control is performed through a Thin Film Transistor (TFT for short) has become a mainstream product in the field of display at present.

### SUMMARY

The following is a summary of subject matter described in the present disclosure in detail. This summary is not intended to limit the protection scope of claims.

In a first aspect, the present disclosure provides a display substrate, including: a first region and a second region, wherein the first region is provided with pixel drive circuits arranged in an array, the second region is provided with a gate drive circuit configured to provide a drive signal to the pixel drive circuits, the gate drive circuit includes: a plurality of shift registers, at least one stage of shift register includes: a pre-circuit and a drive output circuit, the pre-circuit is electrically connected to a signal input terminal, a reset signal terminal and a cascaded output signal terminal respectively, the drive output circuit is electrically connected to N drive signal output terminals respectively, a signal input terminal of at least one stage of shift register is electrically connected to a cascaded output signal terminal of at least one stage of shift register, a reset signal terminal of at least one stage of shift register is electrically connected to a cascaded output signal terminal of at least one stage of shift register,
the drive output circuit includes: N drive output sub-circuits, an n-th drive output sub-circuit is electrically connected to an n-th drive signal output terminal, in at least one display frame, a start time of a drive signal output from an n-th drive signal output terminal is later than a start time of a drive signal output from at least one of a first drive signal output terminal to an (n−1)-th drive signal output terminal, N>2, 1≤n≤N; and
an area of an N-th drive output sub-circuit is larger than an area of at least one of a first drive output sub-circuit to an (N−1)-th drive output sub-circuit.

In an exemplary implementation, the display substrate includes: a base substrate and a drive structure layer arranged on the base substrate, the gate drive circuit and the pixel drive circuits are located on the drive structure layer, the drive structure layer includes: a semiconductor layer, a first conductive layer and a second conductive layer stacked sequentially on the base substrate, at least one drive output sub-circuit includes: an output transistor, a noise reduction transistor and an output capacitor, a transistor includes: an active pattern, a gate electrode, a first electrode and a second electrode, and the output capacitor includes: a first plate and a second plate;
the semiconductor layer at least includes: an active pattern of an output transistor and an active pattern of a noise reduction transistor located on at least one drive output sub-circuit;
the first conductive layer at least includes: a second plate of an output capacitor located on at least one drive output sub-circuit; and
the second conductive layer at least includes: a first plate of an output capacitor, a gate electrode, a first electrode and a second electrode of an output transistor, and a gate electrode, a first electrode and a second electrode of a noise reduction transistor located on at least one drive output sub-circuit.

In an exemplary implementation, an area of an output transistor in the N-th drive output sub-circuit is larger than an area of an output transistor in at least one of the first drive output sub-circuit to an (N−1)-th drive output sub-circuit, and an area of an output capacitor in the N-th drive output sub-circuit is equal to an area of an output capacitor in at least one of the first drive output sub-circuit to the (N−1)-th drive output sub-circuit.

In an exemplary implementation, a width-to-length ratio of a channel region of an active pattern of the output transistor in the N-th drive output sub-circuit is greater than a width-to-length ratio of a channel region of an active pattern of an output transistor in at least one of the first drive output sub-circuit to the (N−1)-th drive output sub-circuit.

In an exemplary implementation, a width-to-length ratio of a channel region of an active pattern of an output transistor in the first drive output sub-circuit is greater than a width-to-length ratio of a channel region of an active pattern of an output transistor in at least one of a second drive output sub-circuit to the (N−1)-th drive output sub-circuit.

In an exemplary implementation, width-to-length ratios of channel regions of active patterns of output transistors in at least two of the second drive output sub-circuit to the (N−1)-th drive output sub-circuit are equal.

In an exemplary implementation, the area of the output capacitor in the N-th drive output sub-circuit is larger than the area of the output capacitor in at least one of the first drive output sub-circuit to the (N−1)-th drive output sub-circuit, and the area of the output transistor in the N-th drive output sub-circuit is equal to the area of the output transistor in at least one of the first drive output sub-circuit to the (N−1)-th drive output sub-circuit.

In an exemplary implementation, in at least one drive output sub-circuit, at least a portion of the gate electrode of the output transistor is of an annular structure, at least a portion of the first electrode of the output transistor is of an annular structure, the gate electrode of the output transistor surrounds the first electrode of the output transistor, and the second electrode of the output transistor surrounds at least one side of the gate electrode of the output transistor.

In an exemplary implementation, in at least one drive output sub-circuit, the output capacitor is located on a side of the output transistor close to a second centerline, the noise reduction transistor is located on a side of the output transistor close to a first centerline, the first centerline is a centerline of an area occupied by the drive output circuit extending in a first direction, and the second centerline is a centerline of the area occupied by the drive output circuit extending in a second direction.

In an exemplary implementation, N=4, an output device in the first drive output sub-circuit is arranged symmetrically with an output device in the second drive output sub-circuit with respect to the second centerline, the output device in the second drive output sub-circuit is arranged symmetrically with an output device in a third drive output sub-circuit with respect to the first centerline, an output capacitor in a fourth drive output sub-circuit is arranged symmetrically with an output capacitor in the third drive output sub-circuit with respect to the second centerline, at least a portion of an output transistor in the fourth drive output sub-circuit is arranged symmetrically with an output transistor in the third drive output sub-circuit with respect to the second centerline, the output capacitor in the fourth drive output sub-circuit is arranged symmetrically with an output capacitor in the first drive output sub-circuit with respect to the first centerline, at least a portion of the output transistor in the fourth drive output sub-circuit is arranged symmetrically with the output transistor in the first drive output sub-circuit with respect to the first centerline, the output device includes: an output transistor and an output capacitor, the first centerline is a centerline of an area occupied by the drive output circuit extending in a first direction, and the second centerline is a centerline of the area occupied by the drive output circuit extending in a second direction;
a noise reduction transistor of the first drive output sub-circuit and a noise reduction transistor of the second drive output sub-circuit are located on a side of the output device of the first drive output sub-circuit close to the first centerline, the noise reduction transistor of the second drive output sub-circuit is located on a side of the noise reduction transistor of the first drive output sub-circuit close to the first centerline, a noise reduction transistor of the third drive output sub-circuit and a noise reduction transistor of the fourth drive output sub-circuit are located on a side of the output device of the third drive output sub-circuit close to the first centerline, and the noise reduction transistor of the third drive output sub-circuit is located on a side of the noise reduction transistor of the fourth drive output sub-circuit close to the first centerline; and
the noise reduction transistor of the first drive output sub-circuit is arranged asymmetrically with the noise reduction transistor of the fourth drive output sub-circuit with respect to the first centerline, and the noise reduction transistor of the second drive output sub-circuit is arranged asymmetrically with the noise reduction transistor of the third drive output sub-circuit with respect to the first centerline.

In an exemplary implementation, a region where the drive output circuit is located is divided into a first region and a second region by the second centerline;
the output device of the first drive output sub-circuit and the output device of the fourth drive output sub-circuit are located in the first region, and the output device of the second drive output sub-circuit and the output device of the third drive output sub-circuit are located in the second region;
the noise reduction transistor of at least one of the first drive output sub-circuit to the fourth drive output sub-circuit is located in the first region and the second region, and an area of the noise reduction transistor in the first region is smaller than an area of the noise reduction transistor in the second region; and
areas of the noise reduction transistors of the first drive output sub-circuit and the second drive output sub-circuit in the first region are larger than areas of the noise reduction transistors of the third drive output sub-circuit and the fourth drive output sub-circuit in the first region, and areas of the noise reduction transistors of the first drive output sub-circuit and the second drive output sub-circuit in the second region are smaller than areas of the noise reduction transistors of the third drive output sub-circuit and the fourth drive output sub-circuit in the second region.

In an exemplary implementation, the active pattern of the output transistor of the fourth drive output sub-circuit includes: at least one first active pattern and at least one second active pattern, wherein a length of a first active pattern in the second direction is greater than a length of a second active pattern in the second direction;
the first active pattern includes: a first active portion and a second active portion, the first active portion and the second active pattern are equal in length in the first direction, and the second active portion is located on a side of the first active portion close to the first centerline; and
the first active portion and the second active pattern of the active pattern of the output transistor of the fourth drive output sub-circuit are arranged symmetrically with at least a portion of the active pattern of the output transistor of the first drive output sub-circuit with respect to the first centerline, and the first active portion and the second active pattern of the active pattern of the output transistor of the fourth drive output sub-circuit are arranged symmetrically with at least a portion of the active pattern of the output transistor of the third drive output sub-circuit with respect to the second centerline.

In an exemplary implementation, the first electrode of the output transistor of the fourth drive output sub-circuit includes: a first electrode portion and a second electrode portion arranged at intervals;
the first electrode portion of the output transistor of the fourth drive output sub-circuit is arranged symmetrically with the first electrode of the output transistor of the first drive output sub-circuit with respect to the first centerline, and the first electrode portion of the output transistor of the fourth drive output sub-circuit is arranged symmetrically with the first electrode of the output transistor of the third drive output sub-circuit;
the first electrode portion and the second electrode portion include: a closed loop structure, an orthographic projection of the first electrode portion on the base substrate at least partially overlaps with orthographic projections of the first active portion and the second active pattern on the base substrate, and an orthographic projection of the second electrode portion on the base substrate at least partially overlaps with an orthographic projection of the second active portion on the base substrate; and
an area of the first electrode portion is larger than an area of the second electrode portion.

In an exemplary implementation, the gate electrode of the output transistor of the fourth drive output sub-circuit includes: a first gate electrode portion and a second gate electrode portion connected to each other;
the first gate electrode portion of the gate electrode of the output transistor of the fourth drive output sub-circuit is arranged symmetrically with the gate electrode of the output transistor of the first drive output sub-circuit with respect to the first centerline, and the first gate electrode portion of the gate electrode of the output transistor of the fourth drive output sub-circuit is arranged symmetrically with the gate electrode of the output transistor of the third drive output sub-circuit with respect to the second centerline;
the first gate electrode portion and the second gate electrode portion include: a closed loop structure, an orthographic projection of the first gate electrode portion on the base substrate at least partially overlaps with orthographic projections of the first active portion and the second active pattern on the base substrate, and an orthographic projection of the second gate electrode portion on the base substrate at least partially overlaps with an orthographic projection of the second active portion on the base substrate; and the first gate electrode portion surrounds the first electrode portion, and the second gate electrode portion surrounds the second electrode portion; and
an area of the first gate electrode portion is larger than an area of the second gate electrode portion.

In an exemplary implementation, a virtual straight line extending in the first direction through the noise reduction transistor of the fourth drive output sub-circuit passes through the output transistor of the fourth drive output sub-circuit.

In an exemplary implementation, the second region further includes: output connection lines, the output connection lines include: a first output connection line to a fourth output connection line; the first drive output sub-circuit is connected to the first output connection line, the second drive output sub-circuit is connected to the second output connection line, the third drive output sub-circuit is connected to the third output connection line, and the fourth drive output sub-circuit is connected to the fourth output connection line;
the first output connection line and the second output connection line are located between the output transistor of the first drive output sub-circuit and the noise reduction transistor of the first drive output sub-circuit, and the third output connection line and the fourth output connection line are located between the output transistor of the fourth drive output sub-circuit and the noise reduction transistor of the fourth drive output sub-circuit; and
the first output connection line and the second output connection line extend in the first direction, the third output connection line and the fourth output connection line are in a shape of a bend line and at least partially extend in the first direction, and the output connection lines are located on the second conductive layer.

In an exemplary implementation, at least one of the third output connection line and the fourth output connection line includes: a first output connection portion, a second output connection portion and a third output connection portion; the first output connection portion and the third output connection portion extend in the first direction, the second output connection portion extends in the second direction, and the second output connection portion is electrically connected to the first output connection portion and the third output connection portion respectively.

In an exemplary implementation, N=4, the first drive output sub-circuit to the third drive output sub-circuit include: one output capacitor, and the fourth drive output sub-circuit includes: two output capacitors;
the output device in the first drive output sub-circuit is arranged symmetrically with the output device in the second drive output sub-circuit with respect to the second centerline, the output device in the second drive output sub-circuit is arranged symmetrically the output device in the third drive output sub-circuit with respect to the first centerline, the output device in the fourth drive output sub-circuit is arranged symmetrically with the output device in the third drive output sub-circuit with respect to the second centerline, the output device in the fourth drive output sub-circuit is arranged symmetrically with the output device in the first drive output sub-circuit with respect to the first centerline, the output devices in the first drive output sub-circuit to the third drive output sub-circuit include: output transistors and output capacitors, the output device in the fourth drive output sub-circuit includes: an output transistor and one of the output capacitors, the first centerline is a centerline of an area occupied by the drive output circuit extending in the first direction, and the second centerline is a centerline of the area occupied by the drive output circuit extending in the second direction;
the noise reduction transistor of the first drive output sub-circuit and the noise reduction transistor of the second drive output sub-circuit are located on a side of the output device of the first drive output sub-circuit close to the first centerline, the noise reduction transistor of the second drive output sub-circuit is located on a side of the noise reduction transistor of the first drive output sub-circuit close to the first centerline, the noise reduction transistor of the third drive output sub-circuit and the noise reduction transistor of the fourth drive output sub-circuit are located on a side of the output device of the third drive output sub-circuit close to the first centerline, the noise reduction transistor of the third drive output sub-circuit is located on a side of the noise reduction transistor of the fourth drive output sub-circuit close to the first centerline, and the other output capacitor of the fourth drive output sub-circuit is located on a side of the output device of the fourth drive output sub-circuit close to the first centerline; and
the noise reduction transistor of the first drive output sub-circuit is arranged symmetrically with the noise reduction transistor of the fourth drive output sub-circuit with respect to the first centerline, and the noise reduction transistor of the second drive output sub-circuit is arranged symmetrically with the noise reduction transistor of the third drive output sub-circuit with respect to the first centerline.

In an exemplary implementation, a region where the drive output circuit is located is divided into a first region and a second region by the second centerline;
the output device of the first drive output sub-circuit and the output device and the other output capacitor of the fourth drive output sub-circuit are located in the first region, and the output device of the second drive output sub-circuit and the output device of the third drive output sub-circuit are located in the second region; and
the noise reduction transistor of at least one of the first drive output sub-circuit to the fourth drive output sub-circuit is located in the first region and the second region, and an area of the noise reduction transistor in the first region is smaller than an area of the noise reduction transistor in the second region.

In an exemplary implementation, the area of the noise reduction transistor in the second region is within a range of 1 to 3 times the area of the noise reduction transistor in the first region.

In an exemplary implementation, the second region further includes: output connection lines, the output connection lines include: a first output connection line to a fourth output connection line; the first drive output sub-circuit is connected to the first output connection line, the second drive output sub-circuit is connected to the second output connection line, the third drive output sub-circuit is connected to the third output connection line, and the fourth drive output sub-circuit is connected to the fourth output connection line;
the output connection lines extend in the first direction, the first output connection line and the second output connection line are located between the output device of the first drive output sub-circuit and the noise reduction transistor of the first drive output sub-circuit, the third output connection line and the fourth output connection line are located between the output device of the fourth drive output sub-circuit and the noise reduction transistor of the fourth drive output sub-circuit, and the other output capacitor and the noise reduction transistor of the fourth drive output sub-circuit are located on a same side of the third output connection line and the fourth output connection line; and
the first output connection line and the second output connection line are located on the second conductive layer.

In an exemplary implementation, at least one of the third output connection line and the fourth output connection line includes: a first output connection portion, a second output connection portion and a third output connection portion; the first output connection portion, the second output connection portion and the third output connection portion extend in the first direction, and the second output connection portion is electrically connected to the first output connection portion and the third output connection portion respectively; and
the first output connection portion and the third output connection portion are located on the second conductive layer, and the second output connection portion is located on the first conductive layer.

In an exemplary implementation, the first region is provided with at least one first signal line and at least one second signal line, the pixel drive circuit is electrically connected to the at least one first signal line and the at least one second signal line, the at least one first signal line at least partially extends in the first direction, and the at least one second signal line at least partially extends in the second direction;
the first signal line at least includes: a scan signal line, the second signal line at least includes: a first power supply line, a sensing signal line and a data signal line, and at least one drive output sub-circuit in the shift register is electrically connected to the at least one first signal line; and
the at least one first signal line is located on the first conductive layer, and the at least one second signal line is located on the second conductive layer.

In an exemplary implementation, the at least one first signal line includes: a plurality of signal connection lines and a plurality of signal overlapping lines; the plurality of signal connection lines and the plurality of signal overlapping lines are arranged alternately in the first direction;
the signal connection lines are arranged in the first direction, and an orthographic projection of a signal overlapping line on the base substrate at least partially overlaps with an orthographic projection of at least one second signal line on the base substrate; and
a line width of a signal connection line of a first signal line connected to at least one of the first drive output sub-circuit to the (N−1)-th drive output sub-circuit in at least one stage of shift register is smaller than a line width of a signal connection line of a first signal line connected to the N-th drive output sub-circuit.

In an exemplary implementation, for at least one stage of shift register, the line width of the signal connection line of the first signal line connected to the N-th drive output sub-circuit is within a range of 1.5 to 2 times the line width of the signal connection line of the first signal line connected to at least one of the first drive output sub-circuit to the (N−1)-th drive output sub-circuit.

In an exemplary implementation, for at least one stage of shift register, the signal overlapping lines of the first signal line connected to the first drive output sub-circuit to the N-th drive output sub-circuit are of an annular structure; and
for at least one first signal line, a length of a signal overlapping line in the first direction is greater than a line width of the at least one second signal line, and the length of the signal overlapping line in the second direction is greater than the line width of the signal connection line.

In an exemplary implementation, for at least one stage of shift register, signal overlapping lines of the first signal line connected to at least one of the first drive output sub-circuit to the (N−1)-th drive output sub-circuit are of an annular structure;
for first signal lines connected to the first drive output sub-circuit to the (N−1)-th drive output sub-circuit, a length of a signal overlapping line in the first direction is greater than the line width of the at least one second signal line, and a length of a signal overlapping line in the second direction is greater than a line width of the signal connection line; and
signal overlapping lines of the first signal line connected to the N-th drive output sub-circuit extend in the first direction, and at least one boundary is arc-shaped, and an average line width of the signal overlapping lines of the first signal line connected to the N-th drive output sub-circuit is smaller than the line width of the signal connection line of the first signal line connected to the N-th drive output sub-circuit.

In a second aspect, the present disclosure further provides a display substrate, including: a first region and a second region, wherein the first region is provided with pixel drive circuits arranged in an array, the second region is provided with a gate drive circuit configured to provide a drive signal to the pixel drive circuits, the gate drive circuit includes: a plurality of shift registers, at least one stage of shift register includes: a pre-circuit and a drive output circuit, the pre-circuit is electrically connected to a signal input terminal, a reset signal terminal and a cascaded output signal terminal respectively, the drive output circuit is electrically connected to N output clock signal terminals respectively, a signal input terminal of at least one stage of shift register is electrically connected to a cascaded output signal terminal of at least one stage of shift register, a reset signal terminal of at least one stage of shift register is electrically connected to a cascaded output signal terminal of at least one stage of shift register,
the drive output circuit includes: N drive output sub-circuits, an n-th drive output sub-circuit is electrically connected to an n-th output clock signal terminal;
the second region is provided with M*N output clock signal lines, at least one output clock signal line at least partially extends in a second direction and is located on a side of the drive output circuit away from the first region, and a first output clock signal terminal to an N-th output clock signal terminal of the at least one stage of shift register are electrically connected to N output clock signal lines respectively, M≥2; and
for the at least one stage of shift register, a line width of an output clock signal line connected to the N-th output clock signal terminal is larger than a line width of an output clock signal line connected to at least one of the first output clock signal terminal to an (N−1)-th output clock signal terminal.

In an exemplary implementation, the display substrate further includes: a base substrate and a drive structure layer arranged on the base substrate, wherein the gate drive circuit and the pixel drive circuit are located on the drive structure layer, the drive structure layer includes: a semiconductor layer, a first conductive layer and a second conductive layer stacked sequentially on the base substrate; and
the output clock signal lines are located on the second conductive layer.

In an exemplary implementation, an n-th output clock signal terminal of the at least one stage of shift register is electrically connected to one of an n-th output clock signal line, and an (N+n)-th output clock signal line to an (M−1)*N+n-th output clock signal line; and
n-th output clock signal terminals of adjacent M stages of shift registers are connected to different output clock signal lines.

In an exemplary implementation, at least one output clock signal line is provided with a via;
a length in the first direction of a via in an output clock signal line connected to at least one of a first output clock signal terminal to an (N−1)-th output clock signal terminal of the at least one stage of shift register is smaller than a length in the first direction of a via in an output clock signal line connected to the N-th output clock signal terminal of the at least one stage of shift register; and
a via correlation distance of an output clock signal line connected to at least one of the first output clock signal terminal to the (N−1)-th output clock signal terminal of the at least one stage of shift register is equal to a via correlation distance of an output clock signal line connected to the N-th output clock signal terminal of the at least one stage of shift register, wherein the via correlation distance is a distance between a boundary of an output clock signal line and a boundary of a via of the output clock signal line.

In an exemplary implementation, the second region further includes: a plurality of clock connection lines, the clock connection lines include: a first clock connection line to an N-th clock connection line, the clock connection lines are located on the first conductive layer; and
the at least one stage of shift register is electrically connected to a connected n-th output clock signal line through an n-th clock connection line, and an orthographic projection of at least one clock connection line on the base substrate at least partially overlaps with an orthographic projection of a via of at least one output clock signal line on the base substrate.

In an exemplary implementation, the second region further includes: a data unit, the data unit is electrically connected to output clock signal lines connected to N drive output sub-circuits of the at least one stage of shift register and configured to provide a first clock signal to output clock signal lines connected to a second drive output sub-circuit to an (N−1)-th drive output sub-circuit of the at least one stage of shift register, and to provide a second clock signal to an output clock signal line connected to an N-th drive output sub-circuit of the at least one stage of shift register, the first clock signal includes: a first rising edge and a first falling edge, and the second clock signal includes: a second rising edge, a third rising edge and a second falling edge;
in a time period where the first rising edge is located, a voltage of the first clock signal rises from a second voltage to a first voltage, and in a time period where the first falling edge is located, the voltage of the first clock signal falls from the first voltage to the second voltage;
in a time period where the second rising edge is located, a voltage of the second clock signal rises from a third voltage to the second voltage, in a time period where the third rising edge is located, the voltage of the second clock signal rises from the second voltage to the first voltage, and in a time period where the second falling edge is located, the voltage of the second clock signal falls from the first voltage to the third voltage; and
the first voltage is a positive voltage, the second voltage and the third voltage are negative voltages, and an absolute value of the second voltage is smaller than an absolute value of the third voltage.

In an exemplary implementation, the data unit is further configured to provide a third clock signal to an output clock signal line connected to a first drive output sub-circuit of the at least one stage of shift register, the third clock signal includes: a fourth rising edge, a third falling edge and a fourth falling edge;
in a time period where the fourth rising edge is located, a voltage of the third clock signal rises from the second voltage to a fourth voltage, in a time period where the third falling edge is located, the voltage of the third clock signal falls from the fourth voltage to the first voltage, and in a time period where the fourth falling edge is located, the voltage of the third clock signal falls from the first voltage to the second voltage; and
the first voltage and the fourth voltage are positive voltages, the second voltage is a negative voltage, and the fourth voltage is greater than the first voltage.

In an exemplary implementation, the second region further includes: a data unit, the data unit is electrically connected to output clock signal lines connected to N drive output sub-circuits of the at least one stage of shift register and configured to provide a fourth clock signal to output clock signal lines connected to a second drive output sub-circuit to an (N−1)-th drive output sub-circuit of the at least one stage of shift register, and to provide a fifth clock signal to an output clock signal line connected to an N-th drive output sub-circuit of the at least one stage of shift register; and
a duration of a time period where a falling edge of the fifth clock signal is located is smaller than a half of a duration of a time period where a falling edge of the fourth clock signal is located.

In an exemplary implementation, the data unit is further configured to provide a sixth clock signal to an output clock signal line connected to a first drive output sub-circuit of at least one stage of shift register; and
a duration of a time period where a rising edge of the sixth clock signal is located is smaller than a half of a duration of a time period where a rising edge of the fourth clock signal is located.

In a third aspect, the present disclosure further provides a display apparatus including the display substrate described above.

Other aspects of the present disclosure may be comprehended after the drawings and the detailed descriptions are read and understood.

### BRIEF DESCRIPTION OF DRAWINGS

Accompany drawings are used to provide understanding of technical solution of the present disclosure, and form a part of the specification. The accompany drawings and embodiments of the present disclosure are adopted to explain the technical solution of the present disclosure, and do not form limitations on the technical solution of the present disclosure.

FIG. 1 is a schematic diagram of a structure of a display apparatus.

FIG. 2 is a schematic diagram of a planar structure of a display substrate.

FIG. 3 is a schematic diagram of a planar structure of another display substrate.

FIG. 4 is a schematic diagram of a planar structure of another display substrate.

FIG. 5 is an equivalent circuit diagram of a pixel drive circuit.

FIG. 6 is a schematic diagram of a structure of a shift register.

FIG. 7 is an equivalent circuit diagram of a shift register.

FIG. 8 is a working timing diagram of the shift register provided in FIG. 7.

FIG. 9 is a first schematic diagram of a structure of an output drive circuit according to an embodiment of the present disclosure.

FIG. 10 is a second schematic diagram of a structure of an output drive circuit according to an embodiment of the present disclosure.

FIG. 11 is a schematic diagram of part of film layers in FIG. 10.

FIG. 12 is a first schematic diagram of part of a structure in a first region of a display substrate.

FIG. 13 is a second schematic diagram of part of a structure in a first region of a display substrate.

FIG. 14 is a schematic diagram of part of a second region of a display apparatus.

FIG. 15 is a signal schematic diagram of a first clock signal.

FIG. 16 is a signal schematic diagram of a second clock signal.

FIG. 17 is a signal schematic diagram of a third clock signal.

FIG. 18 is a schematic diagram of a pattern of a semiconductor layer in FIG. 9.

FIG. 19 is a schematic diagram of a pattern of a semiconductor layer in FIG. 10.

FIG. 20 is a schematic diagram of a pattern of a first conductive layer in FIG. 9.

FIG. 21 is a schematic diagram after a pattern of a first conductive layer is formed in FIG. 9.

FIG. 22 is a schematic diagram of a pattern of a first conductive layer in FIG. 10.

FIG. 23 is a schematic diagram after a pattern of a first conductive layer is formed in FIG. 10.

FIG. 24 is a schematic diagram after a second insulating layer is formed in FIG. 9.

FIG. 25 is a schematic diagram after a second insulating layer is formed in FIG. 10.

FIG. 26 is a schematic diagram of a pattern of a second conductive layer in FIG. 9.

FIG. 27 is a schematic diagram after a pattern of a second conductive layer is formed in FIG. 9.

FIG. 28 is a schematic diagram of a pattern of a second conductive layer in FIG. 10.

FIG. 29 is a schematic diagram after a pattern of a second conductive layer is formed in FIG. 10.

### DETAILED DESCRIPTION

To make the objectives, technical solutions, and advantages of the present disclosure clearer, the embodiments of the present disclosure will be described in detail below with reference to the accompany drawings. It is to be noted that implementations may be implemented in multiple different forms. Those of ordinary skills in the art can easily understand such a fact that implementations and contents may be transformed into various forms without departing from the purpose and scope of the present disclosure. Therefore, the present disclosure should not be explained as being limited to the contents recorded in the following implementations only. The embodiments and features in the embodiments of the present disclosure may be randomly combined with each other if there is no conflict. In order to keep following description of the embodiments of the present disclosure clear and concise, detailed description of part of known functions and known components are omitted in the present disclosure. The drawings in the embodiments of the present disclosure relate only to the structures involved in the embodiments of the present disclosure, and other structures may be described with reference to conventional designs.

Scales of the drawings in the present disclosure may be used as a reference in actual processes, but are not limited thereto. For example, a width-length ratio of a channel, a thickness and spacing of each film, and a width and spacing of each signal line may be adjusted according to actual needs. A quantity of pixels in a display substrate and a quantity of sub-pixels in each pixel are not limited to numbers shown in the drawings. The drawings described in the present disclosure are schematic structural diagrams only, and one implementation of the present disclosure is not limited to shapes, numerical values, or the like shown in the drawings.

Ordinal numerals “first”, “second”, “third”, etc., in the specification are set not to form limits in numbers but only to avoid confusion between constituent elements.

In the specification, for convenience, expressions “central”, “above”, “below”, “front”, “back”, “vertical”, “horizontal”, “top”, “bottom”, “inside”, “outside”, etc., indicating directional or positional relationships are used to illustrate positional relationships between the constituent elements, not to indicate or imply that involved devices or elements are required to have specific orientations and be structured and operated with the specific orientations but only to easily and simply describe the present specification, and thus should not be understood as limitations on the present disclosure. The positional relationships between the constituent elements may be changed as appropriate according to a direction according to which each constituent element is described. Therefore, appropriate replacements based on situations are allowed, which is not limited to the expressions in the specification.

In the specification, unless otherwise specified and defined, terms “mounting”, “mutual connection”, and “connection” should be understood in a broad sense. For example, a connection may be fixed connection, or a detachable connection, or an integral connection; it may be a mechanical connection or an electrical connection; it may be a direct connection, or an indirect connection through middleware, or internal communication inside two elements. Those of ordinary skills in the art may understand specific meanings of the above terms in the present disclosure according to specific situations.

In the specification, a transistor refers to an element that at least includes three terminals, i.e., a gate electrode, a drain electrode, and a source electrode. The transistor has a channel region between the drain electrode (drain electrode terminal, drain region, or drain) and the source electrode (source electrode terminal, source region, or source), and a current can flow through the drain electrode, the channel region, and the source electrode. It is to be noted that in the specification, the channel region refers to a region through which a current mainly flows.

In the specification, a first electrode may be a drain electrode, and a second electrode may be a source electrode. Or, the first electrode may be a source electrode, and the second electrode may be a drain electrode. In a case that transistors with opposite polarities are used, or in a case that a direction of a current changes during operation of a circuit, or the like, functions of the “source electrode” and the “drain electrode” are sometimes interchangeable. Therefore, the “source electrode” and the “drain electrode” are interchangeable in the specification.

In the specification, “electrical connection” includes connection of constituent elements through an element with a certain electrical action. An “element with a certain electrical action” is not particularly limited as long as electrical signals between the connected constituent elements may be sent and received. Examples of the “element with the certain electrical action” not only include an electrode and a wiring, but also include a switching element such as a transistor, a resistor, an inductor, a capacitor, another element with various functions, etc.

In the specification, “parallel” refers to a state in which an angle formed by two straight lines is −10° or more and 10° or less, and thus also includes a state in which the angle is- 5°or more and 5° or less. In addition, “perpendicular” refers to a state in which an angle formed by two straight lines is 80° or more and 100° or less, and thus also includes a state in which the angle is 85° or more and 95° or less.

In the specification, a “film” and a “layer” are interchangeable. For example, a “conductive layer” may be replaced with a “conductive thin film” sometimes. Similarly, an “insulation film” may be replaced with an “insulating layer” sometimes.

In the specification, “arranged in a same layer” refers to a structure formed by patterning two (or more than two) structures through a same patterning process, and their materials may be the same or different. For example, materials of precursors for forming multiple structures arranged in a same layer are the same, and final materials may be the same or different.

Triangle, rectangle, trapezoid, pentagon, hexagon, etc. in this specification are not strictly defined, and they may be approximate triangle, rectangle, trapezoid, pentagon, hexagon, etc. There may be some small deformations caused by tolerance, and there may be chamfer, arc edge, deformation, etc.

In the present disclosure, “about” refers to that a boundary is not defined so strictly and numerical values within a range of process and measurement errors are allowed.

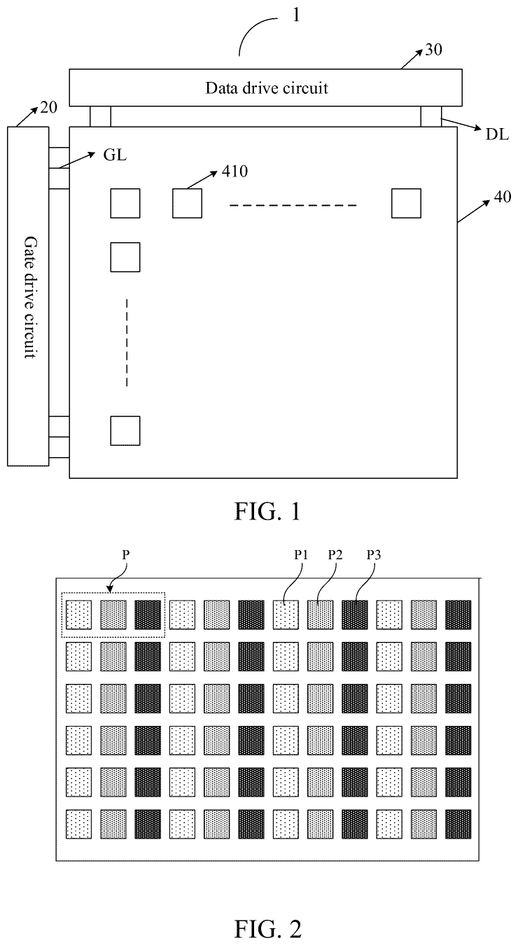

FIG. 1 is a schematic diagram of a structure of a display apparatus. As shown in FIG. 1, the display apparatus may include: a timing controller (not shown in the figure), a data drive circuit 30 and a gate drive circuit 20 located in a non-display area 1, and the display apparatus further includes: a display substrate 40. The timing controller is connected to the data drive circuit 30 and the gate drive circuit 20, the data drive circuit 30 is connected to a plurality of data signal lines DL, and the gate drive circuit 20 is connected to a plurality of scan signal lines GL. The display substrate may include: a pixel array. The pixel array may include a plurality of sub-pixels 410, at least one sub-pixel 410 may include a circuit unit and a light emitting device connected to the circuit unit, and the circuit unit may include a pixel drive circuit which may be connected to a scan signal line and a data signal line.

In an exemplary implementation, the timing controller may provide a gray scale value and a control signal suitable for the specification of the data drive circuit 30 to the data drive circuit 30, and may provide a clock signal, a scan start signal, and the like suitable for the specification of the gate drive circuit 20 to the gate drive circuit 20.

In an exemplary implementation, the data drive circuit 30 may generate a data voltage to be provided to the data signal lines DL using the gray scale value and the control signal received from the timing controller. For example, the data drive circuit 30 may sample the gray scale value using the clock signal, and apply a data voltage corresponding to the gray scale value to the data signal line DL by taking a pixel row as a unit. The gate drive circuit 20 may generate a scan signal to be provided to the scan signal line GL by receiving the clock signal, the scan start signal, or the like from the timing controller. For example, the gate drive circuit 20 may sequentially provide a scan signal with an on-level pulse to the scan signal lines GL. For example, the gate drive circuit 20 may be constructed in a form of a shift register and may generate a scan signal by sequentially transmitting a scan start signal provided in a form of an on-level pulse to a next stage circuit under control of the clock signal.

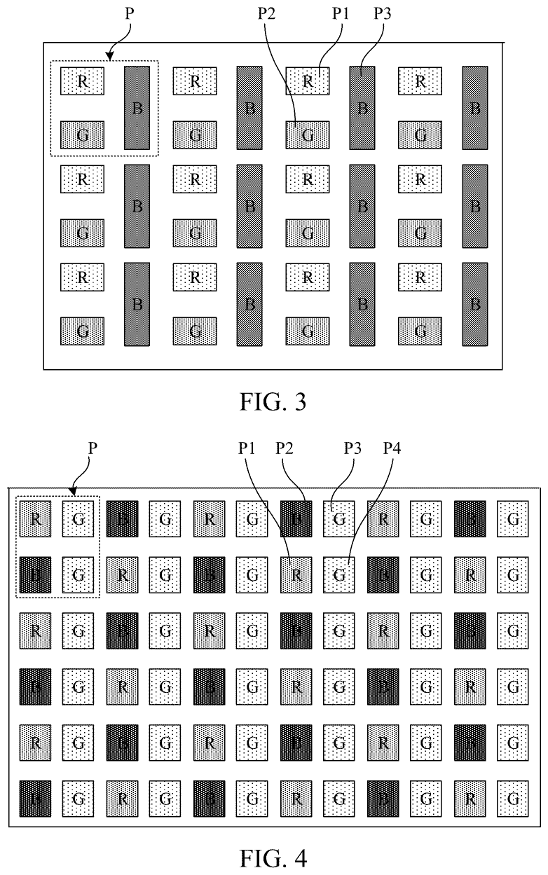

FIG. 2 is a schematic diagram of a planar structure of a display substrate, FIG. 3 is a schematic diagram of a planar structure of another display substrate, and FIG. 4 is a schematic diagram of a planar structure of a further display substrate. As shown in FIG. 2 to FIG. 4, the display substrate may include multiple pixel units P arranged in a matrix, at least one of the multiple pixel units P includes a first sub-pixel P1 emitting light of a first color, a second sub-pixel P2 emitting light of a second color, and a third sub-pixel P3 emitting light of a third color, and the first sub-pixel P1, the second sub-pixel P2 and the third sub-pixel P3 each include a pixel drive circuit and a light emitting device. Pixel drive circuits in the first sub-pixel P1, the second sub-pixel P2 and the third sub-pixel P3 are connected to a scan signal line and a data signal line, and the pixel drive circuit is configured to receive a data voltage transmitted by the data signal line and output a corresponding current to the light emitting device under control of the scan signal line. Light emitting devices in the first sub-pixel P1, the second sub-pixel P2 and the third sub-pixel P3 are respectively connected to the pixel drive circuits of the sub-pixels in which the light emitting devices are located, and the light emitting devices are configured to emit light with a corresponding brightness in response to currents outputted by the pixel drive circuits of the sub-pixels in which the light emitting devices are located.

In an exemplary implementation, the first sub-pixel P1 may be a red (R) sub-pixel emitting red light, the second sub-pixel P2 may be a blue (B) sub-pixel emitting blue light, and the third sub-pixel P3 may be a green (G) sub-pixel emitting green light.

In an exemplary implementation, a sub-pixel may have a shape of a rectangle, a rhombus, a pentagon, or a hexagon.

In an exemplary implementation, a pixel unit may include three sub-pixels, wherein the three sub-pixels may be arranged side by side horizontally, side by side vertically, or in a form of pyramid, which is not limited in the present disclosure. FIG. 2 illustrates an example in which the three sub-pixels in a pixel unit are arranged side by side horizontally. FIG. 3 illustrates an example in which the three sub-pixels in a pixel unit are arranged in a delta-shaped form.

In other exemplary implementations, a pixel unit may include four sub-pixels, which may be arranged side by side horizontally, side by side vertically, or in a shape of a square, the present disclosure is not limited thereto. FIG. 4 illustrates an example in which the four sub-pixels in a pixel unit are arranged in a Square to form a GGRB pixel arrangement.

In an exemplary implementation, the pixel drive circuit may be of a structure of 3T1C, 4T1C, 5T1C, 5T2C, 6T1C, or 7T1C.

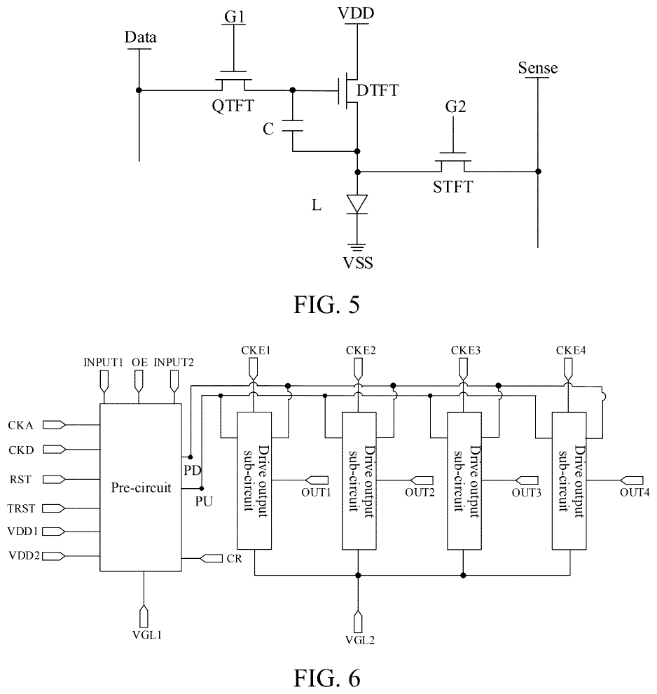

FIG. 5 is an equivalent circuit diagram of a pixel drive circuit. As shown in FIG. 5, the pixel drive circuit has a 3T1C structure, and may include three transistors (a switch transistor QTFT, a sensing transistor STFT and a drive transistor DTFT), one capacitor C and six signal lines (a data signal line Data, a first scan signal line G1, a second scan signal line G2, a sensing signal line Sense, a first power supply line VDD and a second power supply line VSS).

In an exemplary implementation, a gate electrode of the switch transistor QTFT is coupled to the first scan signal line G1, a first electrode of the switch transistor QTFT is coupled to the data signal line Data, and a second electrode of the switch transistor QTFT is coupled to a gate electrode of the drive transistor DTFT. The switch transistor QTFT is configured to receive a data signal transmitted by the data signal line Data under control of the first scan signal line G1, and cause the gate electrode of the drive transistor DTFT to receive the data signal.

In an exemplary implementation, the gate electrode of the drive transistor DTFT is coupled to the second electrode of the switch transistor QTFT, a first electrode of the drive transistor DTFT is coupled to the first power supply line VDD, and a second electrode of the drive transistor DTFT is coupled to a first electrode of the light emitting device L. The drive transistor DTFT is configured to generate a corresponding drive current at the second electrode under control of the data signal received by the gate electrode of the drive transistor DTFT.

In an exemplary implementation, a gate electrode of the sensing transistor STFT is coupled to the second scan signal line G2, a first electrode of the sensing transistor STFT is coupled to the sensing signal line Sense, and a second electrode of the sensing transistor STFT is coupled to the second electrode of the drive transistor DTFT. The sensing transistor STFT is configured to extract a threshold voltage Vth and a mobility of the drive transistor DTFT in response to a sensing time sequence to compensate for the threshold voltage Vth.

In an exemplary implementation, the first electrode of the light emitting device L is coupled to the second electrode of the drive transistor DTFT, and a second electrode of the light emitting device is coupled to the second power supply line VSS. The light emitting device L is configured to emit light of a corresponding brightness in response to a drive current of the second electrode of the drive transistor DTFT.

In an exemplary implementation, a first electrode of the capacitor C is coupled to the gate electrode of the drive transistor DTFT, and a second electrode of the capacitor C is coupled to the second electrode of the sensing transistor STFT. The capacitor C is configured to store a potential of the gate electrode of the drive transistor DTFT.

In an exemplary implementation, a working process of the pixel drive circuit includes: when the signal of the first scan signal line G1 is an active level signal, the switch transistor QTFT is turned on, and the data voltage Vdata provided by the data signal line Data is stored into the capacitor C through the switch transistor QTFT, thereby controlling the drive transistor T2 to generate a drive current to drive the light emitting device L to emit light. In addition, when the signal of the second scan signal line G2 is an active level signal, the sensing transistor STFT is turned on, and the sensing transistor STFT extracts the threshold voltage Vth and the mobility of the drive transistor DTFT in response to the sensing time sequence.

In some exemplary embodiments, the switch transistor QTFT, the sensing transistor STFT and the drive transistor DTFT may be P-type transistors, or may be N-type transistors. Use of a same type of transistors in a pixel drive circuit may simplify a process flow, reduce process difficulties of the display substrate, and improve a yield of products. In some possible implementations, the switch transistor QTFT, the sensing transistor STFT and the drive transistor DTFT may include P-type transistors and N-type transistors.

In an exemplary implementation, the first scan signal line G1 and the second scan signal line G2 may be a same signal line, i.e., the pixel drive circuit may also extract the threshold voltage Vth and the mobility of the drive transistor DTFT while driving the light emitting device L to emit light. The display substrate may externally compensate the pixel drive circuit according to the threshold voltage Vth and the mobility of the drive transistor DTFT.

In an exemplary implementation, the first scan signal line G1 and the second scan signal line G2 may extend in a first direction, and the data signal line Data, the first power supply line VDD and the sensing signal line Sense extend in a second direction. The first direction intersects with the second direction. For example, an angle between the first direction and the second direction is about 70 degrees to 90 degrees. The first direction and the second direction may be in a same plane. For example, the first direction may be a row direction, and the second direction may be a column direction.

In an exemplary implementation, the light emitting device may include any one of an organic light emitting diode (OLED), a quantum dot light emitting diode, and an inorganic light emitting diode. For example, the light emitting device L may be a micron-scale light emitting device, such as a Micro Light emitting Diode (Micro LED), a Mini Light emitting Diode (Mini LED), a Micro Organic Light Emitting Diode (Micro OLED), and the like, which are not limited by the embodiments of the present disclosure. For example, taking a case in which the light emitting device L is an organic electroluminescent diode (OLED) as an example, the light emitting device may include a first electrode (for example, as an anode), an organic light emitting layer, and a second electrode (for example, as a cathode) which are stacked.

In an exemplary implementation, the organic emitting layer may include an Emitting Layer (EML), and any one or more of following: a Hole Injection Layer (HIL), a Hole Transport Layer (HTL), an Electron Block Layer (EBL), a Hole Block Layer (HBL), an Electron Transport Layer (ETL), and an Electron Injection Layer (EIL). In an exemplary implementation, one or more of hole injection layers, hole transport layers, electron block layers, hole block layers, electron transport layers and electron injection layers of all sub-pixels may be connected together to form a common connected layer. The emitting layers of adjacent sub-pixels may overlap slightly with each other, or may be isolated from each other.

In an exemplary implementation, the gate drive circuit is electrically connected to a plurality of first signal lines and configured to provide a drive signal to the first signal lines. The first signal lines include: a scan signal line. The scan signal line may be at least one of the first scan signal lines and the second scan signal line.

In an exemplary implementation, the gate drive circuit includes: a plurality of cascaded shift registers. At least one stage of shift register may be electrically connected to at least one first signal line. FIG. 6 is a schematic diagram of a structure of a shift register. As shown in FIG. 6, at least one stage of shift register may include: a pre-circuit and N drive output sub-circuits. FIG. 6 illustrates an example in which N=4.

In an exemplary implementation, as shown in FIG. 6, the pre-circuit is electrically connected to a first signal input terminal INPUT1, a second signal input terminal INPUT2, a detection input terminal OE, a first clock signal terminal CKA, a second clock signal terminal CKD, a reset signal terminal RST, a total reset signal terminal TRST, a Direct Current (DC) high-level power supply terminal VDD1, an Alternating Current (AC) high-level power supply terminal VDD2, a first low-level power supply terminal VGL1, a cascaded signal output terminal CR, a pull-up node PU and a pull-down node PD. The pre-circuit is configured to provide a signal of the first clock signal terminal CKA, the DC high-level power supply terminal VDD1 or the first low-level power supply terminal VGL1 to the pull-up node PU under control of signals of the second signal input terminal INPUT2, the detection input terminal OE, the first clock signal terminal CKA, the first signal input terminal INPUT1, the reset signal terminal RST and the total reset signal terminal TRST, to provide a signal of the AC high-level power supply terminal VDD2 or the first low-level power supply terminal VGL1 to the pull-down node PD under control of signals of the AC high-level power supply terminal VDD2 and the pull-up node PU, and to provide a signal of the second clock power supply terminal CKD to the cascaded signal output terminal CR under control of the signal of the pull-up node PU.

In an exemplary implementation, an n-th drive output sub-circuit is electrically connected to the pull-up node PU, the pull-down node PD, an n-th output clock signal terminal CKEn, an n-th drive signal output terminal OUTn and the second low-level power supply terminal VGL2, and is configured to provide a signal of the n-th output clock signal terminal CKEn to the n-th drive signal output terminal OUTn under control of the signal of the pull-up node PU, or to provide a signal of the second low-level power supply terminal VGL2 to the n-th drive signal output terminal OUTn under control of the signal of the pull-down node PD.

In an exemplary implementation, at least one stage of shift register is electrically connected to at least one first signal line, wherein any drive signal output terminal of a first drive signal output terminal OUT1 to an n-th drive signal output terminal OUTn in the at least one stage of shift register is electrically connected to at least one first signal line, i.e., the n-th drive signal output terminal OUTn in the at least one stage of shift register is electrically connected to at least one first signal line to which the at least one stage of shift register is connected. That is to say, in the present disclosure, the shift register driving a plurality of rows of sub-pixels is achieved by arranging a plurality of drive output sub-circuits.

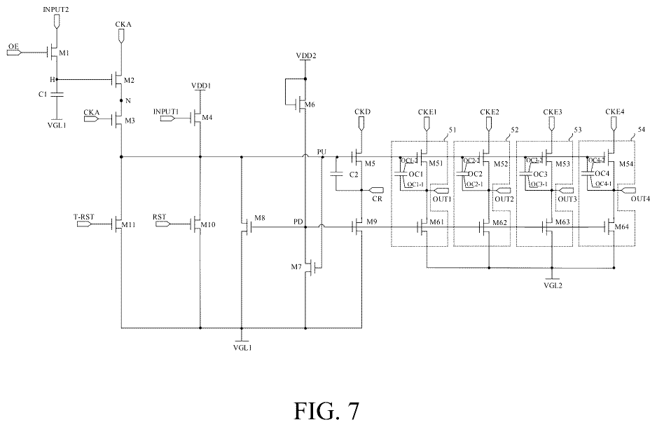

FIG. 7 is an equivalent circuit diagram of a shift register. As shown in FIG. 7, the pre-circuit includes: a first pull-up sub-circuit configured to provide a signal of the first clock signal terminal CKA to the pull-up node PU under control of the signals of the detection input terminal OE, the second signal input terminal INPUT2 and the first clock signal terminal CKA. For example, the first pull-up sub-circuit may include: a first transistor M1 to a third transistor M3, and a first capacitor C1. A gate electrode of the first transistor M1 is electrically connected to the detection input terminal OE, a first electrode of the first transistor M1 is electrically connected to the second signal input terminal INPUT2, and a second electrode of the first transistor M1 is electrically connected to a first node H. A gate electrode of the second transistor M2 is electrically connected to the first node H, a first electrode of the second transistor M2 is electrically connected to the first clock signal terminal CKA, a second electrode of the second transistor M2 is electrically connected to a second node N. A gate electrode of the third transistor M3 is electrically connected to the first clock signal terminal CKA, a first electrode of the third transistor M3 is electrically connected to the second node N, and a second electrode of the third transistor M3 is electrically connected to the pull-up node PU. A first terminal of the first capacitor C1 is electrically connected to the first low-level power supply terminal VGL1, and a second terminal of the first capacitor C1 is electrically connected to the first node H.

In an exemplary implementation, the first pull-up sub-circuit may pull up a potential of the signal of the pull-up node PU in a sensing stage.

In an exemplary implementation, as shown in FIG. 7, the pre-circuit may further include: a second pull-up sub-circuit configured to provide a signal of the DC high-level power supply terminal VDD1 to the pull-up node PU under control of the signal of the first signal input terminal INPUT1. For example, the second pull-up sub-circuit may include: a fourth transistor M4. A gate electrode of the fourth transistor M4 is electrically connected to the first signal input terminal INPUT1, a first electrode of the fourth transistor M4 is electrically connected to the DC high-level power supply terminal VDD1, and a second electrode of the fourth transistor M4 is electrically connected to the pull-up node PU.

In an exemplary implementation, the second pull-up sub-circuit may pull up the potential of the signal of the pull-up node PU in a display phase.

In an exemplary implementation, as shown in FIG. 7, the pre-circuit may further include: a cascaded output sub-circuit. The cascaded output sub-circuit is configured to provide a signal of the second clock signal terminal CKD to the cascaded signal output terminal CR under control of the signal of the pull-up node PU. For example, the cascaded output sub-circuit may include: a fifth transistor M5 and a second capacitor C2. A gate electrode of the fifth transistor M5 is electrically connected to the pull-up node PU, a first electrode of the fifth transistor M5 is electrically connected to the second clock signal terminal CKD, a second electrode of the fifth transistor M5 is electrically connected to the cascaded signal output terminal CR. A first terminal of the second capacitor C2 is electrically connected to the pull-up node PU, and a second terminal of the second capacitor C2 is electrically connected to the cascaded signal output terminal CR.

In an exemplary implementation, the cascaded output sub-circuit may provide a cascaded signal to a first signal input terminal INPUT1 of a shift register of a next stage.

In an exemplary implementation, as shown in FIG. 7, the pre-circuit may further include: a noise reduction sub-circuit. The noise reduction sub-circuit is configured to provide a signal of the AC high-level power supply terminal VDD2 to the pull-down node PD under control of the signal of the AC high-level power supply terminal VDD2, and to provide a signal of the first low-level power supply terminal VGL1 to the pull-up node PU and the cascaded output signal terminal CR under control of the signal of the pull-down node PD. For example, the noise reduction sub-circuit may include: a sixth transistor M6 to a ninth transistor M9. A gate electrode and a first electrode of the sixth transistor M6 are electrically connected to the AC high-level power supply terminal VDD2, and a second electrode of the sixth transistor M6 is electrically connected to the pull-down node PD. A gate electrode of the seventh transistor M7 is electrically connected to the pull-up node PU, a first electrode of the seventh transistor M7 is electrically connected to the first low-level power supply terminal VGL1, and a second electrode of the seventh transistor M7 is electrically connected to the pull-down node PD. A gate electrode of the eighth transistor M8 is electrically connected to the pull-down node PD, a first electrode of the eighth transistor M8 is electrically connected to the pull-up node PU, a second electrode of the eighth transistor M8 is electrically connected to the first low-level power supply terminal VGL1. A gate electrode of the ninth transistor M9 is electrically connected to the pull-down node PD, a first electrode of the ninth transistor M9 is electrically connected to the cascaded signal output terminal CR, and a second electrode of the ninth transistor M9 is electrically connected to the first low-level power supply terminal VGL1.

In an exemplary implementation, the noise reduction sub-circuit may reduce the noise of a shift register after an output of the shift register, and may improve reliability of the shift register.

In an exemplary implementation, as shown in FIG. 7, the pre-circuit may further include: a reset sub-circuit. The reset sub-circuit is configured to provide a signal of the first low-level power supply terminal VGL1 to the pull-up node PU under control of the signals of the reset signal terminal RST and the total reset signal terminal TRST. For example, the reset sub-circuit may include: a tenth transistor M10 and an eleventh transistor M11. A gate electrode of the tenth transistor M10 is electrically connected to the reset signal terminal RST, a first electrode of the tenth transistor M10 is electrically connected to the first low-level power supply terminal VGL1, and a second electrode of the tenth transistor M10 is electrically connected to the pull-up node PU. A gate electrode of the eleventh transistor M11 is electrically connected to the total reset signal terminal TRST, a first electrode of the eleventh transistor M11 is electrically connected to the first low-level power supply terminal VGL1, and a second electrode of the eleventh transistor M11 is electrically connected to the pull-up node PU.

In an exemplary implementation, as shown in FIG. 7, a first drive output sub-circuit may include: a first output transistor M51, a first noise reduction transistor M61 and a first output capacitor OC1. A gate electrode of the first output transistor M51 is electrically connected to the pull-up node PU, a first electrode of the first output transistor M51 is electrically connected to a first output clock signal terminal CKE1, a second electrode of the first output transistor M51 is electrically connected to the first drive signal output terminal OUT1. A gate electrode of the first noise reduction transistor M61 is electrically connected to the pull-down node PD, a first electrode of the first noise reduction transistor M61 is electrically connected to the second low-level power supply terminal VGL2, and a second electrode of the first noise reduction transistor M61 is electrically connected to the first drive signal output terminal OUT1. A first plate OC1-1 of the first output capacitor OC1 is electrically connected to the first drive signal output terminal OUT1, and a second plate OC1-2 of the first output capacitor C1 is electrically connected to the pull-up node PU.

In an exemplary implementation, as shown in FIG. 7, a second drive output sub-circuit may include: a second output transistor M52, a second noise reduction transistor M62 and a second output capacitor OC2. A gate electrode of the second output transistor M52 is electrically connected to the pull-up node PU, a first electrode of the second output transistor M52 is electrically connected to a second output clock signal terminal CKE2, and a second electrode of the second output transistor M52 is electrically connected to the second drive signal output terminal OUT2. A gate electrode of the second noise reduction transistor M62 is electrically connected to the pull-down node PD, a first electrode of the second noise reduction transistor M62 is electrically connected to the second low-level power supply terminal VGL2, and a second electrode of the second noise reduction transistor M62 is electrically connected to the second drive signal output terminal OUT2. A first plate OC2-1 of the second output capacitor OC2 is electrically connected to the second drive signal output terminal OUT2, and a second plate OC2-2 of the second output capacitor C2 is electrically connected to the pull-up node PU.

In an exemplary implementation, as shown in FIG. 7, a third drive output sub-circuit may include: a third output transistor M53, a third noise reduction transistor M63 and a third output capacitor OC3. A gate electrode of the third output transistor M53 is electrically connected to the pull-up node PU, a first electrode of the third output transistor M53 is electrically connected to a third output clock signal terminal CKE3, and a second electrode of the third output transistor M53 is electrically connected to the third drive signal output terminal OUT3. A gate electrode of the third noise reduction transistor M63 is electrically connected to the pull-down node PD, a first electrode of the third noise reduction transistor M63 is electrically connected to the second low-level power supply terminal VGL2, a second electrode of the third noise reduction transistor M63 is electrically connected to the third drive signal output terminal OUT3. A first plate of the third output capacitor OC3 is electrically connected to the third drive signal output terminal OUT3, and a second plate OC3-2 of the third output capacitor C3 is electrically connected to the pull-up node PU.

In an exemplary implementation, as shown in FIG. 7, a fourth drive output sub-circuit may include: a fourth output transistor M54, a fourth noise reduction transistor M64 and a fourth output capacitor OC4. A gate electrode of the fourth output transistor M54 is electrically connected to the pull-up node PU, a first electrode of the fourth output transistor M54 is electrically connected to a fourth output clock signal terminal CKE4, a second electrode of the fourth output transistor M54 is electrically connected to the fourth drive signal output terminal OUT4. A gate electrode of the fourth noise reduction transistor M64 is electrically connected to the pull-down node PD, a first electrode of the fourth noise reduction transistor M64 is electrically connected to the second low-level power supply terminal VGL2, and a second electrode of the fourth noise reduction transistor M64 is electrically connected to the fourth drive signal output terminal OUT4. A first plate OC4-1 of the fourth output capacitor OC4 is electrically connected to the fourth drive signal output terminal OUT4, and a second plate OC4-2 of the fourth output capacitor C4 is electrically connected to the pull-up node PU.

In some exemplary embodiments, the first transistor M1 to the eleventh transistor M11, the first output transistor M51 to the fourth output transistor M54, and the first noise reduction transistor M61 to the fourth noise reduction transistor M64 may be P-type transistors, or may be N-type transistors. Use of a same type of transistors in a pixel drive circuit may simplify a process flow, reduce process difficulties of the display substrate, and improve a yield of products. FIG. 7 illustrates an example in which the first transistor M1 to the eleventh transistor M11, the first output transistor M51 to the fourth output transistor M54, and the first noise reduction transistor M61 to the fourth noise reduction transistor M64 are all N-type transistors.

In an exemplary implementation, a signal at any one of the first clock signal terminal CKA, the second clock signal terminal CKD, and the first output clock signal terminal CKE1 to the fourth output clock signal terminal CKE4 is a square wave signal repeating a high voltage and a low voltage. For example, signals of the second clock signal terminal CKD, and the first output clock signal terminal CKE1 to the fourth output clock signal terminal CKE4 may have a same cycle, and may be configured as phase shift signals. Here, the signal at the second output clock signal terminal CKE2 may be phase shifted by half a cycle compared to the signal at the first output clock signal terminal CKE1. The signal at the third output clock signal terminal CKE3 may be phase shifted by half a cycle compared to the signal at the second output clock signal terminal CKE2. The signal at the fourth output clock signal terminal CKE4 may be phase shifted by half a cycle compared to the signal at the third output clock signal terminal CKE3. A high voltage period in each cycle of a signal of at least one of the first output clock signal terminal CKE1 to the fourth output clock signal terminal CKE4 may be set longer than a low voltage period.

In an exemplary implementation, the signal of the first low-level power supply terminal VGL1 is a DC signal and is continuously a low-level signal.

In an exemplary implementation, the signal of the second low-level power supply terminal VGL2 is a DC signal and is continuously a low-level signal. An absolute value of a voltage value of the signal of the second low-level power supply terminal VGL2 is greater than an absolute value of a voltage value of the signal of the first low-level power supply terminal VGL1.

In an exemplary implementation, the signal of the DC high-level power supply terminal VDD1 is a DC signal and is continuously a high-level signal.

In an exemplary implementation, the signal of the AC high-level power supply terminal VDD2 is an AC signal, and the signal in part of the time period is a high-level signal, and the signal in part of the time period is a low-level signal.

In an exemplary implementation, any of the first capacitor C1, the second capacitor C2, and all capacitors located in all the drive output sub-circuits may be a capacitor device made by a process, for example, the capacitor device may be implemented by making a special capacitor electrode, and a plurality of capacitor electrodes of the capacitor may be implemented by metal layers, semiconductor layers (e.g. doped polysilicon), or the like. Or, any of the first capacitor C1, the second capacitor C2, and all the capacitors located in all the drive output sub-circuits may be parasitic capacitance between a plurality of devices, connection of any of the first capacitor C1, the second capacitor C2, and all the capacitors located in all the drive output sub-circuits may be implemented by the transistors themselves, and other devices and lines, including but not limited to the implementations described above, which may be other suitable connection modes, as long as the level of a corresponding node can be stored. Herein, the illustrative embodiments of the present disclosure are not limited thereto.

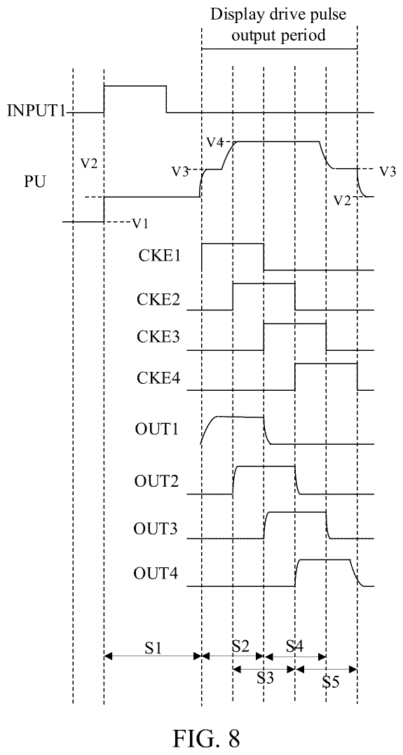

In an exemplary implementation, a working process of the shift register includes: a display stage and a sensing stage. In the display stage, the second pull-up sub-circuit provides a signal to the pull-up node PU, and in the sensing stage, the first pull-up sub-circuit provides a signal to the pull-up node PU. FIG. 8 is a working timing diagram of the shift register provided in FIG. 7. As shown in FIG. 8, the working process of the shift register in the display stage may include the followings.

In a first stage S1 (an input stage), the signal of the first signal input terminal INPUT1 is a high-level signal, and the signals of the second clock signal terminal CKD, and the first output clock signal terminal CKE1 to the fourth output clock signal terminal CKE4 are low-level signals. The signal of the first signal input terminal INPUT1 is the high-level signal, the fourth transistor M4 is turned on, the signal of the DC high-level power supply terminal VDD1 is written into the pull-up node PU, a signal of the pull-up node PU is a high-level signal, the fifth transistor M5, and the first output transistor M51 to the fourth output transistor M54 are turned on, the signals of the second clock signal terminal CKD, and the first output clock signal terminal CKE1 to the fourth output clock signal terminal CKE4 are written into the cascaded signal output terminal CR, and the first drive signal output terminal OUT1 to the fourth drive signal output terminal OUT4, respectively, and the cascaded signal output terminal CR, and the first drive signal output terminal OUT1 to the fourth drive signal output terminal OUT4 have no output.

In a second stage S2 (a first output stage), the signal of the first output clock signal terminal CKE1 is a high-level signal, and the signals of the second output clock signal terminal CKE2 to the fourth output clock signal terminal CKE4 are low-level signals. The signal of the pull-up node PU is maintained as a high-level signal under action of the second capacitor C2, and the first output capacitor OC1 to the fourth output capacitor OC4, the first output transistor M51 to the fourth output transistor M54 are turned on, and the high-level signal of the first output clock signal terminal CKE1 is written into the first drive signal output terminal OUT1. In this stage, the first drive signal output terminal OUT1 outputs a drive signal.

In a third stage S3 (a second output stage), the signal of the second output clock signal terminal CKE2 is a high-level signal, and the signals of the first output clock signal terminal CKE1, the third output clock signal terminal CKE3 and the fourth output clock signal terminal CKE4 are low-level signals. The signal of the pull-up node PU is maintained as a high-level signal under the action of the second capacitor C2, and the first output capacitor OC1 to the fourth output capacitor OC4, the first output transistor M51 to the fourth output transistor M54 are turned on, and the high-level signal of the second output clock signal terminal CKE2 is written into the second drive signal output terminal OUT2. In this stage, the second drive signal output terminal OUT2 outputs a drive signal.

In a fourth stage S4 (a third output stage), the signal of the third output clock signal terminal CKE3 is a high-level signal, and the signals of the first output clock signal terminal CKE1, the second output clock signal terminal CKE2 and the fourth output clock signal terminal CKE4 are low-level signals. The signal of the pull-up node PU is maintained as a high-level signal under the action of the second capacitor C2, and the first output capacitor OC1 to the fourth output capacitor OC4, the first output transistor M51 to the fourth output transistor M54 are turned on, and the high-level signal of the third output clock signal terminal CKE3 is written into the third drive signal output terminal OUT3. In this stage, the third drive signal output terminal OUT3 outputs a drive signal.

In a fifth stage S5 (a fourth output stage), the signal of the fourth output clock signal terminal CKE4 is a high-level signal, and the signals of the first output clock signal terminal CKE1 to the third output clock signal terminal CKE3 are low-level signals. The signal of the pull-up node PU is maintained as a high-level signal under the action of the second capacitor C2, and the first output capacitor OC1 to the fourth output capacitor OC4, the first output transistor M51 to the fourth output transistor M54 are turned on, and the high-level signal of the fourth output clock signal terminal CKE4 is written into the fourth drive signal output terminal OUT4. In this stage, the fourth drive signal output terminal OUT4 outputs a drive signal.

In an exemplary implementation, there is an overlap between time periods in which drive signals output in adjacent output stages are located.

A time period in which the second stage S2 to the fifth stage S5 are located may be referred to as a display drive pulse output period.

In an exemplary implementation, the signal of the second clock signal terminal CKD may be a high-level signal in one of the second stage S2 to the fifth stage S5, to enable the cascaded signal output terminal CR to output cascaded signals.

In an exemplary implementation, after the display drive pulse output period, the working process of the shift register may further include: a reset stage. In the reset stage, the signal of the reset signal terminal RST of at least one stage of shift register is a high-level signal, the tenth transistor M10 is turned on, the signal of the pull-up node PU is pulled down by the signal of the first low-level power supply terminal VGL1, the fifth transistor M5, and the first output transistor M51 to the fourth output transistor M54 are turned off, and the signals of the first drive signal output terminal OUT1 to the fourth drive signal output terminal OUT4 are not affected by the signals of the first output clock signal terminal CKE1 to the fourth output clock signal terminal CKE4.

In an exemplary implementation, after the display drive pulse output period, the working process of the shift register may further include: a noise reduction stage. In the noise reduction stage, when the signal of the AC high-level power supply terminal VDD2 is a high-level signal, the sixth transistor M6 is turned on, the signal of the pull-down node PD is pulled up, the eighth transistor M8, the ninth transistor M9, and the first noise reduction transistor M61 to the fourth noise reduction transistor M64 are turned on, the signals of the pull-up node PU and the cascaded output signal terminal CR are pulled down by the signal of the first low-level power supply terminal VGL1, and the signals of the first drive signal output terminal OUT1 to the fourth drive signal output terminal OUT4 are pulled down by the signal of the second low-level power supply terminal VGL2, so as to reduce noise of the shift register.

In an exemplary implementation, when the shift register is in a sensing stage, in the input stage, the signals of the detection input terminal OE, the second signal input terminal INPUT2 and the first clock signal terminal CKA are high-level signals, the first transistor M3, the second transistor M2 and the third transistor M3 are turned on, and the signals of the first node H, the second node N and the pull-up node PU are high-level signals.

As shown in FIG. 8, when the first drive signal output terminal OUT1 of at least one stage of shift register outputs a drive signal, i.e., in the first output stage, the potential of the signal of the pull-up node PU rises from a second potential V2 to a third potential V3, and then rises from the third potential V3 to a fourth potential V4. Due to the continuous rise of the potential of the signal of the pull-up node PU, the drive signal output from the first drive signal output terminal OUT1 has a relatively obvious rising edge. The rising edge will affect on-durations of some transistors (such as switch transistors or sensing transistors) in the pixel drive circuit, thereby affecting the display screen.

As shown in FIG. 8, when the second drive signal output terminal OUT2 and the third drive signal output terminal OUT3 of at least one stage of shift register output a drive signal, i.e., in the second output stage and the third output stage, the potential of the signal of the pull-up node PU remains substantially unchanged at the level of the fourth potential V4. The reason why the potential of the signal of the pull-up node PU remains substantially unchanged at the level of the fourth potential V4 in the second output stage is as follows. When the second drive signal output terminal OUT2 outputs a drive signal, under the action of the second output capacitor OC2, the potential of the signal of the pull-up node PU will be pulled up by the drive signal output from the second drive signal output terminal OUT2, but at this time, the potential of the drive signal output from the first drive signal output terminal OUT1 starts to decrease, and under action of the first output capacitor OC1, the potential of the signal of the pull-up node PU will be pulled down by the drive signal output from the first drive signal output terminal OUT1. Therefore, the potential of the signal of the pull-up node PU remains unchanged in the second output stage under the action of the first output capacitor OC1 and the second output capacitor OC2. Similarly, the reason why the potential of the signal of the pull-up node PU remains substantially unchanged at the level of the fourth potential V4 in the third output stage is as follows. When the third drive signal output terminal OUT3 outputs a drive signal, under action of the third output capacitor OC3, the potential of the signal of the pull-up node PU will be pulled up by the drive signal output from the third drive signal output terminal OUT3, but at this time, the potential of the drive signal output from the second drive signal output terminal OUT2 starts to decrease, and under action of the second output capacitor OC2, the potential of the signal of the pull-up node PU will be pulled down by the drive signal output from the second drive signal output terminal OUT2. Therefore, the potential of the signal of the pull-up node PU remains unchanged in the third output stage under the action of the second output capacitor OC2 and the third output capacitor OC3.

As shown in FIG. 8, when the fourth drive signal output terminal OUT4 of at least one stage of shift register outputs a drive signal, i.e., in the fourth output stage, the potential of the signal of the pull-up node PU decreases from the fourth potential V4 to the third potential V3, and in the second half of the fourth output stage, the potential of the drive signal output from the fourth noise reduction transistor M54 begins to decrease, and under action of the fourth output capacitor OC4, the potential of the signal of the pull-up node PU further decreases. In the at least one stage of shift register, no drive signal is output after the fourth drive signal output terminal OUT4, i.e., there is no drive output sub-circuit capable of raising the potential of the signal of the pull-up node PU, then the potential of the pull-up node PU decreases from the fourth potential V4 to the third potential V3, and then from the third potential V3 to the second potential V2. Therefore, the drive signal (which is also the drive signal output by the last drive signal output terminal in the shift register) output by the fourth drive signal output terminal OUT4 has a relatively long falling edge, and this relatively long falling edge will affect the on-duration of some transistors (such as switch transistors or sensing transistors) in the pixel drive circuit. In summary, since the signal of the pull-up node in the shift register in the display substrate varies in the output stage, the drive signals provided by the shift register to the connected different rows of pixel drive circuits are also different. In particular, the sub-pixels connected to the last drive output sub-circuit of the shift register are less bright than the sub-pixels connected to the other drive output sub-circuits, so that lateral stripes appear in the display substrate, resulting in uneven display of the display substrate, which affects a display effect of the display substrate.

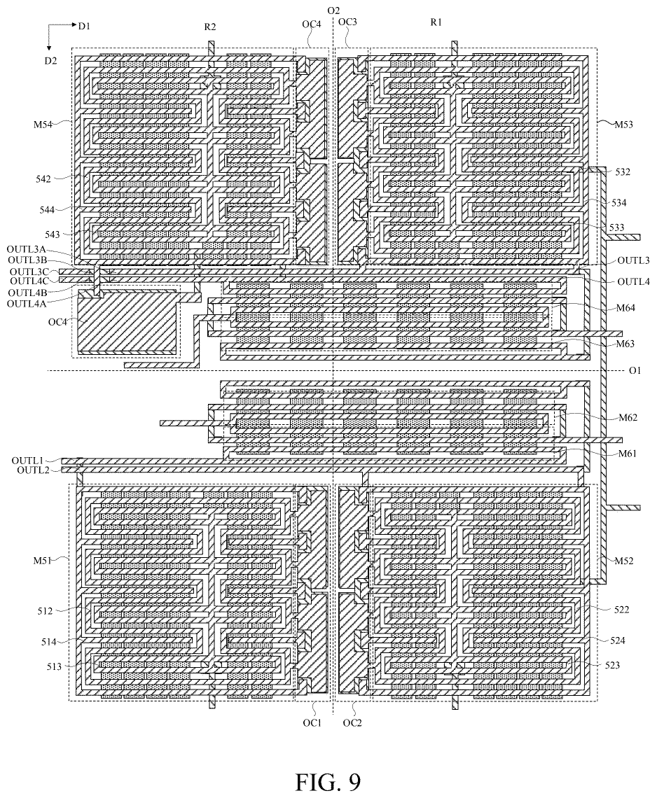

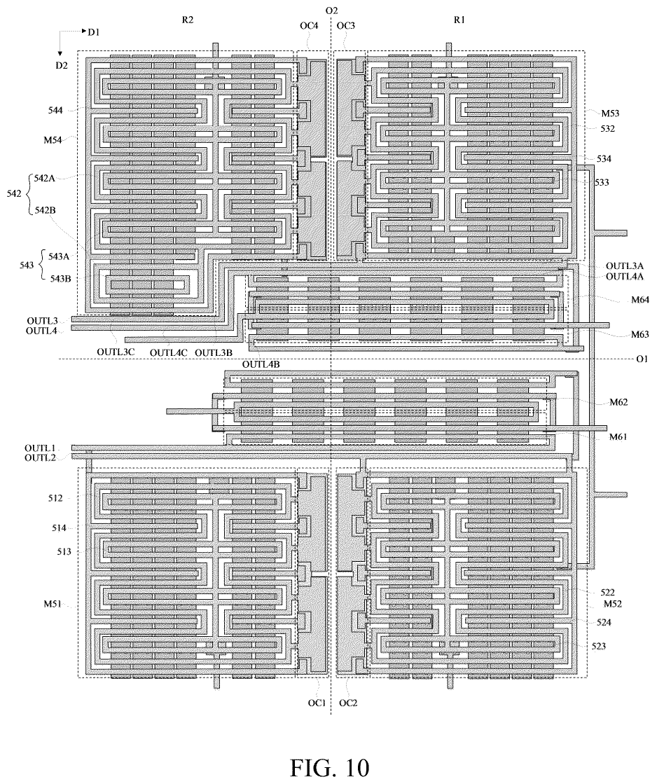

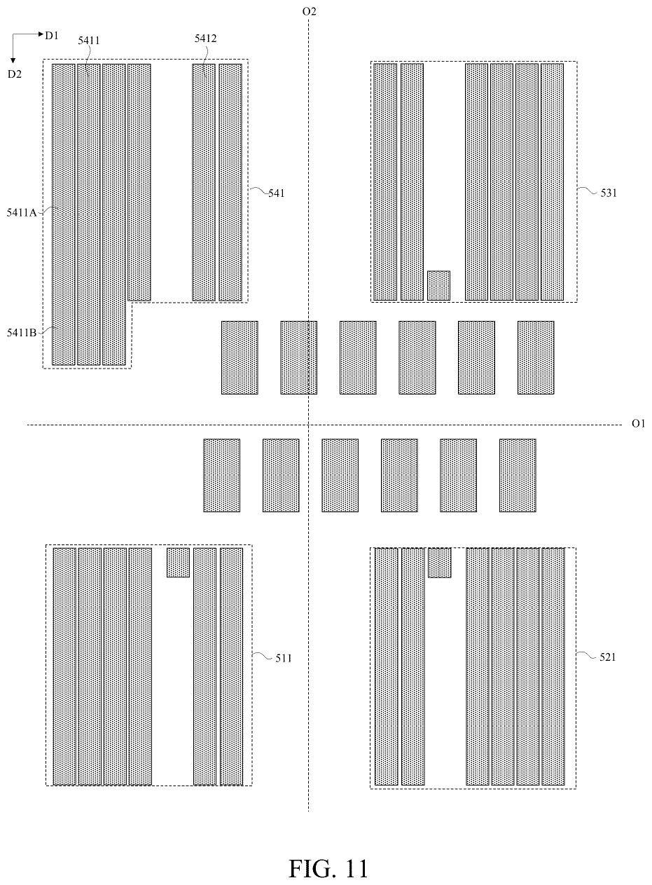

FIG. 9 is a first schematic diagram of a structure of an output drive circuit according to an embodiment of the present disclosure, and FIG. 10 is a second schematic diagram of a structure of an output drive circuit according to an embodiment of the present disclosure. The display substrate provided by the embodiment of the present disclosure may include: a first region and a second region. The first region is provided with pixel drive circuits arranged in an array, the second region is provided with a gate drive circuit configured to provide a drive signal to the pixel drive circuits. The gate drive circuit includes: a plurality of shift registers, and at least one stage of shift register includes: a pre-circuit and a drive output circuit. The pre-circuit is electrically connected to a signal input terminal, a reset signal terminal and a cascaded output signal terminal. The drive output circuit is electrically connected to N drive signal output terminals, a signal input terminal of at least one stage of shift register is electrically connected to a cascaded output signal terminal of at least one stage of shift register, a reset signal terminal of at least one stage of shift register is electrically connected to a cascaded output signal terminal of at least one stage of shift register.

In an exemplary implementation, the pixel drive circuits are the pixel drive circuit provided in FIG. 5 and the shift registers are the shift register provided in FIG. 7.

In an exemplary implementation, as shown in FIGS. 9 and 10, a drive output circuit includes: N drive output sub-circuits, an n-th drive output sub-circuit is electrically connected to an n-th drive signal output terminal. In at least one display frame, a start time of a drive signal output from an n-th drive signal output terminal is later than a start time of a drive signal output from at least one of a first drive signal output terminal to an (n−1)-th drive signal output terminal, N>2, 1≤n≤N. FIG. 9 and FIG. 10 illustrate an example in which N=4. For example, the start time of the drive signal output from the n-th drive signal output terminal is later than the start time of the drive signal output from an (n−1)-th drive signal output terminal, i.e., the start time of the drive signal output from a second drive signal output terminal is later than the start time of the drive signal output from a first drive signal output terminal, the start time of the drive signal output from a third drive signal output terminal is later than the start time of the drive signal output from the second drive signal output terminal, and the start time of the drive signal output from a fourth drive signal output terminal is later than the start time of the drive signal output from the third drive signal output terminal.

In an exemplary implementation, as shown in FIGS. 9 and 10, an area of the N-th drive output sub-circuit is larger than an area of at least one of the first drive output sub-circuit to the (N−1)-th drive output sub-circuit. For example, the first drive output sub-circuit includes: a first output transistor M51, a first output capacitor OC1 and a first noise reduction transistor M61. The second drive output sub-circuit includes: a second output transistor M52, a second output capacitor OC2 and a second noise reduction transistor M62. The third drive output sub-circuit includes: a third output transistor M53, a third output capacitor OC3 and a third noise reduction transistor M63. The fourth drive output sub-circuit includes: a fourth output transistor M54, a fourth output capacitor OC4 and a fourth noise reduction transistor M64.

In the present disclosure, by setting the area of the N-th drive output sub-circuit outputting the latest drive signal to be larger than the area of at least one of the first drive output sub-circuit to the (N−1)-th drive output sub-circuit, the driving capability of the N-th drive output sub-circuit can be improved, a duration of a time period where a falling edge of the drive signal output by the N-th drive output sub-circuit is located can be reduced, and the phenomenon of lateral stripes in the display substrate can be improved, thereby improving the display effect of the display substrate.

In an exemplary implementation, the display substrate may include: a base substrate and a drive structure layer arranged on the base substrate. The gate drive circuit and the pixel drive circuits are located on the drive structure layer, and the drive structure layer includes a semiconductor layer, a first conductive layer and a second conductive layer stacked sequentially on the base substrate. At least one drive output sub-circuit includes: an output transistor, a noise reduction transistor and an output capacitor. A transistor includes: an active pattern, a gate electrode, a first electrode and a second electrode, and the capacitor includes: a first plate and a second plate.

The semiconductor layer at least includes: an active pattern of an output transistor and an active pattern of a noise reduction transistor located in at least one drive output sub-circuit.

The first conductive layer at least includes: a second plate of an output capacitor located in at least one drive output sub-circuit.

The second conductive layer at least includes: a first plate of an output capacitor, a gate electrode, a first electrode and a second electrode of an output transistor, and a gate electrode, a first electrode and a second electrode of a noise reduction transistor located in at least one drive output sub-circuit.

In an exemplary implementation, as shown in FIG. 10, an area of an output transistor in the N-th drive output sub-circuit is larger than an area of an output transistor in at least one of the first drive output sub-circuit to the (N−1)-th drive output sub-circuit, and an area of an output capacitor in the N-th drive output sub-circuit is equal to an area of an output capacitor in at least one of the first drive output sub-circuit to the (N−1)-th drive output sub-circuit. For example, an area of the fourth output transistor M54 is larger than an area of at least one of the first output transistor M51 to the third output transistor M53, and an area of the fourth output capacitor OC4 is equal to an area of at least one of the first output capacitor OC1 to the third output capacitor OC3.

In an exemplary implementation, a width-to-length ratio of a channel region of an active pattern of the output transistor in the N-th drive output sub-circuit is greater than a width-to-length ratio of a channel region of an active pattern of an output transistor in at least one of the first drive output sub-circuit to the (N−1)-th drive output sub-circuit, thereby increasing the driving capability of the output transistor in the N-th drive output sub-circuit. For example, the width-to-length ratio of the channel region of the active pattern of the fourth output transistor M54 is greater than the width-to-length ratio of the channel region of the active pattern of at least one of the first output transistor M51 to the third output transistor M53.

In an exemplary implementation, the width-to-length ratio of the channel region of the active pattern of the output transistor in the first drive output sub-circuit is greater than a width-to-length ratio of a channel region of an active pattern of an output transistor in at least one of the second drive output sub-circuit to the (N−1)-th drive output sub-circuit. For example, the width-to-length ratio of the channel region of the active pattern of the first output transistor M51 is greater than width-to-length ratios of channel regions of the active patterns of the second output transistor M52 and the third output transistor M53.

In an exemplary implementation, width-to-length ratios of channel regions of active patterns of the output transistors in at least two of the second drive output sub-circuit to the (N−1)-th drive output sub-circuit are equal, which can ensure consistence in driving capability of the second drive output sub-circuit to the (N−1)-th drive output sub-circuit, and ensure the display uniformity of the display substrate. For example, the width-to-length ratio of the channel region of the active pattern of the second output transistor M52 is equal to the width-to-length ratio of the channel region of the active pattern of the third output transistor M53.

In an exemplary implementation, as shown in FIGS. 9 and 10, in at least one drive output sub-circuit, at least a portion of a gate electrode of an output transistor is of an annular structure, at least a portion of a first electrode of the output transistor is of an annular structure, the gate electrode of the output transistor surrounds the first electrode of the output transistor, and the second electrode of the output transistor surrounds at least one side of the gate electrode of the output transistor. For example, at least a portion of a gate electrode 512 of the first output transistor is of an annular structure, at least a portion of a first electrode 513 of the first output transistor is of an annular structure, the gate electrode 512 of the first output transistor surrounds the first electrode 513 of the first output transistor, and a second electrode 514 of the first output transistor surrounds at least one side of the gate electrode 512 of the first output transistor. At least a portion of a gate electrode 522 of the second output transistor is of an annular structure, at least a portion of a first electrode 523 of the second output transistor is of an annular structure, the gate electrode 522 of the second output transistor surrounds the first electrode 523 of the second output transistor, and a second electrode 524 of the second output transistor surrounds at least one side of the gate electrode 522 of the second output transistor. At least a portion of a gate electrode 532 of the third output transistor is of an annular structure, at least a portion of a first electrode 533 of the third output transistor is of an annular structure, the gate electrode 532 of the third output transistor surrounds the first electrode 533 of the third output transistor, and a second electrode 534 of the third output transistor surrounds at least one side of the gate electrode 532 of the third output transistor. At least a portion of a gate electrode 542 of the fourth output transistor is of an annular structure, at least a portion of a first electrode 543 of the fourth output transistor is of an annular structure, the gate electrode 542 of the fourth output transistor surrounds the first electrode 543 of the fourth output transistor, and a second electrode 544 of the fourth output transistor surrounds at least one side of the gate electrode 542 of the fourth output transistor.

In an exemplary implementation, as shown in FIGS. 9 and 10, in at least one drive output sub-circuit, the output capacitor is located on a side of the output transistor close to a second centerline O2, and the noise reduction transistor is located on a side of the output transistor close to a first centerline O1. The first centerline O1 is a centerline of an area occupied by the drive output circuit extending in a first direction D1, and the second centerline O2 is a centerline of an area occupied by the drive output circuit extending in a second direction D2. For example, the first output capacitor OC1 is located on a side of the first output transistor M51 close to the second centerline O2 the first noise reduction transistor M61 is located on a side of the first output transistor M51 close to the first centerline O1, the second output capacitor OC2 is located on a side of the second output transistor M52 close to the second centerline O2, the second noise reduction transistor M62 is located on a side of the second output transistor M52 close to the first centerline O1, the third output capacitor OC3 is located on a side of the third output transistor M53 close to the second centerline O2, the third noise reduction transistor M63 is located on a side of the third output transistor M53 close to the first centerline O1, the fourth output capacitor OC4 is located on a side of the fourth output transistor M54 close to the second centerline O2, and the fourth noise reduction transistor M64 is located on a side of the fourth output transistor M54 close to the first centerline O1.

In an exemplary implementation, as shown in FIG. 10, N=4, the output devices (i.e., the first output transistor M51 and the first output capacitor OC1) in the first drive output sub-circuit are arranged symmetrically with the output devices (i.e., the second output transistor M52 and the second output capacitor OC2) in the second drive output sub-circuit with respect to the second centerline O2. The output devices (i.e., the second output transistor M52 and the second output capacitor OC2) in the second drive output sub-circuit are arranged symmetrically with the output devices (i.e., the third output transistor M53 and the third output capacitor OC3) in the third drive output sub-circuit with respect to the first centerline O1. The output capacitor (i.e., the fourth output capacitor OC4) in the fourth drive output sub-circuit is arranged symmetrically with the output capacitor (i.e., the third output capacitor OC3) in the third drive output sub-circuit with respect to the second centerline O2. At least a portion of the output transistor (i.e., the fourth output transistor M54) in the fourth drive output sub-circuit is arranged symmetrically with the output transistor (i.e., the third output transistor M53) in the third drive output sub-circuit with respect to the second centerline O2. The output capacitor (i.e., the fourth output capacitor OC4) in the fourth drive output sub-circuit is arranged symmetrically with the output capacitor (i.e., the first output capacitor OC1) in the first drive output sub-circuit with respect to the first centerline O1. At least a portion of the output transistor (i.e., the fourth output transistor M54) in the fourth drive output sub-circuit is arranged symmetrically with the output transistor (i.e., the first output transistor M51) in the first drive output sub-circuit with respect to the first centerline O1.

In an exemplary implementation, as shown in FIG. 10, the noise reduction transistor (i.e., the first noise reduction transistor M61) of the first drive output sub-circuit and the noise reduction transistor (i.e., the second noise reduction transistor M62) of the second drive output sub-circuit are located on a side of the output devices (i.e., the first output transistor M51 and the first output capacitor OC1) of the first drive output sub-circuit close to the first centerline O1. The noise reduction transistor (i.e., the second noise reduction transistor M62) of the second drive output sub-circuit is located on a side of the noise reduction transistor (i.e., the first noise reduction transistor M61) of the first drive output sub-circuit close to the first centerline O1. The noise reduction transistor (i.e., the third noise reduction transistor M63) of the third drive output sub-circuit and the noise reduction transistor (i.e., the fourth noise reduction transistor M64) of the fourth drive output sub-circuit are located on a side of the output devices (i.e., the third output transistor M53 and the third output capacitor OC3) of the third drive output sub-circuit close to the first centerline O1. The noise reduction transistor (i.e., the third noise reduction transistor M63) of the third drive output sub-circuit is located on a side of the noise reduction transistor (i.e., the fourth noise reduction transistor M64) of the fourth drive output sub-circuit close to the first centerline O1.

In an exemplary implementation, as shown in FIG. 10, the noise reduction transistor (i.e., the first noise reduction transistor M61) of the first drive output sub-circuit is arranged asymmetrically with the noise reduction transistor (i.e., the fourth noise reduction transistor M64) of the fourth drive output sub-circuit with respect to the first centerline O1. The noise reduction transistor (i.e., the second noise reduction transistor M62) of the second drive output sub-circuit is arranged asymmetrically with the noise reduction transistor (i.e., the third noise reduction transistor M63) of the third drive output sub-circuit with respect to the first centerline O1.

In an exemplary implementation, as shown in FIG. 10, a region in which the drive output circuits are located is divided into a first region R1 and a second region R2 by the second centerline O2. The output devices (i.e., the first output transistor M51 and the first output capacitor OC1) of the first drive output sub-circuit and the output devices (i.e., the fourth output transistor M54 and the fourth output capacitor OC4) of the fourth drive output sub-circuit are located in the first region R1, and the output devices (i.e., the second output transistor M52 and the second output capacitor OC2) of the second drive output sub-circuit and the output devices (i.e., the third output transistor M53 and the third output capacitor OC3) of the third drive output sub-circuit are located in the second region R2.

In an exemplary implementation, as shown in FIG. 10, the noise reduction transistor (i.e., at least one of the first noise reduction transistor M61, the second noise reduction transistor M62, the third noise reduction transistor M63 and the fourth noise reduction transistor M64) of at least one of the first drive output sub-circuit to the fourth drive output sub-circuit is located in the first region R1 and the second region R2, and an area of the noise reduction transistor located in the first region R1 is smaller than an area of the noise reduction transistor located in the second region R2. For example, an area of the first noise reduction transistor M61 located in the first region R1 is smaller than an area of the first noise reduction transistor M61 located in the second region R2, an area of the second noise reduction transistor M62 located in the first region R1 is smaller than an area of the second noise reduction transistor M62 located in the second region R2, an area of the third noise reduction transistor M63 located in the first region R1 is smaller than an area of the third noise reduction transistor M63 located in the second region R2, and an area of the fourth noise reduction transistor M64 located in the first region R1 is smaller than an area of the fourth noise reduction transistor M64 located in the second region R2.

In an exemplary implementation, as shown in FIG. 10, the areas of the noise reduction transistors (i.e., the first noise reduction transistor M61 and the second noise reduction transistor M62) of the first drive output sub-circuit and the second drive output sub-circuit in the first region R1 are larger than the areas of the noise reduction transistors (i.e., the third noise reduction transistor M63 and the fourth noise reduction transistor M64) of the third drive output sub-circuit and the fourth drive output sub-circuit in the first region R1, and the areas of the noise reduction transistors (i.e., the first noise reduction transistor M61 and the second noise reduction transistor M62) of the first drive output sub-circuit and the second drive output sub-circuit in the second region R2 are smaller than the areas of the noise reduction transistors (i.e., the third noise reduction transistor M63 and the fourth noise reduction transistor M64) of the third drive output sub-circuit and the fourth drive output sub-circuit in the second region R2.

In an exemplary implementation, FIG. 11 is a schematic diagram of some film layers in FIG. 10. As shown in FIG. 11, an active pattern 541 of the output transistor (i.e., the fourth output transistor M54) of the fourth drive output sub-circuit includes: at least one first active pattern 5411 and at least one second active pattern 5412. A length of a first active pattern 5411 in the second direction D2 is greater than a length of a second active pattern 5412 in the second direction D2.

In an exemplary implementation, as shown in FIG. 11, the first active pattern 5411 includes: a first active portion 5411A and a second active portion 5411B. A length of the first active portion 5411A in the first direction D1 is equal to a length of the second active pattern 5412 in the first direction D1, and the second active portion 5411B is located on a side of the first active portion 5411a close to the first centerline O1.

In an exemplary implementation, as shown in FIG. 11, the first active portion and the second active pattern of the active pattern of the output transistor (i.e., the fourth output transistor M54) of the fourth drive output sub-circuit are arranged symmetrically with at least a portion of the active pattern 511 of the output transistor (i.e., the first output transistor M51) of the first drive output sub-circuit with respect to the first centerline O1, and the first active portion and the second active pattern of the active pattern of the output transistor (i.e., the fourth output transistor M54) of the fourth drive output sub-circuit are arranged symmetrically with the active pattern 531 of the output transistor (i.e., the third output transistor M53) of the third drive output sub-circuit with respect to the second centerline O2. The active pattern 511 of the first output transistor is arranged symmetrically with the active pattern 521 of the second output transistor with respect to the second centerline O2, and the active pattern 521 of the second output transistor is arranged symmetrically with the active pattern 531 of the third output transistor with respect to the first centerline O1.

In an exemplary implementation, as shown in FIG. 10, the first electrode 543 of the output transistor (i.e., the fourth output transistor M54) of the fourth drive output sub-circuit includes: a first electrode portion 543A and a second electrode portion 543B arranged at intervals. The first electrode portion 543A of the output transistor (i.e., the fourth output transistor M54) of the fourth drive output sub-circuit is arranged symmetrically with the first electrode 513 of the output transistor (i.e., the first output transistor M51) of the first drive output sub-circuit with respect to the first centerline O1, and the first electrode portion 543A of the output transistor (i.e., the fourth output transistor M54) of the fourth drive output sub-circuit is arranged symmetrically with the first electrode 533 of the output transistor (i.e., the third output transistor M53) of the third drive output sub-circuit.

In an exemplary implementation, with reference to FIGS. 10 and 11, the first electrode portion 543A and the second electrode portion 543B include: a closed loop structure. An orthographic projection of the first electrode portion 543A on the base substrate at least partially overlaps with orthographic projections of the first active portion 5411A and the second active pattern 5412 on the base substrate, and an orthographic projection of the second electrode portion 543B on the base substrate at least partially overlaps with an orthographic projection of the second active portion 5411B on the base substrate.

In an exemplary implementation, as shown in FIG. 10, an area of the first electrode portion 543A is larger than an area of the second electrode portion 543B.

In an exemplary implementation, as shown in FIG. 10, the gate electrode 542 of the output transistor (i.e., the fourth output transistor M54) of the fourth drive output sub-circuit includes: a first gate electrode portion 542A and a second gate electrode portion 542B connected to each other. The first gate electrode portion 542A of the gate electrode of the output transistor of the fourth drive output sub-circuit is arranged symmetrically with the gate electrode 512 of the output transistor (i.e., the first output transistor) of the first drive output sub-circuit with respect to the first centerline O1, and the first gate electrode portion 542A of the gate electrode 542 of the output transistor (i.e., the fourth output transistor M54) of the fourth drive output sub-circuit is arranged symmetrically with the gate electrode 532 of the output transistor (i.e., the third output transistor M53) of the third drive output sub-circuit with respect to the second centerline O2. The gate electrode 512 of the first output transistor is arranged symmetrically with the gate electrode 522 of the second output transistor with respect to the second centerline O2, and the gate electrode 522 of the second output transistor is arranged symmetrically with the gate electrode 532 of the third output transistor with respect to the first centerline O1.

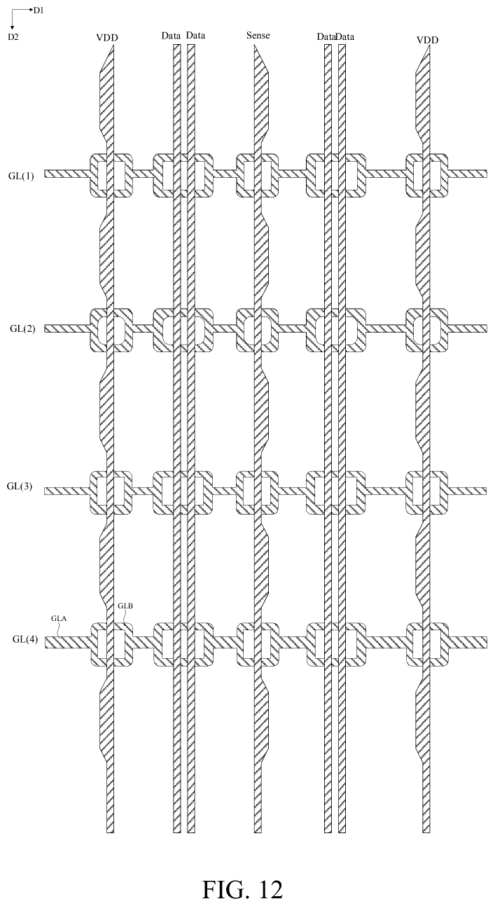

In an exemplary implementation, with reference to FIGS. 10 and 12, the first gate electrode portion 542A and the second gate electrode portion 542B include: a closed loop structure. An orthographic projection of the first gate electrode portion 542A on the base substrate at least partially overlaps with orthographic projections of the first active portion 5411A and the second active pattern 5412 on the base substrate, and an orthographic projection of the second gate electrode portion 542B on the base substrate at least partially overlaps with an orthographic projection of the second active portion 5411B on the base substrate. The first gate electrode portion 542A surrounds the first electrode portion 543A, and the second gate electrode portion 542B surrounds the second electrode portion 543B.

In an exemplary implementation, as shown in FIG. 10, an area of the first gate electrode portion 542A is larger than an area of the second gate electrode portion 542B.

In an exemplary implementation, as shown in FIG. 10, a virtual straight line extending in the first direction D1 through the noise reduction transistor (i.e., the fourth noise reduction transistor M64) of the fourth drive output sub-circuit passes through the output transistor (i.e., the fourth output transistor M54) of the fourth drive output sub-circuit. The virtual straight line extending in the first direction D1 through the noise reduction transistor (i.e., the fourth noise reduction transistor M64) of the fourth drive output sub-circuit passes through the second gate electrode portion 542B and the second electrode portion 543B.

In an exemplary implementation, as shown in FIG. 10, the second region may further include: output connection lines. The output connection lines may include: a first output connection line OUTL1 to a fourth output connection line OUTL4. The first drive output sub-circuit is connected to the first output connection line OUTL1, the second drive output sub-circuit is connected to a second output connection line OUTL2, the third drive output sub-circuit is connected to a third output connection line OUTL3, and the fourth drive output sub-circuit is connected to the fourth output connection line OUTL4.

In an exemplary implementation, as shown in FIG. 10, the first output connection line OUTL1 and the second output connection line OUTL2 are located between the output transistor (i.e., the first output transistor M51) of the first drive output sub-circuit and the noise reduction transistor (i.e., the first noise reduction transistor M61) of the first drive output sub-circuit. The third output connection line OUTL3 and the fourth output connection line OUTL4 are located between the output transistor (i.e., the fourth output transistor M54) of the fourth drive output sub-circuit and the noise reduction transistor (i.e., the fourth noise reduction transistor M64) of the fourth drive output sub-circuit.

In an exemplary implementation, as shown in FIG. 10, the output connection lines are located on the second conductive layer.

In an exemplary implementation, as shown in FIG. 10, the first output connection line OUTL1 and the second output connection line OUTL2 extend in the first direction D1, and the third output connection line OUTL3 and the fourth output connection line OUTL4 are in a shape of a bend line and extend at least partially in the first direction D1.

In an exemplary implementation, as shown in FIG. 10, the third output connection line OUTL3 includes: a first output connection portion OUTL3A, a second output connection portion OUTL3B and a third output connection portion OUTL3C. The first output connection portion OUTL3A and the third output connection portion OUTL3C extend in the first direction D1, the second output connection portion OUTL3B extends in the second direction D2, and the second output connection portion OUTL3B is electrically connected to the first output connection portion OUTL3A and the third output connection portion OUTL3C respectively.

In an exemplary implementation, as shown in FIG. 10, the fourth output connection line OUTL4 includes: a first output connection portion OUTL4A, a second output connection portion OUTL4B and a third output connection portion OUTL4C. The first output connection portion OUTL4A and the third output connection portion OUTL4C extend in the first direction D1, the second output connection portion OUTL4B extends in the second direction D2, and the second output connection portion OUTL4B is electrically connected to the first output connection portion OUTL4A and the third output connection portion OUTL4C.

In an exemplary implementation, as shown in FIG. 9, an area of an output capacitor in the N-th drive output sub-circuit is larger than an area of an output capacitor in at least one of the first drive output sub-circuit to the (N−1)-th drive output sub-circuit. An area of the output transistor in the N-th drive output sub-circuit is equal to an area of the output transistor in at least one of the first drive output sub-circuit to the (N−1)-th drive output sub-circuit. For example, the area of the fourth output capacitor OC4 is larger than the area of at least one of the first output capacitor OC1 to the third output capacitor OC3, and the area of the fourth output transistor M54 is equal to the area of at least one of the first output transistor M51 to the third output transistor M53.

In an exemplary implementation, as shown in FIG. 9, N=4, the first drive output sub-circuit to the third output sub-circuit includes: one output capacitor, and the fourth drive output sub-circuit includes: two output capacitors. The output devices (i.e., the first output transistor M51 and the first output capacitor OC1) in the first drive output sub-circuit are arranged symmetrically with the output devices (i.e., the second output transistor M52 and the second output capacitor OC2) in the second drive output sub-circuit with respect to the second centerline O2. The output devices (i.e., the second output transistor M52 and the second output capacitor OC2) in the second drive output sub-circuit are arranged symmetrically with the output devices (i.e., the third output transistor M53 and the third output capacitor OC3) in the third drive output sub-circuit with respect to the first centerline O1. The output devices (i.e., the fourth output transistor M54 and one of the fourth output capacitors OC4) in the fourth drive output sub-circuit are arranged symmetrically with the output devices (i.e., the third output transistor M53 and the third output capacitor OC3) in the third drive output sub-circuit with respect to the second centerline O2. The output devices (i.e., the fourth output transistor M54 and one of the fourth output capacitors OC4) in the fourth drive output sub-circuit are arranged symmetrically with the output devices (i.e., the first output transistor M51 and the first output capacitor OC1) in the first drive output sub-circuit with respect to the first centerline O1.

In an exemplary implementation, as shown in FIG. 9, the noise reduction transistor (i.e., the first noise reduction transistor M61) of the first drive output sub-circuit and the noise reduction transistor (i.e., the second noise reduction transistor M62) of the second drive output sub-circuit are located on a side of the output devices (i.e., the first output transistor M51 and the first output capacitor OC1) of the first drive output sub-circuit close to the first centerline O1. The noise reduction transistor (i.e., the second noise reduction transistor M62) of the second drive output sub-circuit is located on a side of the noise reduction transistor (i.e., the first noise reduction transistor M61) of the first drive output sub-circuit close to the first centerline O1. The noise reduction transistor (i.e., the third noise reduction transistor M63) of the third drive output sub-circuit and the noise reduction transistor (i.e., the fourth noise reduction transistor M64) of the fourth drive output sub-circuit are located on a side of the output devices (i.e., the third output transistor M53 and the third output capacitor OC3) of the third drive output sub-circuit close to the first centerline O1. The noise reduction transistor (i.e., the third noise reduction transistor M63) of the third drive output sub-circuit is located on a side of the noise reduction transistor (i.e., the fourth noise reduction transistor M64) of the fourth drive output sub-circuit close to the first centerline O1, and the other output capacitor OC4 of the fourth drive output sub-circuit is located on a side of the output devices (i.e., the fourth output transistor M54 and one of the fourth output capacitors OC4) of the fourth drive output sub-circuit close to the first centerline O1.

In an exemplary implementation, as shown in FIG. 9, the noise reduction transistor (i.e., the first noise reduction transistor M61) of the first drive output sub-circuit is arranged symmetrically with the noise reduction transistor (i.e., the fourth noise reduction transistor M64) of the fourth drive output sub-circuit with respect to the first centerline O1, and the noise reduction transistor (i.e., the second noise reduction transistor M62) of the second drive output sub-circuit is arranged symmetrically with the noise reduction transistor (i.e., the third noise reduction transistor M63) of the third drive output sub-circuit with respect to the first centerline O1.

In an exemplary implementation, as shown in FIG. 9, the region in which the drive output circuits are located is divided into a first region R1 and a second region R2 by the second centerline O2. The output devices (i.e., the first output transistor M51 and the first output capacitor OC1) of the first drive output sub-circuit, the output devices (i.e., the fourth output transistor M54 and one of the output capacitors OC4) and the other output capacitor OC4 of the fourth drive output sub-circuit are located in the first region R1, and the output devices (i.e., the second output transistor M52 and the second output capacitor OC2) of the second drive output sub-circuit and the output devices (i.e., the third output transistor M53 and the third output capacitor OC3) of the third drive output sub-circuit are located in the second region R2.

In an exemplary implementation, as shown in FIG. 9, the noise reduction transistor of at least one of the first drive output sub-circuit to the fourth drive output sub-circuit is located in the first region R1 and the second region R2, and an area of the noise reduction transistor located in the first region R1 is smaller than an area of the noise reduction transistor located in the second region R2. That is, an area of the first noise reduction transistor M61 located in the first region R1 is smaller than an area of the first noise reduction transistor M61 located in the second region R2. An area of the second noise reduction transistor M62 located in the first region R1 is smaller than an area of the second noise reduction transistor M62 located in the second region R2. An area of the third noise reduction transistor M63 located in the first region R1 is smaller than an area of the third noise reduction transistor M63 located in the second region R2. An area of the fourth noise reduction transistor M64 located in the first region R1 is smaller than an area of the fourth noise reduction transistor M64 located in the second region R2.

In an exemplary implementation, the area of the noise reduction transistor located in the second region R2 is within a range of 1 to 3 times the area of the noise reduction transistor located in the first region R1. For example, the area of the noise reduction transistor located in the second region R2 may be twice the area of the noise reduction transistor located in the first region R1.

In an exemplary implementation, as shown in FIG. 9, the second region further includes: output connection lines. The output connection lines include: a first output connection line OUTL1 to a fourth output connection line OUTL4. The first drive output sub-circuit is connected to the first output connection line OUTL1, the second drive output sub-circuit is connected to the second output connection line OUTL2, the third drive output sub-circuit is connected to the third output connection line OUTL3, and the fourth drive output sub-circuit is connected to the fourth output connection line OUTL4.

In an exemplary implementation, as shown in FIG. 9, the output connection lines extend in the first direction D1. For example, at least one of the first output connection line OUTL1 to the fourth output connection line OUTL4 extends in the first direction D1.

In an exemplary implementation, as shown in FIG. 9, the first output connection line OUTL1 and the second output connection line OUTL2 are located between the output devices (i.e., the first output transistor M51 and the first output capacitor OC1) of the first drive output sub-circuit and the noise reduction transistor (i.e., the first noise reduction transistor M61) of the first drive output sub-circuit. The third output connection line OUTL3 and the fourth output connection line OUTL4 are located between the output devices (i.e., the fourth output transistor M54 and one of the output capacitors OC4) of the fourth drive output sub-circuit and the noise reduction transistor (i.e., the fourth noise reduction transistor M64) of the fourth drive output sub-circuit.

In an exemplary implementation, as shown in FIG. 9, the other output capacitor (i.e., the other fourth output capacitor OC4) and the noise reduction transistor (i.e., the fourth noise reduction transistor M64) of the fourth drive output sub-circuit are located on a same side of the third output connection line OUTL3 and the fourth output connection line OUTL4.

In an exemplary implementation, as shown in FIG. 9, the first output connection line OUTL1 and the second output connection line OUTL2 may be located on the second conductive layer.

In an exemplary implementation, as shown in FIG. 9, the third output connection line OUTL3 includes: a first output connection portion OUTL3A, a second output connection portion OUTL3B and a third output connection portion OUTL3C. The first output connection portion OUTL3A, the second output connection portion OUTL3B and the third output connection portion OUTL3C extend in the first direction D1, and the second output connection portion OUTL3B is electrically connected to the first output connection portion OUTL3A and the third output connection portion OUTL3C respectively. The first output connection portion OUTL3A and the third output connection portion OUTL3C may be located on the second conductive layer, and the second output connection portion OUTL3B may be located on the first conductive layer.

In an exemplary implementation, as shown in FIG. 9, the fourth output connection line OUTL4 includes: a first output connection portion OUTL4A, a second output connection portion OUTL4B and a third output connection portion OUTL4C. The first output connection portion OUTL4A, the second output connection portion OUTL4B and the third output connection portion OUTL4C extend in the first direction D1, and the second output connection portion OUTL4B is electrically connected to the first output connection portion OUTL4A and the third output connection portion OUTL4C respectively. The first output connection portion OUTL4A and the third output connection portion OUTL4C are located on the second conductive layer, and the second output connection portion OUTL4B is located on the first conductive layer.

In an exemplary implementation, the manner in which the fourth drive output sub-circuit is arranged in FIGS. 9 and 10 can prevent the shift register from occupying a large space, which may improve a space utilization of the shift register.

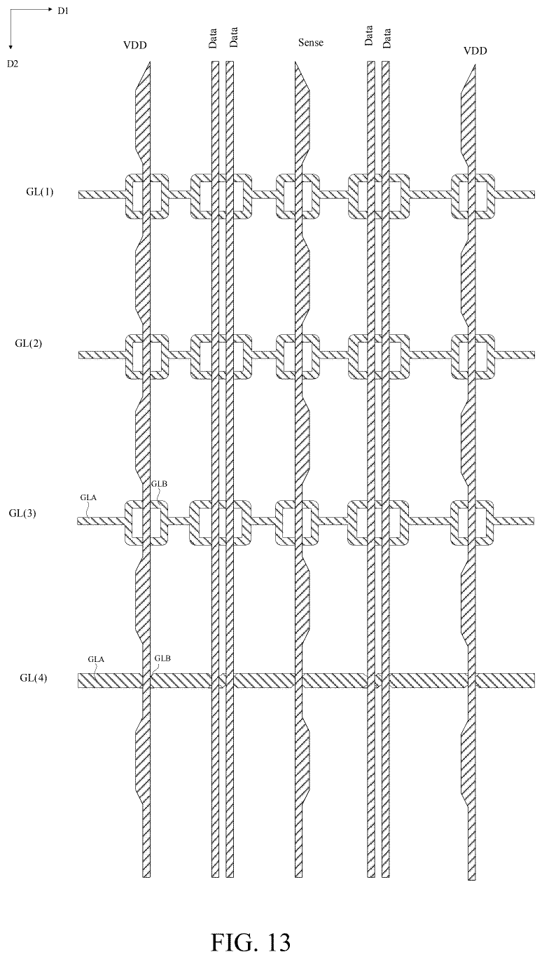

In an exemplary implementation, FIG. 12 is a first schematic diagram of part of a structure in a first region of a display substrate, and FIG. 13 is a second schematic diagram of part of a structure in a first region of a display substrate. As shown in FIGS. 12 and 13, the first region is provided with at least one first signal line and at least one second signal line. The pixel drive circuit is electrically connected to the at least one first signal line and the at least one second signal line. The at least one first signal line extends at least partially in the first direction D1, and the at least one second signal line extends at least partially in the second direction D2. The at least one first signal line at least includes: a scan signal line GL, the at least one second signal line at least includes: a first power supply line VDD, a sensing signal line Sense and a data signal line Data, and at least one drive output sub-circuit in the shift register is electrically connected to at least one first signal line. FIGS. 12 and 13 illustrate an example in which N=4, and one drive signal output terminal is connected to one scan signal line GL. In FIGS. 12 and 13, GL(1) is a scan signal line connected to a first drive output sub-circuit of a first stage of shift register, GL(2) is a scan signal line connected to a second drive output sub-circuit of the first stage of shift register, GL(3) is a scan signal line connected to a third drive output sub-circuit of the first stage of shift register, and GL(4) is a scan signal line connected to the fourth drive output sub-circuit of the first stage of shift register.

In an exemplary implementation, the at least one first signal line may be located on the first conductive layer, the at least one second signal line may be located on the second conductive layer, or the at least one first signal line and the at least one second signal line may also be located on the other film layers, which is not limited in any way in the present disclosure.

In an exemplary implementation, as shown in FIGS. 12 and 13, at least one scan signal line GL includes: a plurality of signal connection lines GLA and a plurality of signal overlapping lines GLB. The plurality of signal connection lines GLA and the plurality of signal overlapping lines GLB are arranged alternately in the first direction D1. The signal connection lines GLA are arranged in the first direction D1, and an orthographic projection of a signal overlapping line GLB on the base substrate at least partially overlaps with an orthographic projection of at least one second signal line on the base substrate.

In an exemplary implementation, as shown in FIGS. 12 and 13, a line width of a signal connection line GLA of a scan signal line GL connected to at least one of the first drive output sub-circuit to the (N−1)-th drive output sub-circuit in at least one stage of shift register is smaller than a line width of a signal connection line GLA of a scan signal line GL connected to the N-th drive output sub-circuit. For example, line widths of signal connection lines GLA of the scan signal lines GL(1) to GL(3) are smaller than a line width of a signal connection line GLA of the scan signal line GL(4).

In an exemplary implementation, as shown in FIGS. 12 and 13, for at least one stage of shift register, the line width of the signal connection line GLA of the scan signal line GL connected to the N-th drive output sub-circuit is within a range of 1.5 to 2 times the line width of the signal connection line GLA of the scan signal line GL connected to at least one of the first drive output sub-circuit to the (N−1)-th drive output sub-circuit. For example, the line width of the signal connection line GLA of the scan signal line GL(4) is 1.5 to 2 times the line width of the signal connection lines GLA of the scan signal lines GL(1) to GL(3).

In an exemplary implementation, as shown in FIG. 12, for at least one stage of shift register, the signal overlapping lines GLB of the scan signal lines GL connected to the first drive output sub-circuit to the N-th drive output sub-circuit are of an annular structure. For at least one scan signal line GL, a length of a signal overlapping line GLB in the first direction D1 is greater than a line width of at least one second signal line, and a length of the signal overlapping line GLB in the second direction D2 is greater than a line width of the signal connection line GLA. For example, the signal overlapping lines GLB of the scan signal lines GL(1) to GL(4) are each of an annular structure. The signal overlapping line being of an annular structure in the present disclosure can reduce an area of an overlapping region between the scan signal lines and the second signal lines, reduce crosstalk between the signal lines, and improve reliability of the display substrate.

In an exemplary implementation, as shown in FIG. 13, for at least one stage of shift register, the signal overlapping lines GLB of the scan signal lines GL connected to at least one of the first drive output sub-circuit to the (N−1)-th drive output sub-circuit are of an annular structure. For the scan signal line GL connected to the first drive output sub-circuit to the (N−1)-th drive output sub-circuit. A length of a signal overlapping line GLB in the first direction D1 is greater than a line width of at least one second signal line, and a length of the signal overlapping line GLB in the second direction D2 is greater than a line width of a signal connection line GLA. For example, the signal overlapping lines GLB of the scan signal lines GL(1) to GL(4) are each of an annular structure.

In an exemplary implementation, as shown in FIG. 13, the signal overlapping lines GLB of the scan signal line GL connected to the N-th drive output sub-circuit extend in the first direction D1, and at least one boundary is arc-shaped. An average line width of the signal overlapping lines GLB of the scan signal line GL connected to the N-th drive output sub-circuit is smaller than the line width of the signal connection line GLA of the scan signal line GL connected to the N-th drive output sub-circuit. The average line width of the signal overlapping lines GLB of the scan signal line GL connected to the N-th drive output sub-circuit being smaller than the line width of the signal connection line GLA of the scan signal line GL connected to the N-th drive output sub-circuit can reduce resistance and capacitance loads of the scan signal line connected to the last drive output sub-circuit in the shift register, can improve display uniformity of sub-pixels driven by the shift register, and can improve the reliability of the display substrate.

The manner in which the scan signal line GL connected to the N-th drive output sub-circuit is arranged in FIGS. 12 and 13 can reduce the difference between the signals transmitted by the plurality of scan signal lines connected to the shift register, and can improve the display uniformity of the display substrate.

In an exemplary implementation, the drive output circuit is further electrically connected to N output clock signal terminals, and an n-th drive output sub-circuit is electrically connected to an n-th output clock signal terminal.

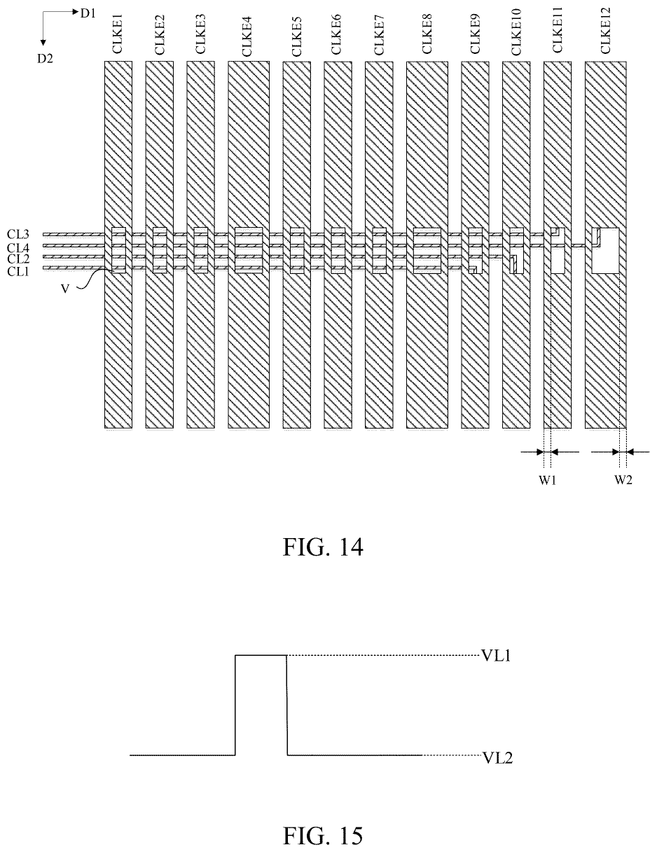

The present disclosure further provides a display substrate, including: a first region and a second region. The first region is provided with pixel drive circuits arranged in an array, the second region is provided with a gate drive circuit configured to provide a drive signal to the pixel drive circuits. The gate drive circuit includes: a plurality of shift registers, and at least one stage of shift register includes: a pre-circuit and a drive output circuit. The pre-circuit is electrically connected to a signal input terminal, a reset signal terminal and a cascaded output signal terminal, and the drive output circuit is electrically connected to N output clock signal terminals. A signal input terminal of at least one stage of shift register is electrically connected to a cascaded output signal terminal of at least one stage of shift register. A reset signal terminal of at least one stage of shift register is electrically connected to a cascaded output signal terminal of at least one stage of shift register. The drive output circuit includes: N drive output sub-circuits, and an n-th drive output sub-circuit is electrically connected to an n-th output clock signal terminal. FIG. 14 is a schematic diagram of part of a second region of a display apparatus. As shown in FIG. 14, the second region of the display substrate is provided with M*N output clock signal lines, and at least one output clock signal line extends at least partially in the second direction D2, and is located on a side of the drive output circuit away from the first region, M≥2. FIG. 14 illustrates an example in which M=3 and N=4, and FIG. 14 includes: a first output clock signal line CLKE1 to a twelfth output clock signal line CLKE12.

In an exemplary implementation, the display substrate may further include: a base substrate and a drive structure layer arranged on the base substrate. The gate drive circuit and the pixel drive circuit are located on the drive structure layer, and the drive structure layer includes: a semiconductor layer, a first conductive layer and a second conductive layer stacked sequentially on the base substrate. The output clock signal lines may be located on the second conductive layer.

In an exemplary implementation, as shown in FIG. 14, the first output clock signal terminal to the N-th output clock signal terminal of at least one stage of shift register are electrically connected to N output clock signal lines respectively. In FIG. 14, the first output clock signal terminal is electrically connected to the ninth output clock signal line CLKE9, the second output clock signal terminal is electrically connected to the tenth output clock signal line CLKE10, the third output clock signal terminal is electrically connected to the eleventh output clock signal line CLKE11, and the fourth output clock signal terminal is electrically connected to the twelfth output clock signal line CLKE12.

In an exemplary implementation, as shown in FIG. 14, for at least one stage of shift register, a line width of an output clock signal line connected to the N-th output clock signal terminal is larger than a line width of an output clock signal line connected to at least one of the first output clock signal terminal to an (N−1)-th output clock signal terminal. For example, a line width of the twelfth output clock signal line CLKE12 is greater than a line width of at least one of the ninth output clock signal line CLKE9 to the eleventh output clock signal line CLKE11.

In an exemplary implementation, an n-th output clock signal terminal of at least one stage of shift register is electrically connected to one of an n-th output clock signal line, and an (N+n)-th output clock signal line to an (M−1)*N+n-th output clock signal line, and n-th output clock signal terminals of adjacent M stages of shift registers are connected to different output clock signal lines. For example, taking M=3 and N=4 as an example, every three stages of shift registers are taken as a repeating unit, for the first stage of shift register in every three stages of shift registers, the first output clock signal terminal is electrically connected to the first output clock signal line CLKE1, the second output clock signal terminal is electrically connected to the second output clock signal line CLKE2, the third output clock signal terminal is electrically connected to the third output clock signal line CLKE3, and the fourth output clock signal terminal is electrically connected to the fourth output clock signal line CLKE4. For the second stage of shift register in every three stages of shift registers, the first output clock signal terminal is electrically connected to the fifth output clock signal line CLKE5, the second output clock signal terminal is electrically connected to the sixth output clock signal line CLKE6, the third output clock signal terminal is electrically connected to the seventh output clock signal line CLKE7, and the fourth output clock signal terminal is electrically connected to the eighth output clock signal line CLKE8. For the third stage of shift register in every three stages of shift registers, the first output clock signal terminal is electrically connected to the ninth output clock signal line CLKE9, the second output clock signal terminal is electrically connected to the tenth output clock signal line CLKE10, the third output clock signal terminal is electrically connected to the eleventh output clock signal line CLKE11, and the fourth output clock signal terminal is electrically connected to the twelfth output clock signal line CLKE12. Taking M=4 and N=4 as examples, every four stages of shift registers are taken as a repeating unit, for the first stage of shift register in every four stages of shift registers, the first output clock signal terminal is electrically connected to the first output clock signal line, the second output clock signal terminal is electrically connected to the second output clock signal line, the third output clock signal terminal is electrically connected to the third output clock signal line, and the fourth output clock signal terminal is electrically connected to the fourth output clock signal line. For the second stage of shift register in every four stages of shift registers, the first output clock signal terminal is electrically connected to the fifth output clock signal line, the second output clock signal terminal is electrically connected to the sixth output clock signal line, the third output clock signal terminal is electrically connected to the seventh output clock signal line, and the fourth output clock signal terminal is electrically connected to the eighth output clock signal line. For the third stage of shift register in every four stages of shift registers, the first output clock signal terminal is electrically connected to the ninth output clock signal line, the second output clock signal terminal is electrically connected to the tenth output clock signal line, the third output clock signal terminal is electrically connected to the eleventh output clock signal line, and the fourth output clock signal terminal is electrically connected to the twelfth output clock signal line. For the fourth stage of shift register in every four stages of shift registers, the first output clock signal terminal is electrically connected to the thirteenth output clock signal line CLKE13, the second output clock signal terminal is electrically connected to the fourteenth output clock signal line CLKE14, the third output clock signal terminal is electrically connected to the fifteenth output clock signal line CLKE15, and the fourth output clock signal terminal is electrically connected to the sixteenth output clock signal line CLKE16. That is, the N-th drive output sub-circuit is electrically connected to an output signal line whose ordinal number is an integral multiple of N.

In an exemplary implementation, as shown in FIG. 14, at least one output clock signal line is provided with a via V. A length in the first direction D1 of a via in an output clock signal line connected to at least one of a first output clock signal terminal to an (N−1)-th output clock signal terminal of at least one stage of shift register is smaller than a length in the first direction D1 of a via in an output clock signal line connected to an N-th output clock signal terminal of at least one stage of shift register.

In an exemplary implementation, as shown in FIG. 14, a via correlation distance W1 of an output clock signal line connected to at least one of a first output clock signal terminal to an (N−1)-th output clock signal terminal of at least one stage of shift register is equal to a via correlation distance W2 of an output clock signal line connected to an N-th output clock signal terminal of at least one stage of shift register, wherein the via correlation distance is a distance between a boundary of an output clock signal line and a boundary of a via of the output clock signal line.

In an exemplary implementation, as shown in FIG. 14, the second region further includes: a plurality of clock connection lines, the clock connection lines include: a first clock connection line to an N-th clock connection line, and the clock connection lines are located on the first conductive layer. FIG. 14 illustrates an example in which N=4, and the clock connection lines include: a first clock connection line CL1 to a fourth clock connection line CL4.

In an exemplary implementation, as shown in FIG. 14, at least one stage of shift register is electrically connected to a connected n-th output clock signal line through an n-th clock connection line, and an orthographic projection of at least one clock connection line on the base substrate at least partially overlaps with an orthographic projection of a via of at least one output clock signal line on the base substrate.

In the present disclosure, W1=W2 can ensure that the overlapping regions between each output clock signal line and any clock signal line are the same, which can maintain good uniformity of parasitic capacitances in the shift register, and ensure the reliability of the shift register.

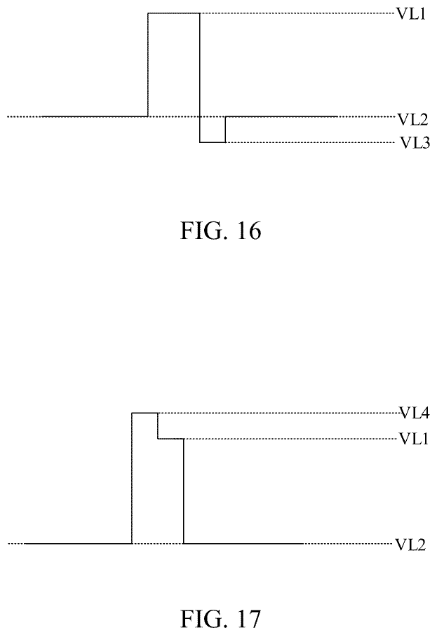

In an exemplary implementation, FIG. 15 is a signal schematic diagram of a first clock signal, and FIG. 16 is a signal schematic diagram of a second clock signal. As shown in FIGS. 15 and 16, the second region further includes: a data unit. The data unit is electrically connected to output clock signal lines connected to N drive output sub-circuits of at least one stage of shift register and configured to provide a first clock signal to output clock signal lines connected to a second drive output sub-circuit to an (N−1)-th drive output sub-circuit of the at least one stage of shift register, and to provide a second clock signal to an output clock signal line connected to an N-th drive output sub-circuit of the at least one stage of shift register. The first clock signal includes: a first rising edge and a first falling edge, and the second clock signal includes: a second rising edge, a third rising edge and a second falling edge.

In an exemplary implementation, as shown in FIG. 15, in a time period where the first rising edge is located, a voltage of the first clock signal rises from a second voltage VL2 to a first voltage VL1, and in a time period where the first falling edge is located, the voltage of the first clock signal falls from the first voltage VL1 to the second voltage VL2.

In an exemplary implementation, as shown in FIG. 16, in a time period where the second rising edge is located, a voltage of the second clock signal rises from a third voltage VL3 to the second voltage VL2, in a time period where the third rising edge is located, the voltage of the second clock signal rises from the second voltage VL2 to the first voltage VL1, and in a time period where the second falling edge is located, the voltage of the second clock signal falls from the first voltage VL1 to the third voltage VL3.

In the present disclosure, by providing the second clock signal described above, the drive signal output from the N-th drive output sub-circuit can be rapidly dropped to a lower potential, and the falling edge of the drive signal output from the N-th drive output sub-circuit can be shortened, thereby realizing uniformity of the plurality of drive signals output by the shift register and improving the reliability of the display substrate.

In an exemplary implementation, the first voltage VL1 is a positive voltage, the second voltage VL2 and the third voltage VL3 are negative voltages, and an absolute value of the second voltage VL2 is smaller than an absolute value of the third voltage VL3. For example, the first voltage VL1 may be 24 volts, the second voltage VL2 may be −6 volts, and the third voltage VL3 may be −8 volts.

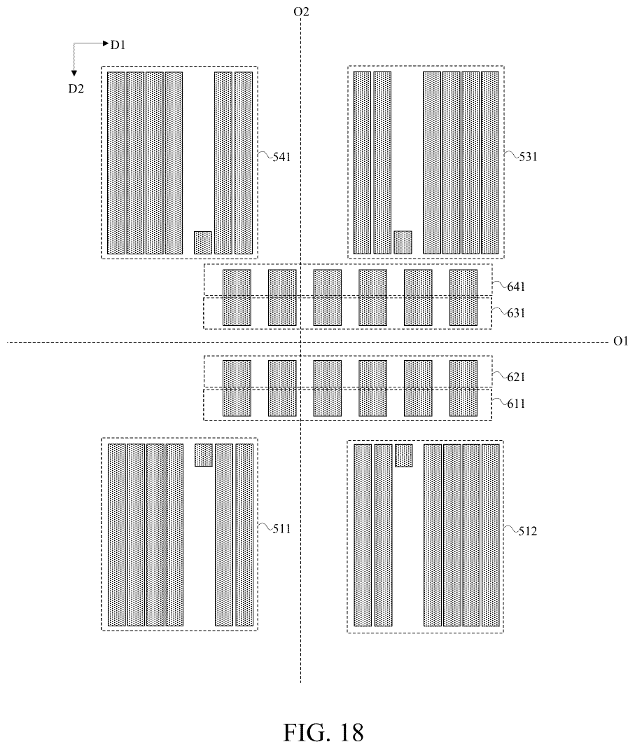

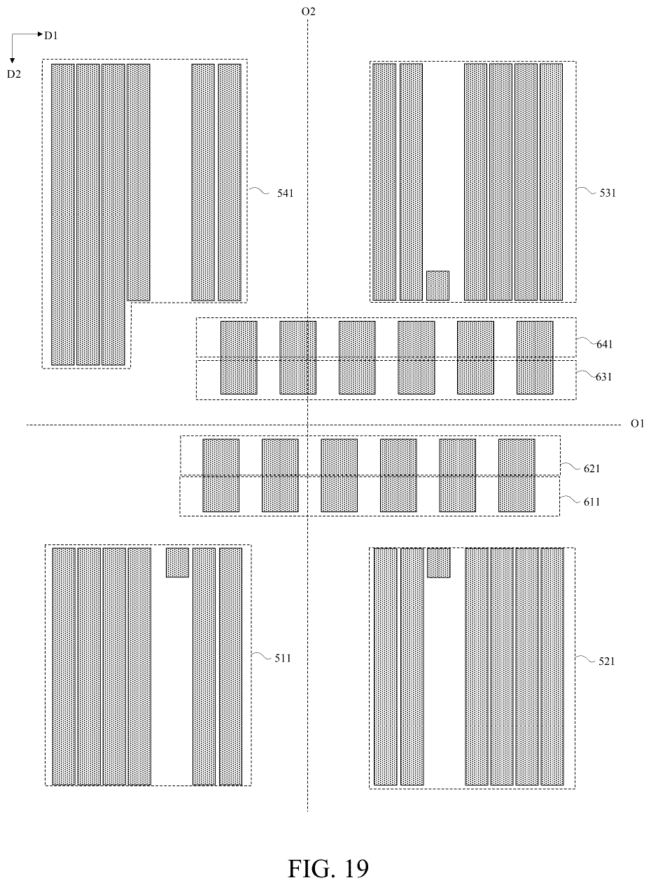

In an exemplary implementation, FIG. 17 is a signal schematic diagram of a third clock signal. As shown in FIG. 17, the data unit is further configured to provide a third clock signal to an output clock signal line connected to a first drive output sub-circuit of at least one stage of shift register, and the third clock signal includes: a fourth rising edge, a third falling edge and a fourth falling edge. In a time period where the fourth rising edge is located, a voltage of the third clock signal rises from the second voltage VL2 to a fourth voltage VL4, in a time period where the third falling edge is located, the voltage of the third clock signal falls from the fourth voltage VL4 to the first voltage VL1, and in a time period where the fourth falling edge is located, the voltage of the third clock signal falls from the first voltage VL1 to the second voltage VL2.

In an exemplary implementation, the fourth voltage is a positive voltage, and the fourth voltage is greater than the first voltage. For example, the fourth voltage may be 26 volts.

In the present disclosure, by providing the third clock signal described above, the drive signal output from the first drive output sub-circuit can be rapidly risen to a higher potential, and the rising edge of the drive signal output from the first drive output sub-circuit can be shortened, thereby realizing uniformity of the plurality of drive signals output by the shift register and improving the reliability of the display substrate.

In an exemplary implementation, the second region further includes: a data unit, the data unit is electrically connected to output clock signal lines connected to N drive output sub-circuits of at least one stage of shift register and configured to provide a fourth clock signal to output clock signal lines connected to a second drive output sub-circuit to an (N−1)-th drive output sub-circuit of the at least one stage of shift register, and to provide a fifth clock signal to an output clock signal line connected to an N-th drive output sub-circuit of the at least one stage of shift register. The duration of a time period where a falling edge of the fifth clock signal is located is smaller than a half of a duration of a time period where a falling edge of the fourth clock signal is located.

In the present disclosure, by providing the fifth clock signal described above, the drive signal output from the N-th drive output sub-circuit can drop rapidly, and the falling edge of the drive signal output from the N-th drive output sub-circuit can be shortened, thereby realizing uniformity of the plurality of drive signals output by the shift register and improving the reliability of the display substrate.

In an exemplary implementation, the data unit is further configured to provide a sixth clock signal to an output clock signal line connected to a first drive output sub-circuit of at least one stage of shift register, and a duration of a time period where a rising edge of the sixth clock signal is located is smaller than a half of a duration of a time period where a rising edge of the fourth clock signal is located.

In the present disclosure, by providing the sixth clock signal described above, a rapid rise can be realized for the drive signal output from the first drive output sub-circuit, and the rising edge of the drive signal output from another first drive output sub-circuit can be shortened, thereby realizing uniformity of the plurality of drive signals output by the shift register and improving the reliability of the display substrate.

In an exemplary implementation, the display substrate may further include a light emitting structure layer disposed on a side of the drive structure layer away from the base substrate, and an encapsulation structure layer disposed on a side of the light emitting structure layer away from the base substrate. In some possible implementations, the display substrate may include another film layer, such as a touch structure layer, which is not limited here in the present disclosure.

In an exemplary implementation, the base substrate may be a flexible substrate, or a rigid substrate.

In an exemplary embodiment, the light emitting structure layer may include an anode, a pixel definition layer, an organic light emitting layer and a cathode. The anode is connected to a drain electrode of the drive transistor through a via, the organic light emitting layer is connected to the anode, the cathode is connected to the organic light emitting layer, and the organic light emitting layer emits light of a corresponding color under the drive of the anode and the cathode.

In an exemplary implementation, the encapsulation structure layer may include a first encapsulation layer, a second encapsulation layer, and a third encapsulation layer that are stacked. The first encapsulation layer and the third encapsulation layer may be made of an inorganic material, and the second encapsulation layer may be made of an organic material. The second encapsulation layer is disposed between the first encapsulation layer and the third encapsulation layer, which may be ensured that external moisture cannot enter the light emitting structure layer.

In an exemplary implementation, the touch structure layer may include a first touch insulating layer arranged on the encapsulation structure layer, a first touch metal layer arranged on the first touch insulating layer, a second touch insulating layer covering the first touch metal layer, a second touch metal layer arranged on the second touch insulating layer, and a touch protective layer covering the second touch metal layer. The first touch metal layer may include a plurality of bridge electrodes, the second touch metal layer may include a plurality of first touch electrodes and second touch electrodes, and a first touch electrode or second touch electrode may be connected to a bridge electrode through a via.

Exemplary description is made below through a preparation process of a display substrate. A “patterning process” mentioned in the present disclosure includes photoresist coating, mask exposure, development, etching, photoresist stripping, etc., for a metal material, an inorganic material, or a transparent conductive material, and includes organic material coating, mask exposure, development, etc., for an organic material. Deposition may be any one or more of sputtering, evaporation, and chemical vapor deposition. The coating may be any one or more of spray coating, spin coating, and inkjet printing. A “thin film” refers to a layer of thin film made of a certain material on a base substrate using deposition, coating, or other processes. If the “thin film” does not need to be processed through a patterning process in the entire manufacturing process, the “thin film” may also be called a “layer”. If the “thin film” needs to be processed through the patterning process in the entire manufacturing process, the “thin film” is called a “thin film” before the patterning process is performed and is called a “layer” after the patterning process is performed. At least one “pattern” is contained in the “layer” which has been processed through the patterning process. “A and B are arranged in a same layer” in the present disclosure means that A and B are formed simultaneously through a same patterning process, and a “thickness” of a film layer is a dimension of the film layer in a direction perpendicular to a display substrate. In an exemplary implementation of the present disclosure, “an orthographic projection of B is within a range of an orthographic projection of A” or “an orthographic projection of A contains an orthographic projection of B” refers to that a boundary of the orthographic projection of B falls within a range of a boundary of the orthographic projection of A, or the boundary of the orthographic projection of A coincides with the boundary of the orthographic projection of B.

In an exemplary implementation, a preparation process of the display substrate may include following operations.

(1) A pattern of a semiconductor layer is formed. In an exemplary implementation, forming a pattern of a semiconductor layer may include: depositing a semiconductor thin film on a base substrate, and patterning the semiconductor thin film by a patterning process to form a pattern of a semiconductor layer covering the base substrate, as shown in FIGS. 18 and 19, FIG. 18 being a schematic diagram of a pattern of a semiconductor layer in FIG. 9, and FIG. 19 being a schematic diagram of a pattern of a semiconductor layer in FIG. 10.

In an exemplary implementation, as shown in FIGS. 18 and 19, the pattern of the semiconductor layer may at least include: an active pattern 511 of a first output transistor to an active pattern 541 of a fourth output transistor, and an active pattern 611 of a first noise reduction transistor to an active pattern 641 of a fourth noise reduction transistor.

In an exemplary implementation, as shown in FIGS. 18 and 19, the active pattern 511 of the first output transistor to the active pattern 541 of the fourth output transistor are arranged separately. The active pattern 611 of the first noise reduction transistor and the active pattern 621 of the second noise reduction transistor are of an integrated structure. The active pattern 631 of the third noise reduction transistor and the active pattern 641 of the fourth noise reduction transistor are of an integrated structure.

In an exemplary implementation, as shown in FIG. 18, the active pattern 511 of the first output transistor is arranged symmetrically with the active pattern 521 of the second output transistor with respect to the second centerline O2, the active pattern 521 of the second output transistor is arranged symmetrically with the active pattern 531 of the third output transistor with respect to the first centerline O1, the active pattern 511 of the first output transistor is arranged symmetrically with the active pattern 541 of the fourth output transistor with respect to the second centerline O2, and the active pattern 531 of the third output transistor is arranged symmetrically with the active pattern 541 of the fourth output transistor with respect to the first centerline O1. The active pattern 611 of the first noise reduction transistor is arranged symmetrically with the active pattern 641 of the fourth output transistor with respect to the first centerline O1, and the active pattern 621 of the second noise reduction transistor is arranged symmetrically with the active pattern 631 of the third output transistor with respect to the first centerline O1.

In an exemplary implementation, as shown in FIG. 18, a virtual straight line extending in the first direction D1 through the active pattern 631 of the third noise reduction transistor and the active pattern 641 of the fourth noise reduction transistor does not pass through the active pattern 641 of the fourth output transistor.

In an exemplary implementation, as shown in FIG. 19, the active pattern 511 of the first output transistor is arranged symmetrically with the active pattern 521 of the second output transistor with respect to the second centerline O2, the active pattern 521 of the second output transistor is arranged symmetrically with the active pattern 531 of the third output transistor with respect to the first centerline O1, the active pattern 511 of the first output transistor is arranged partially symmetrically with the active pattern 541 of the fourth output transistor with respect to the second centerline O2, and the active pattern 531 of the third output transistor is arranged symmetrically with the active pattern 541 of the fourth output transistor with respect to the first centerline O1. The active pattern 611 of the first noise reduction transistor is arranged asymmetrically with the active pattern 641 of the fourth output transistor with respect to the first centerline O1, and the active pattern 621 of the second noise reduction transistor is arranged asymmetrically with the active pattern 631 of the third output transistor with respect to the first centerline O1.

In an exemplary implementation, as shown in FIG. 19, the area of the active pattern 541 of the fourth output transistor is larger than the area of at least one of the active pattern 511 of the first output transistor to the active pattern 531 of the third output transistor.

In an exemplary implementation, as shown in FIGS. 18 and 19, the active pattern 511 of the first output transistor to the active pattern 531 of the third output transistor include: a plurality of strip-like structures extending in the second direction D2, the plurality of strip-like structures are arranged in the first direction D1.

In an exemplary implementation, as shown in FIG. 19, some of the strip-like structures in the active pattern 541 of the fourth output transistor have a length greater than the lengths of the strip-like structures in the active pattern 511 of the first output transistor to the active pattern 531 of the third output transistor.

In an exemplary implementation, as shown in FIG. 19, a virtual straight line extending in the first direction D1 through the active pattern 631 of the third noise reduction transistor and the active pattern 641 of the fourth noise reduction transistor passes through the active pattern 541 of the fourth output transistor.

In an exemplary implementation, as shown in FIGS. 18 and 19, the active pattern 611 of the first noise reduction transistor to the active pattern 641 of the fourth noise reduction transistor include: a plurality of strip-like structures extending in the second direction D2, the plurality of strip-like structures being arranged in the first direction D1. The lengths of the strip-like structures in the active pattern 611 of the first noise reduction transistor to the active pattern 641 of the fourth noise reduction transistor are smaller than the lengths of the strip-like structures in the active pattern 511 of the first output transistor to the active pattern 541 of the fourth output transistor.

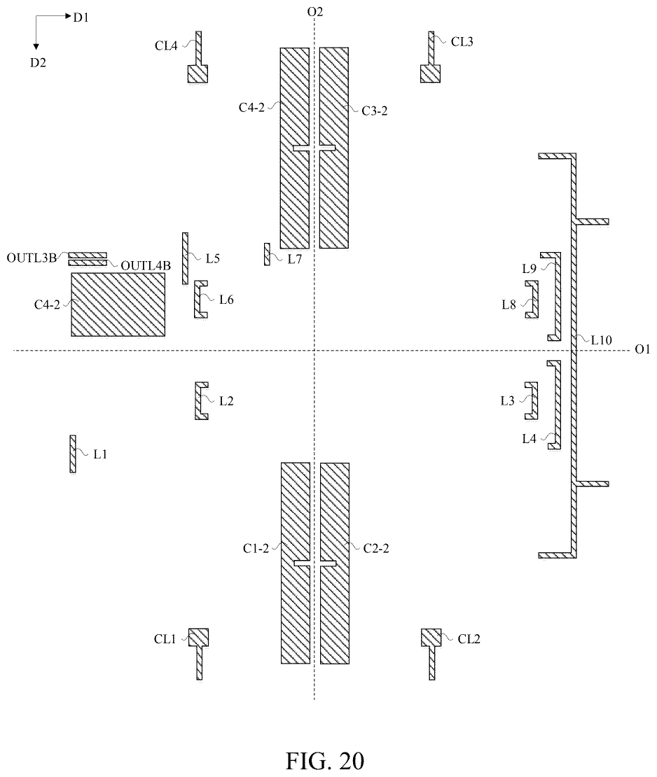

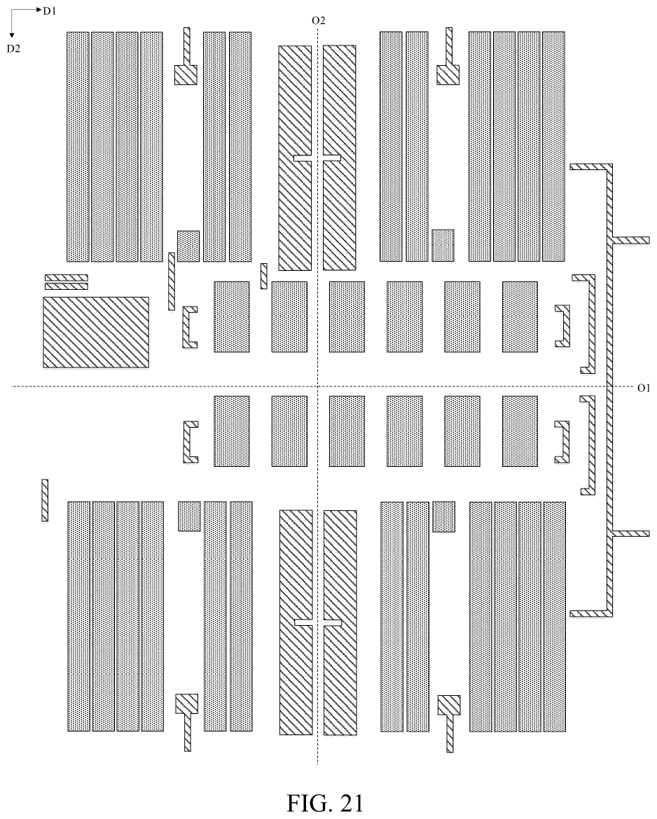

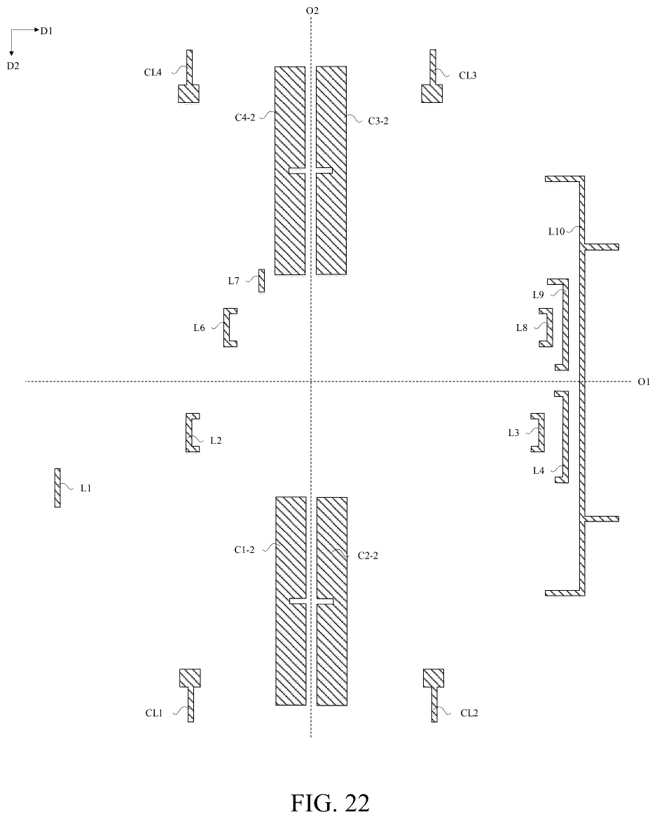

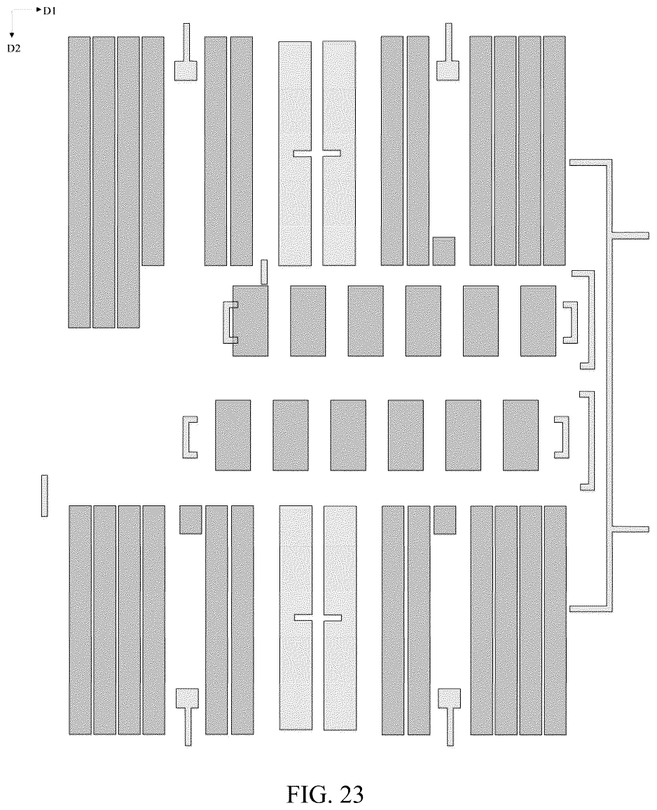

(2) A pattern of a first conductive layer is formed. In an exemplary implementation, forming a pattern of a first conductive layer may include: sequentially depositing a first insulating thin film and a first conductive thin film on the base substrate on which the aforementioned pattern is formed, and patterning the first conductive thin film by a patterning process to form a first insulating layer covering the pattern of the semiconductor layer, and a pattern of a first conductive layer arranged on the first insulating layer, as shown in FIGS. 20 to 23, FIG. 20 being a schematic diagram of the pattern of the first conductive layer in FIG. 9, FIG. 21 being a schematic diagram after the pattern of the first conductive layer is formed in FIG. 9, FIG. 22 being a schematic diagram of the pattern of the first conductive layer in FIG. 10, and FIG. 23 being a schematic diagram after the pattern of the first conductive layer is formed in FIG. 10. In an exemplary implementation, the first conductive layer may be referred to as a gate metal (GATE) layer.

In an exemplary implementation, as shown in FIGS. 20 to 23, the pattern of the first conductive layer in FIGS. 9 and 10 at least includes: a second plate OC1-2 of the first output capacitor to a second plate OC4-2 of the fourth output capacitor, a first clock connection line CL1 to a fourth clock connection line CL4, a first connection line L1, a second connection line L2, a third connection line L4, a fourth connection line LA, a sixth connection line L6, a seventh connection line L7, an eighth connection line L8, a ninth connection line L9 and a tenth connection line L10.

In an exemplary implementation, as shown in FIGS. 20 and 21, the pattern of the first conductive layer provided in FIG. 9 further includes: a fifth connection line L5, a second output connection portion OUTL3B of the third output signal line, and a second output connection portion OUTL4B of the fourth output signal line.

In an exemplary implementation, as shown in FIGS. 20 and 21, the respective numbers of second plates OC1-2 of the first output capacitor to second plates OC3-2 of the third output capacitor in the pattern of the first conductive layer provided in FIG. 9 are one, and the number of second plates OC4-2 of the fourth output capacitor is two. The second plate OC1-2 of the first output capacitor is arranged symmetrically with the second plate OC2-2 of the second output capacitor with respect to the second centerline O2, the second plate OC2-2 of the second output capacitor is arranged symmetrically with the second plate OC3-2 of the third output capacitor with respect to the first centerline O1, the second plate OC3-2 of the third output capacitor is arranged symmetrically with the second plate OC4-2 of one of the fourth output capacitors with respect to the second centerline O2, and the second plate OC1-2 of the first output capacitor is arranged symmetrically with the second plate OC4-2 of one of the fourth output capacitors with respect to the first centerline O1. The second plate OC4-2 of the other fourth output capacitor is located on a side of the second plate OC4-2 of the one of the fourth output capacitors close to the first centerline O1 and away from the second centerline O2.

In an exemplary implementation, as shown in FIGS. 20 and 21, the second plate OC1-2 of the first output capacitor to the second plate OC3-2 of the third output capacitor and the second plate OC4-2 of one of the fourth output capacitors are each in a shape of a strip extending in the second direction D2. The second plate OC4-2 of the other fourth output capacitor is in a shape of a strip extending in the first direction D1.

In an exemplary implementation, as shown in FIGS. 22 and 23, the respective numbers of second plates OC1-2 of the first output capacitor to second plates OC3-2 of the fourth output capacitor in the pattern of the first conductive layer provided in FIG. 10 are one. The second plate OC1-2 of the first output capacitor is arranged symmetrically with the second plate OC2-2 of the second output capacitor with respect to the second centerline O2, the second plate OC2-2 of the second output capacitor is arranged symmetrically with the second plate OC3-2 of the third output capacitor with respect to the first centerline O1, the second plate OC3-2 of the third output capacitor is arranged symmetrically with the second plate OC4-2 of the fourth output capacitor with respect to the second centerline O2, and the second plate OC1-2 of the first output capacitor is arranged symmetrically with the second plate OC4-2 of the fourth output capacitor with respect to the first centerline O1.

In an exemplary implementation, as shown in FIGS. 22 and 23, the second plate OC1-2 of the first output capacitor to the second plate OC4-2 of the fourth output capacitor are each in a shape of a strip extending in the second direction D2.

In an exemplary implementation, as shown in FIGS. 20 to 23, the first clock connection line CL1 to the fourth clock connection line CL4 extend at least partially in the second direction D2. The first clock connection line CL1 is arranged symmetrically with the second clock connection line CL2 with respect to the second centerline O2, the third clock connection line CL3 is arranged symmetrically with the second clock connection line CL2 with respect to the first centerline O1, the first clock connection line CL1 is arranged symmetrically with the fourth clock connection line CLA with respect to the first centerline O1, and the third clock connection line CL3 is arranged symmetrically with the fourth clock connection line CL4 with respect to the second centerline O2.

In an exemplary implementation, as shown in FIGS. 20 to 23, at least one of the first connection line L1 to the tenth connection line L10 extends at least partially in the second direction D2.

In an exemplary implementation, as shown in FIGS. 20 to 23, the first connection line L1 to the fourth connection line L4 are located on a side of the first centerline O1, the fifth connection line L5 to the ninth connection line L9 are located on the other side of the first centerline O1, and the tenth connection line L10 is arranged symmetrically with respect to the first centerline O1.

In an exemplary implementation, as shown in FIGS. 20 to 23, the first connection line L1, the second connection line L2, the fifth connection line L5, the sixth connection line L6 and the seventh connection line L7 are located on a side of the second centerline O2, and the third connection line L3, the fourth connection line LA, the eighth connection line L8, the ninth connection line L9 and the tenth connection line L10 are located on the other side of the second centerline O2.

In an exemplary implementation, as shown in FIGS. 20 to 23, the third connection line L3 is arranged symmetrically with the eighth connection line L8 with respect to the first centerline O1, and the fourth connection line L4 is arranged symmetrically with the ninth connection line L9 with respect to the first centerline O1.

In an exemplary implementation, as shown in FIGS. 20 and 21, the second connection line L2 is arranged symmetrically with the sixth connection line L6 with respect to the first centerline O1. There is no overlapping region between the orthographic projection of the sixth connection line L6 on the base substrate and the orthographic projections of the active pattern of the third noise reduction transistor and the active pattern of the fourth noise reduction transistor on the base substrate.

In an exemplary implementation, as shown in FIGS. 22 and 23, the second connection line L2 is arranged asymmetrically with the sixth connection line L6 with respect to the first centerline O1. There is an overlapping region between the orthographic projection of the sixth connection line L6 on the base substrate and the orthographic projections of the active pattern of the third noise reduction transistor and the active pattern of the fourth noise reduction transistor on the base substrate.

In an exemplary implementation, as shown in FIGS. 20 and 21, the second output connection portion OUTL3B of the third output signal line is in a shape of a strip extending in the first direction D1.

In an exemplary implementation, as shown in FIGS. 20 and 21, the second output connection portion OUTL4B of the fourth output signal line is in a shape of a strip extending in the first direction D1.

In an exemplary implementation, as shown in FIGS. 20 and 21, the second output connection portion OUTL3B of the third output signal line and the second output connection portion OUTL4B of the fourth output signal line are arranged in the second direction D2, and have equal lengths in the first direction D1.

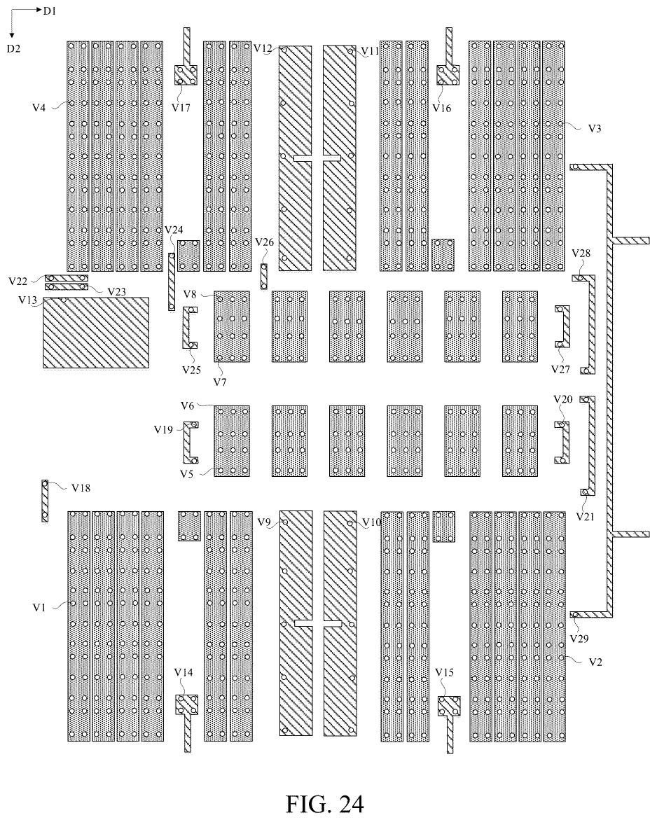

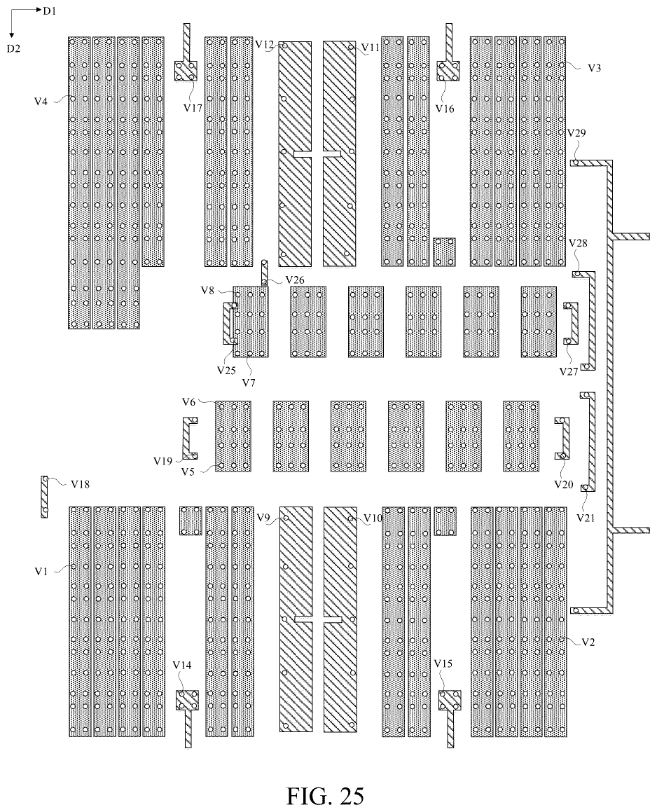

(3) A pattern of a second insulating layer is formed. In an exemplary implementation, forming a pattern of a second insulating layer may include: depositing a second insulating thin film on the base substrate on which the aforementioned patterns are formed, and patterning the second insulating thin film by a patterning process to form a second insulating layer covering the conductive layer, the second insulating layer being provided with a plurality of vias, as shown in FIGS. 24 and 25. FIG. 24 is a schematic diagram after a second insulating layer is formed in FIG. 9, and FIG. 25 is a schematic diagram after a second insulating layer is formed in FIG. 10.

In an exemplary implementation, as shown in FIG. 24, the plurality of vias in the second insulating layer in FIG. 9 include: a first via to a twenty-ninth via V29.

In an exemplary implementation, as shown in FIG. 25, the plurality of vias in the second insulating layer in FIG. 10 include: a first via to an eleventh via V11, a fourteenth via V14 to a twenty-first via V21, and a twenty-fifth via V25 to a twenty-ninth via V29.

In an exemplary implementation, an orthographic projection of the first via V1 on the base substrate is within the range of an orthographic projection of the active pattern of the first output transistor on the base substrate, the first insulating layer within the first via V1 is etched off, exposing a surface of the active pattern of the first output transistor, and the first via V1 is configured in such a manner that the first electrode and the second electrode of the first output transistor formed subsequently are connected to the active pattern of the first output transistor through the via.

In an exemplary implementation, an orthographic projection of the second via V2 on the base substrate is within the range of an orthographic projection of the active pattern of the second output transistor on the base substrate, the first insulating layer within the second via V2 is etched off, exposing a surface of the active pattern of the second output transistor, and the second via V2 is configured in such a manner that the first electrode and the second electrode of the second output transistor formed subsequently are connected to the active pattern of the second output transistor through the via.

In an exemplary implementation, an orthographic projection of the third via V3 on the base substrate is within the range of an orthographic projection of the active pattern of the third output transistor on the base substrate, the first insulating layer within the third via V3 is etched off, exposing a surface of the active pattern of the third output transistor, and the third via V3 is configured in such a manner that the first electrode and the second electrode of the third output transistor formed subsequently are connected to the active pattern of the third output transistor through the via.

In an exemplary implementation, an orthographic projection of the fourth via V4 on the base substrate is within the range of an orthographic projection of the active pattern of the fourth output transistor on the base substrate, the first insulating layer within the fourth via V4 is etched off, exposing a surface of the active pattern of the fourth output transistor, and the fourth via V4 is configured in such a manner that the first electrode and the second electrode of the fourth output transistor formed subsequently are connected to the active pattern of the fourth output transistor through the via.

In an exemplary implementation, an orthographic projection of the fifth via V5 on the base substrate is within the range of an orthographic projection of the active pattern of the first noise reduction transistor on the base substrate, the first insulating layer within the fifth via V5 is etched off, exposing a surface of the active pattern of the first noise reduction transistor, and the fifth via V5 is configured in such a manner that the first electrode and the second electrode of the first noise reduction transistor formed subsequently are connected to the active pattern of the first noise reduction transistor through the via.

In an exemplary implementation, an orthographic projection of the sixth via V6 on the base substrate is within the range of an orthographic projection of the active pattern of the second noise reduction transistor on the base substrate, the first insulating layer within the sixth via V6 is etched off, exposing a surface of the active pattern of the second noise reduction transistor, and the sixth via V6 is configured in such a manner that the first electrode and the second electrode of the second noise reduction transistor formed subsequently are connected to the active pattern of the second noise reduction transistor through the via.

In an exemplary implementation, an orthographic projection of the seventh via V7 on the base substrate is within the range of an orthographic projection of the active pattern of the third noise reduction transistor on the base substrate, the first insulating layer within the seventh via V7 is etched off, exposing a surface of the active pattern of the third noise reduction transistor, and the seventh via V7 is configured in such a manner that the first electrode and the second electrode of the third noise reduction transistor formed subsequently are connected to the active pattern of the third noise reduction transistor through the via.

In an exemplary implementation, an orthographic projection of the eighth via V8 on the base substrate is within the range of an orthographic projection of the active pattern of the fourth noise reduction transistor on the base substrate, the first insulating layer within the eighth via V8 is etched off, exposing a surface of the active pattern of the fourth noise reduction transistor, and the eighth via V8 is configured in such a manner that the first electrode and the second electrode of the fourth noise reduction transistor formed subsequently are connected to the active pattern of the fourth noise reduction transistor through the via.

In an exemplary implementation, an orthographic projection of the ninth via V9 on the base substrate is within the range of an orthographic projection of the second plate of the first output capacitor on the base substrate, the ninth via V9 exposes a surface of the second plate of the first output capacitor, and the ninth via V9 is configured in such a manner that the second electrode of the first output transistor formed subsequently is connected to the second plate of the first output capacitor through the via.

In an exemplary implementation, an orthographic projection of the tenth via V10 on the base substrate is within the range of an orthographic projection of the second plate of the second output capacitor on the base substrate, the tenth via V10 exposes a surface of the second plate of the second output capacitor, and the tenth via V10 is configured in such a manner that the second electrode of the second output transistor formed subsequently is connected to the second plate of the second output capacitor through the via.

In an exemplary implementation, an orthographic projection of the eleventh via V11 on the base substrate is within the range of an orthographic projection of the second plate of the third output capacitor on the base substrate, the eleventh via V11 exposes a surface of the second plate of the third output capacitor, and the eleventh via V11 is configured in such a manner that the second electrode of the third output transistor formed subsequently is connected to the second plate of the third output capacitor through the via.

In an exemplary implementation, in the display substrate provided in FIG. 9, an orthographic projection of the twelfth via V12 on the base substrate is within the range of an orthographic projection of the second plate of one of the fourth output capacitors on the base substrate, the twelfth via V12 exposes a surface of the second plate of one of the fourth output capacitors, and the twelfth via V12 is configured in such a manner that the second electrode of the fourth output transistor formed subsequently is connected to the second plate of one of the fourth output capacitors through the via.

In an exemplary implementation, in the display substrate provided in FIG. 10, an orthographic projection of the twelfth via V12 on the base substrate is within the range of an orthographic projection of the second plate of the fourth output capacitor on the base substrate, the twelfth via V12 exposes a surface of the second plate of the fourth output capacitor, and the twelfth via V12 is configured in such a manner that the second electrode of the fourth output transistor formed subsequently is connected to the second plate of the fourth output capacitor through the via.

In an exemplary implementation, an orthographic projection of the thirteenth via V13 on the base substrate is within the range of an orthographic projection of the second plate of the other fourth output capacitor on the base substrate, the thirteenth via V13 exposes a surface of the second plate of the other fourth output capacitor, and the thirteenth via V13 is configured in such a manner that the second electrode of the fourth output transistor formed subsequently is connected to the second plate of the other fourth output capacitor through the via.

In an exemplary implementation, an orthographic projection of the fourteenth via V14 on the base substrate is within the range of an orthographic projection of the first clock connection line on the base substrate, the fourteenth via V14 exposes a surface of the first clock connection line, and the fourteenth via V14 is configured in such a manner that the first electrode of the first output transistor formed subsequently is connected to the first clock connection line through the via.

In an exemplary implementation, an orthographic projection of the fifteenth via V15 on the base substrate is within the range of an orthographic projection of the second clock connection line on the base substrate, the fifteenth via V15 exposes a surface of the second clock connection line, and the fifteenth via V15 is configured in such a manner that the first electrode of the second output transistor formed subsequently is connected to the second clock connection line through the via.

In an exemplary implementation, an orthographic projection of the sixteenth via V16 on the base substrate is within the range of an orthographic projection of the third clock connection line on the base substrate, the sixteenth via V16 exposes a surface of the third clock connection line, and the sixteenth via V16 is configured in such a manner that the first electrode of the third output transistor formed subsequently is connected to the third clock connection line through the via.

In an exemplary implementation, an orthographic projection of the seventeenth via V17 on the base substrate is within the range of an orthographic projection of the fourth clock connection line on the base substrate, the seventeenth via V17 exposes a surface of the fourth clock connection line, and the seventeenth via V17 is configured in such a manner that the first electrode of the fourth output transistor formed subsequently is connected to the fourth clock connection line through the via.

In an exemplary implementation, an orthographic projection of the eighteenth via V18 on the base substrate is within the range of an orthographic projection of the first connection line on the base substrate, the eighteenth via V18 exposes a surface of the first connection line, and the eighteenth via V18 is configured in such a manner that the second electrode of the first output transistor and the first output signal line formed subsequently are connected to the first connection line through the via.

In an exemplary implementation, an orthographic projection of the nineteenth via V19 on the base substrate is within the range of an orthographic projection of the second connection line on the base substrate, the nineteenth via V19 exposes a surface of the second connection line, and the nineteenth via V19 is configured in such a manner that the gate electrode of the first noise reduction transistor and the gate electrode of the second noise reduction transistor formed subsequently are connected to the second connection line.

In an exemplary implementation, an orthographic projection of the twentieth via V20 on the base substrate is within the range of an orthographic projection of the third connection line on the base substrate, the twentieth via V20 exposes a surface of the third connection line, and the twentieth via V20 is configured in such a manner that the gate electrode of the first noise reduction transistor and the gate electrode of the second noise reduction transistor formed subsequently are connected to the third connection line.

In an exemplary implementation, an orthographic projection of the twenty-first via V21 on the base substrate is within the range of an orthographic projection of the fourth connection line on the base substrate, the twenty-first via V21 exposes a surface of the fourth connection line, and the twenty-first via V21 is configured in such a manner that the second electrode of the second output transistor and the first electrode of the second noise reduction transistor formed subsequently are connected to the fourth connection line.

In an exemplary implementation, an orthographic projection of the twenty-second via V22 on the base substrate is within the range of an orthographic projection of the second output connection portion of the third output signal line on the base substrate, the twenty-second via V22 exposes a surface of the second output connection portion of the third output signal line, and the twenty-second via V22 is configured in such a manner that the first output connection portion and the third output connection portion of the third output signal line formed subsequently are connected to the second output connection portion of the third output signal line.

In an exemplary implementation, an orthographic projection of the twenty-third via V23 on the base substrate is within the range of an orthographic projection of the second output connection portion of the fourth output signal line on the base substrate, the twenty-third via V23 exposes a surface of the second output connection portion of the fourth output signal line, and the twenty-third via V23 is configured in such a manner that the first output connection portion and the third output connection portion of the fourth output signal line formed subsequently are connected to the second output connection portion of the fourth output signal line.

In an exemplary implementation, an orthographic projection of the twenty-fourth via V24 on the base substrate is within the range of an orthographic projection of the fifth connection line on the base substrate, the twenty-fourth via V24 exposes a surface of the fifth connection line, and the twenty-fourth via V24 is configured in such a manner that the gate electrode (which is also the first plate of one of the fourth output capacitors) of the fourth output transistor and the first plate of the other fourth output capacitor formed subsequently are connected to the fifth connection line.

In an exemplary implementation, an orthographic projection of the twenty-fifth via V25 on the base substrate is within the range of an orthographic projection of the sixth connection line on the base substrate, the twenty-fifth via V25 exposes a surface of the sixth connection line, and the twenty-fifth via V25 is configured in such a manner that the gate electrode of the third noise reduction transistor and the gate electrode of the fourth noise reduction transistor formed subsequently are connected to the sixth connection line.

In an exemplary implementation, in FIG. 9, an orthographic projection of the twenty-sixth via V26 on the base substrate is within the range of an orthographic projection of the seventh connection line on the base substrate, the twenty-sixth via V26 exposes a surface of the seventh connection line, and the twenty-sixth via V26 is configured in such a manner that the second electrode of the fourth output transistor and the first output connection portion of the fourth output signal line formed subsequently are connected to the seventh connection line.

In an exemplary implementation, in FIG. 10, the orthographic projection of the twenty-sixth via V26 on the base substrate is within the range of the orthographic projection of the seventh connection line on the base substrate, the twenty-sixth via V26 exposes the surface of the seventh connection line, and the twenty-sixth via V26 is configured in such a manner that the second electrode of the fourth output transistor and the fourth output signal line formed subsequently are connected to the seventh connection line.

In an exemplary implementation, an orthographic projection of the twenty-seventh via V27 on the base substrate is within the range of an orthographic projection of the eighth connection line on the base substrate, the twenty-seventh via V27 exposes a surface of the eighth connection line, and the twenty-seventh via V27 is configured in such a manner that the gate electrode of the third noise reduction transistor and the gate electrode of the fourth noise reduction transistor formed subsequently are connected to the eighth connection line.

In an exemplary implementation, in FIG. 9, an orthographic projection of the twenty-eighth via V28 on the base substrate is within the range of an orthographic projection of the ninth connection line on the base substrate, the twenty-eighth via V28 exposes a surface of the ninth connection line, and the twenty-eighth via V28 is configured in such a manner that the first electrode of the third noise reduction transistor and the first output connection portion of the third output signal line formed subsequently are connected to the ninth connection line.

In an exemplary implementation, in FIG. 10, the orthographic projection of the twenty-eighth via V28 on the base substrate is within the range of the orthographic projection of the ninth connection line on the base substrate, the twenty-eighth via V28 exposes the surface of the ninth connection line, and the twenty-eighth via V28 is configured in such a manner that the first electrode of the third noise reduction transistor and the third output signal line formed subsequently are connected to the ninth connection line.

In an exemplary implementation, an orthographic projection of the twenty-ninth via V29 on the base substrate is within the range of the orthographic projection of the ninth connection line on the base substrate, the twenty-ninth via V29 exposes the surface of the ninth connection line, and the twenty-ninth via V29 is configured in such a manner that the gate electrode (which is also the first plate of the third output capacitor) of the third output transistor and the gate electrode (which is also the first plate of the first output capacitor) of the second output transistor formed subsequently are connected to the ninth connection line.

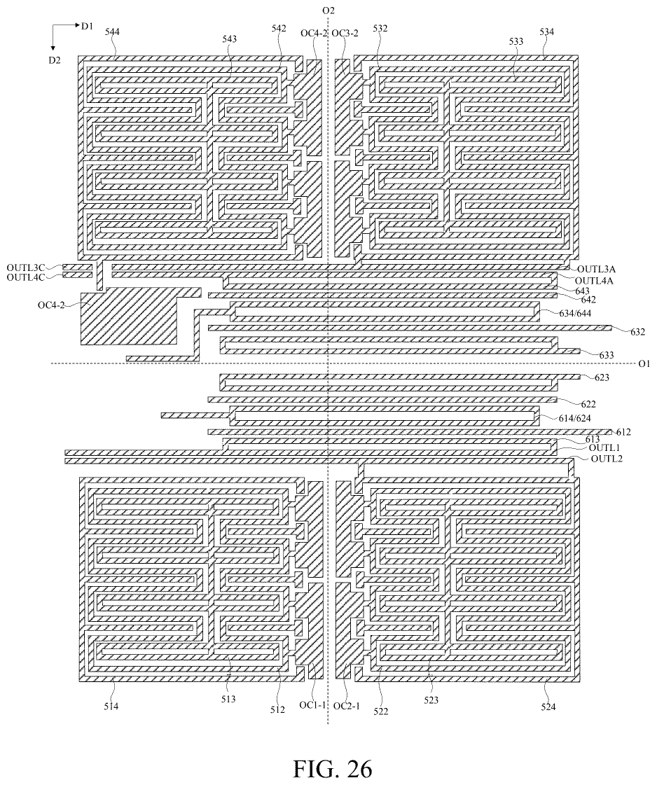

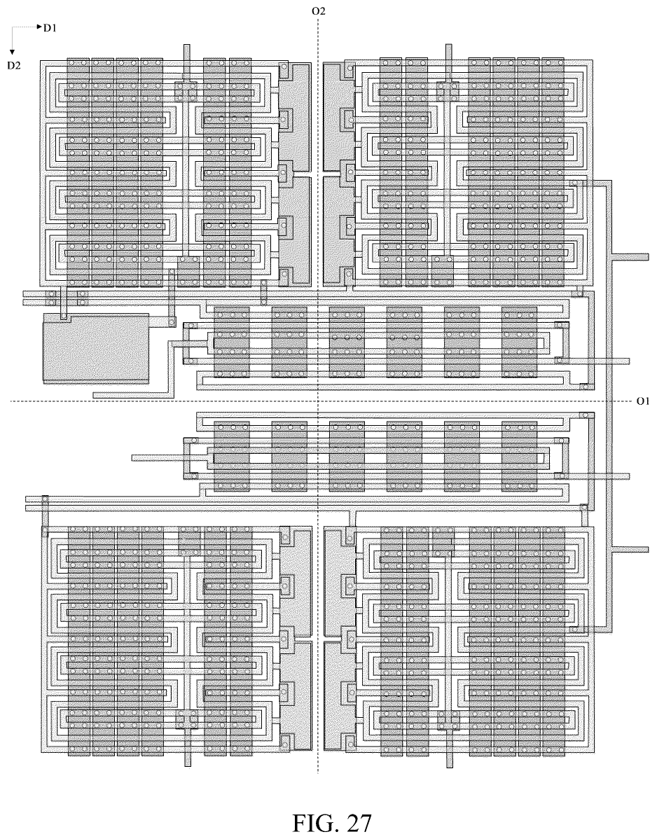

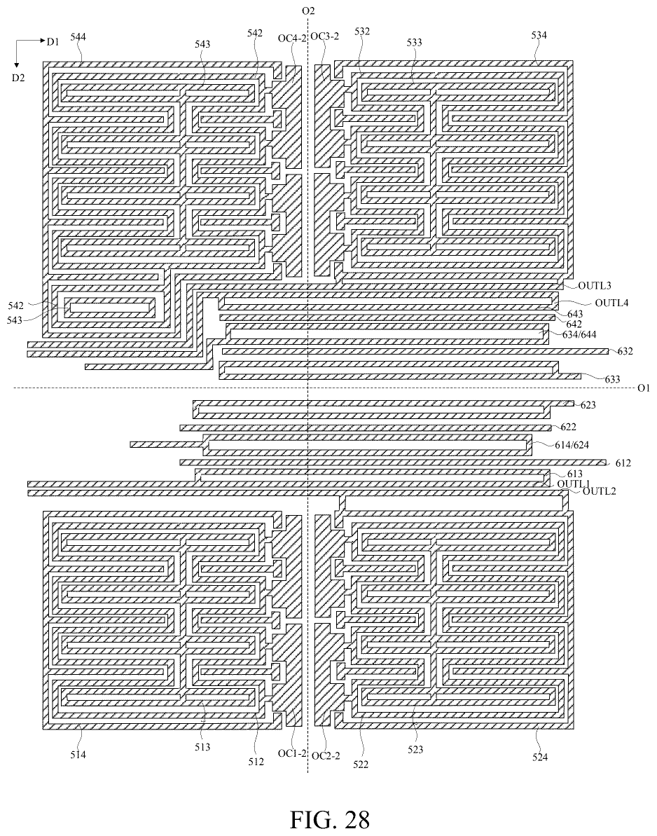

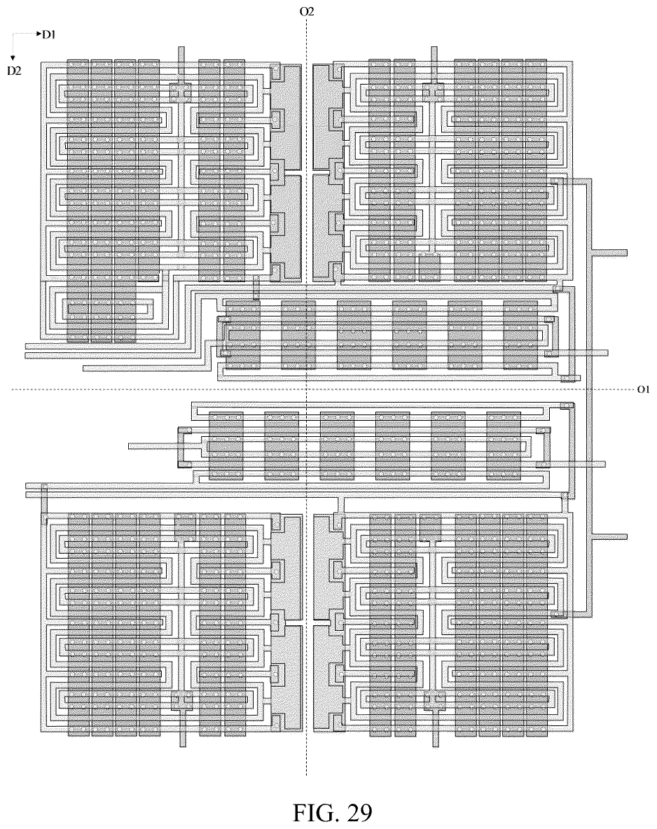

(4) A pattern of a second conductive layer is formed. In an exemplary implementation, forming a pattern of a second conductive layer may include: depositing a second conductive thin film on the base substrate on which the aforementioned patterns are formed, and patterning the second conductive thin film by a patterning process to form a pattern of a second conductive layer arranged on the second insulating layer, as shown in FIGS. 26 to 29, FIG. 26 being a schematic diagram of a pattern of a second conductive layer in FIG. 9, FIG. 27 being a schematic diagram after the pattern of the second conductive layer is formed in FIG. 9, FIG. 28 being a schematic diagram of a pattern of a second conductive layer in FIG. 10, and FIG. 29 being a schematic diagram after the pattern of the second conductive layer is formed in FIG. 10. In an exemplary embodiment, the second conductive layer may be referred to as a Source Drain metal (SD) layer.

In an exemplary implementation, as shown in FIGS. 26 to 29, the pattern of the second conductive layer at least includes: a gate electrode 512, a first electrode 513 and a second electrode 514 of a first output transistor to a gate electrode 542, a first electrode 543 and a second electrode 544 of a fourth output transistor; a gate electrode 612, a first electrode 613 and a second electrode 614 of a first noise reduction transistor to a gate electrode 642, a first electrode 643 and a second electrode 644 of a fourth noise reduction transistor; and a first plate OC1-1 of a first output capacitor to a first plate OC4-1 of a fourth output capacitor.

In an exemplary implementation, as shown in FIGS. 26 and 27, the pattern of the second conductive layer in FIG. 9 at least further includes: a first output connection portion OUTL3A and a third output connection portion OUTL3C of a third output signal line, and a first output connection portion OUTL4A and a third output connection portion OUTL4C of a fourth output signal line.

In an exemplary implementation, as shown in FIGS. 28 and 29, the pattern of the second conductive layer in FIG. 10 at least further includes: a third output signal line OUTL3 and a fourth output signal line OUTL4.

In an exemplary implementation, in FIGS. 9 and 10, the gate electrode 512 of the first output transistor and the first plate OC1-1 of the first output capacitor are of an integrated structure. The gate electrode 512 of the first output transistor is of an annular structure, and the boundary extending in the second direction D2 is in a shape of [symbol] . The first plate OC1-1 of the first output capacitor is in a shape of a strip extending in the second direction D2, and the boundary on the side close to the gate electrode 512 of the first output transistor is in a shape of [symbol] . The number of first plates OC1-1 of the first output capacitor is two, and they are arranged at intervals.

In an exemplary implementation, in FIGS. 9 and 10, the first electrode 513 of the first output transistor is arranged inside the gate electrode 512 of the first output transistor, and may be in a shape of [symbol] . The first electrode 513 of the first output transistor is connected to the active pattern of the first output transistor through the first via, and to the first clock connection line through the fourteenth via.

In an exemplary implementation, in FIGS. 9 and 10, the second electrode 514 of the first output transistor is arranged on at least one side of the gate electrode 512 of the first output transistor, and the shape of the second electrode 514 of the first output transistor matches that of the gate electrode 512 of the first output transistor. The second electrode 514 of the first output transistor is connected to the active pattern of the first output transistor through the first via, to the first connection line through the eighteenth via, and to the second plate of the first output capacitor through the ninth via.

In an exemplary implementation, in FIGS. 9 and 10, the gate electrode 522 of the second output transistor and the first plate OC2-1 of the second output capacitor are of an integrated structure. The gate electrode 522 of the second output transistor is of an annular structure, and the boundary extending in the second direction D2 is in a shape of [symbol] . The first plate OC2-1 of the second output capacitor is in a shape of a strip extending in the second direction D2, and the boundary on the side close to the gate electrode 522 of the second output transistor is in a shape of [symbol] . The number of first plates OC2-1 of the second output capacitor is two, and they are arranged at intervals. The gate electrode 522 of the second output transistor is connected to the ninth connection line through the twenty-ninth via.

In an exemplary implementation, in FIGS. 9 and 10, the first electrode 523 of the second output transistor is arranged inside the gate electrode 522 of the second output transistor, and may be in a shape of [symbol] . The first electrode 523 of the second output transistor is connected to the active pattern of the second output transistor through the second via, and to the second clock connection line through the fifteenth via.

In an exemplary implementation, in FIGS. 9 and 10, the second electrode 524 of the second output transistor and the second output signal line OUTL2 are of an integrated structure. The second output signal line OUTL2 is in a shape of a line extending at least partially in the first direction D1. The second electrode 524 of the second output transistor is arranged on at least one side of the gate electrode 522 of the second output transistor, and the shape of the second electrode 524 of the second output transistor matches that of the gate electrode 522 of the second output transistor. The second electrode 524 of the second output transistor is connected to the active pattern of the second output transistor through the second via, to the second plate of the second output capacitor through the tenth via, and to the fourth connection line through the twenty-first via.

In an exemplary implementation, in FIGS. 9 and 10, the gate electrode 532 of the third output transistor and the first plate OC3-1 of the third output capacitor are of an integrated structure. The gate electrode 532 of the third output transistor is of an annular structure, and the boundary extending in the second direction D2 is in a shape of [symbol] . The first plate OC3-1 of the third output capacitor is in a shape of a strip extending in the second direction D2, and the boundary on the side close to the gate electrode 532 of the third output transistor is in a shape of [symbol] . The number of first plates OC3-1 of the third output capacitor is two, and they are arranged at intervals. The gate electrode 532 of the third output transistor is connected to the ninth connection line through the twenty-ninth via.

In an exemplary implementation, in FIGS. 9 and 10, the first electrode 533 of the third output transistor is arranged inside the gate electrode 532 of the third output transistor, and may be in a shape of [symbol] . The first electrode 533 of the third output transistor is connected to the active pattern of the third output transistor through the third via, and to the third clock connection line through the sixteenth via.

In an exemplary implementation, in FIG. 9, the second electrode 534 of the third output transistor and the first output connection portion OUTL3A of the third output signal line are of an integrated structure. The first output connection portion OUTL3A of the third output signal line OUTL3 is in a shape of a line extending at least partially in the first direction D1. The second electrode 534 of the third output transistor is arranged on at least one side of the gate electrode 532 of the third output transistor, and the shape of the second electrode 534 of the third output transistor matches that of the gate electrode 532 of the third output transistor. The second electrode 534 of the third output transistor is connected to the active pattern of the third output transistor through the third via, to the second plate of the third output capacitor through the eleventh via, to the second output connection portion of the third output signal line through the twenty-second via, and to the ninth connection line through the twenty-eighth via.

In an exemplary implementation, in FIG. 10, the second electrode 534 of the third output transistor and the third output signal line OUTL3 are of an integrated structure. The third output signal line OUTL3 is in a shape of a line extending at least partially in the first direction D1. The second electrode 534 of the third output transistor is arranged on at least one side of the gate electrode 532 of the third output transistor, and the shape of the second electrode 534 of the third output transistor matches that of the gate electrode 532 of the third output transistor. The second electrode 534 of the third output transistor is connected to the active pattern of the third output transistor through the third via, and to the ninth connection line through the twenty-eighth via.

In an exemplary implementation, in FIG. 9, the gate electrode 542 of the fourth output transistor and the first plate OC4-1 of one of the fourth output capacitors are of an integrated structure. The gate electrode 542 of the fourth output transistor is of an annular structure, and the boundary extending in the second direction D2 is in a shape of [symbol] . The first plate OC4-1 of one of the fourth output capacitors is in a shape of a strip extending in the second direction D2, and the boundary on the side close to the gate electrode 542 of the fourth output transistor is in a shape of [symbol] . The number of first plates OC-1 of the fourth output capacitor is two, and they are arranged at intervals.

In an exemplary implementation, in FIG. 9, the first plate OC4-1 of the other fourth output capacitor is in a shape of a strip extending in the first direction D1. The first plate OC4-1 of the other fourth output capacitor is connected to the gate electrode 542 of the fourth output transistor through the twenty-fourth via.

In an exemplary implementation, in FIG. 10, the gate electrode 542 of the fourth output transistor and the first plate OC4-1 of the fourth output capacitor are of an integrated structure. The gate electrode 542 of the fourth output transistor is of an annular structure, and the boundary extending in the second direction D2 is in a shape of [symbol] . The first plate OC4-1 of one of the fourth output capacitors is in a shape of a strip extending in the second direction D2, and the boundary on the side close to the gate electrode 542 of the fourth output transistor is in a shape of [symbol] . The number of first plates OC-1 of the fourth output capacitor is two, and they are arranged at intervals.

In an exemplary implementation, in FIGS. 9 and 10, the first electrode 543 of the fourth output transistor is arranged inside the gate electrode 542 of the fourth output transistor, and may be at least partially in a shape of [symbol] .The first electrode 543 of the fourth output transistor is connected to the active pattern of the fourth output transistor through the fourth via, and to the fourth clock connection line through the seventeenth via.

In an exemplary implementation, in FIG. 9, the second electrode 544 of the fourth output transistor is arranged on at least one side of the gate electrode 542 of the fourth output transistor, and the shape of the second electrode 544 of the fourth output transistor matches that of the gate electrode 542 of the fourth output transistor. The second electrode 544 of the fourth output transistor is connected to the active pattern of the fourth output transistor through the fourth via, to the second plate of one of the fourth output capacitors through the twelfth via, to the second plate of the other fourth output capacitor through the thirteenth via, and to the seventh connection line through the twenty-sixth via.

In an exemplary implementation, in FIG. 10, the second electrode 544 of the fourth output transistor is arranged on at least one side of the gate electrode 542 of the fourth output transistor, and the shape of the second electrode 544 of the fourth output transistor matches that of the gate electrode 542 of the fourth output transistor. The second electrode 544 of the fourth output transistor is connected to the active pattern of the fourth output transistor through the fourth via, to the second plate of the fourth output capacitor through the twelfth via, and to the seventh connection line through the twenty-sixth via.

In an exemplary implementation, in FIGS. 9 and 10, the gate electrode 612 of the first noise reduction transistor is in a shape of a strip extending in the first direction. The gate electrode 612 of the first noise reduction transistor is connected to the second connection line through the nineteenth via, and to the third connection line through the twentieth via.

In an exemplary implementation, in FIGS. 9 and 10, the first electrode 613 of the first noise reduction transistor and the first output signal line OUTL1 are of an integrated structure. The first output signal line OUTL1 is in a shape of a strip extending in the first direction. The first electrode 613 of the first noise reduction transistor is connected to the active pattern of the first noise reduction transistor through the fifth via, and to the first connection line through the eighteenth via.

In an exemplary implementation, in FIGS. 9 and 10, the second electrode 614 of the first noise reduction transistor and the second electrode 624 of the second noise reduction transistor are of an integrated structure. The integrated structure of the second electrode 614 of the first noise reduction transistor and the second electrode 624 of the second noise reduction transistor includes an annular structure. The integrated structure of the second electrode 614 of the first noise reduction transistor and the second electrode 624 of the second noise reduction transistor is connected to the active pattern of the first noise reduction transistor through the fifth via, and to the active pattern of the second noise reduction transistor through the sixth via.

In an exemplary implementation, in FIGS. 9 and 10, the gate electrode 622 of the second noise reduction transistor is in a shape of a strip extending in the first direction. The gate electrode 622 of the second noise reduction transistor is connected to the second connection line through the nineteenth via, and to the third connection line through the twentieth via.

In an exemplary implementation, in FIGS. 9 and 10, the first electrode 623 of the second noise reduction transistor is arranged separately. The first electrode 623 of the second noise reduction transistor includes an annular structure. The first electrode 623 of the second noise reduction transistor is connected to the active pattern of the second noise reduction transistor through the sixth via, and to the fourth connection line through the twenty-first via.

In an exemplary implementation, in FIGS. 9 and 10, the gate electrode 632 of the third noise reduction transistor is in a shape of a strip extending in the first direction. The gate electrode 632 of the third noise reduction transistor is connected to the sixth connection line through the twenty-fifth via, and to the eighth connection line through the twenty-seventh via.

In an exemplary implementation, in FIGS. 9 and 10, the first electrode 633 of the third noise reduction transistor is arranged separately as an integrated structure, and the first electrode 633 of the third noise reduction transistor is connected to the active pattern of the third noise reduction transistor through the seventh via, and to the ninth connection line through the twenty-eighth via.

In an exemplary implementation, in FIGS. 9 and 10, the second electrode 634 of the third noise reduction transistor and the second electrode 644 of the fourth noise reduction transistor are of an integrated structure. The integrated structure of the second electrode 634 of the third noise reduction transistor and the second electrode 644 of the fourth noise reduction transistor includes an annular structure. The integrated structure of the second electrode 634 of the third noise reduction transistor and the second electrode 644 of the fourth noise reduction transistor is connected to the active pattern of the third noise reduction transistor through the seventh via, and to the active pattern of the fourth noise reduction transistor through the eighth via.

In an exemplary implementation, in FIGS. 9 and 10, the gate electrode 642 of the fourth noise reduction transistor is in a shape of a strip extending in the first direction. The gate electrode 642 of the fourth noise reduction transistor is connected to the sixth connection line through the twenty-fifth via, and to the eighth connection line through the twenty-seventh via.

In an exemplary implementation, in FIG. 9, the first electrode 643 of the fourth noise reduction transistor and the first output connection portion OUTL4A of the fourth output signal line are of an integrated structure. The integrated structure of the first electrode 643 of the fourth noise reduction transistor and the first output connection portion OUTL4A of the fourth output signal line includes an annular structure. The first electrode 643 of the fourth noise reduction transistor is connected to the active pattern of the fourth noise reduction transistor through the eighth via, to the second output connection portion of the fourth output signal line through the twenty-third via, and to the seventh connection line through the twenty-sixth via.

In an exemplary implementation, in FIG. 10, the first electrode 643 of the fourth noise reduction transistor and the fourth output signal line OUTL are of an integrated structure. The integrated structure of the first electrode 643 of the fourth noise reduction transistor and the fourth output signal line OU4A includes an annular structure. The first electrode 643 of the fourth noise reduction transistor is connected to the active pattern of the fourth noise reduction transistor through the eighth via.

In an exemplary implementation, in FIG. 9, the third output connection portion OUTL3C of the third output signal line is in a shape of a strip extending in the first direction D1, and is connected to the second output connection portion of the third output signal line through the twenty-second via.

In an exemplary implementation, in FIG. 9, the third output connection portion OUTL3C of the fourth output signal line is in a shape of a strip extending in the first direction D1, and is connected to the second output connection portion of the fourth output signal line through the twenty-third via.

In an exemplary implementation, the base substrate may be a rigid base substrate or a flexible base substrate, wherein the rigid base substrate may be, but is not limited to, one or more of glass and metal foil; the flexible base substrate may be, but is not limited to, one or more of polyethylene terephthalate, ethylene terephthalate, polyether ether ketone, polystyrene, polycarbonate, polyarylate, polyarylester, polyimide, polyvinyl chloride, polyethylene, and textile fiber.

In an exemplary implementation, the flexible base substrate may include a first flexible material layer, a first inorganic material layer, a semiconductor layer, a second flexible material layer, and a second inorganic material layer which are stacked. Materials of the first flexible material layer and the second flexible material layer may be Polyimide (PI), Polyethylene Terephthalate (PET), or a surface-treated polymer soft film, etc., and materials of the first inorganic material layer and the second inorganic material layer may be Silicon Nitride (SiNx), Silicon Oxide (SiOx), or the like, for improving water and oxygen resistance of the base substrate. The first inorganic material layer and the second inorganic material layer may also be referred to as barrier layers, and a material of the semiconductor layer may be amorphous silicon (a-si). In an exemplary implementation, taking a stacked structure of PI1/Barrier1/a-si/PI2/Barrier2 as an example, its preparation process may include: first coating a layer of polyimide on a glass carrier board, after the layer of polyimide is cured to form a film, a first flexible (PI1) layer is formed; then depositing a layer of barrier thin film on the first flexible layer to form a first barrier (Barrier 1) layer overlaying the first flexible layer; then depositing a layer of amorphous silicon thin film on the first barrier layer to form an amorphous silicon (a-si) layer overlaying the first barrier layer; then coating another layer of polyimide on the amorphous silicon layer, after this layer of polyimide is cured to form a film, a second flexible (PI2) layer is formed; and then depositing a layer of barrier thin film on the second flexible layer to form a second barrier (Barrier 2) layer overlaying the second flexible layer, so as to complete preparation of the base substrate.

In an exemplary embodiment, the semiconductor layer may be an amorphous silicon layer, a polycrystalline silicon layer, or may be a metal oxide layer. Herein, the metal oxide layer may use an oxide including indium and tin, an oxide including tungsten and indium, an oxide including tungsten, indium and zinc, an oxide including titanium and indium, an oxide including titanium, indium and tin, an oxide including indium and zinc, an oxide including silicon, indium and tin, or an oxide including indium or gallium and zinc. The metal oxide layer may be a single layer, a double-layer, or a multi-layer.

In an exemplary implementation, the first conductive layer and the second conductive layer may be made of a metal material, such as any one or more of Argentum (Ag), Copper (Cu), Aluminum (Al), and Molybdenum (Mo), or an alloy material of the above metals, such as an Aluminum Neodymium alloy (AlNd) or a Molybdenum Niobium alloy (MoNb), and may be of a single-layer structure or a multi-layer composite structure, such as Mo/Cu/Mo.

In an exemplary implementation, the first insulating layer and the second insulating layer may be any one or more of silicon oxide (SiOx), silicon nitride (SiNx), and silicon oxynitride (SiON), and may be in a single layer, multiple layers, or a composite layer. The first insulating layer may be referred to as a gate insulating (GI) layer, and the second insulating layer may be referred to as an interlayer dielectric (ILD) layer. The first planarization layer and the second planarization layer may be made of an organic material, such as resin.

In an exemplary implementation, after preparation of the drive structure layer is completed, a light emitting structure layer is prepared on the drive structure layer, and a preparation process of the light emitting structure layer may include following operations.

A pattern of an anode conductive layer is formed. In an exemplary implementation, forming the pattern of the anode conductive layer may include: depositing an anode conductive thin film on the base substrate on which the aforementioned patterns are formed, and patterning the anode conductive thin film by a patterning process to form an anode conductive layer arranged on the drive structure layer, the anode conductive layer at least including a plurality of anode patterns.

In an exemplary implementation, the anode conductive layer may be of a single-layer structure, such as Indium Tin Oxide (ITO) or Indium Zinc Oxide (IZO), or may be of a multi-layer composite structure, such as ITO/Ag/ITO.

A pattern of a pixel definition layer is formed. In an exemplary implementation, forming the pattern of the pixel definition layer may include: coating a pixel definition thin film on the base substrate on which the aforementioned patterns are formed, and patterning the pixel definition thin film by a patterning process to form a pattern of a pixel definition layer.

In an exemplary implementation, the subsequent preparation process may include:
forming an organic light emitting layer by an evaporation or inkjet printing process, then forming a cathode on the organic light emitting layer, and then forming an encapsulation structure layer, wherein the encapsulation structure layer may include a first encapsulation layer, a second encapsulation layer and a third encapsulation layer that are stacked, the first encapsulation layer and the third encapsulation layer may be made of an inorganic material, the second encapsulation layer may be made of an organic material, and the second encapsulation layer is disposed between the first encapsulation layer and the third encapsulation layer, which may ensure that external water vapor cannot enter the light emitting structure layer.

The present disclosure also provides a display apparatus which includes the aforementioned display substrate. The display apparatus may be any product or component with a display function, such as a mobile phone, a tablet computer, a television, a display, a laptop computer, a digital photo frame, or a navigator, which is not limited in the embodiments of the present invention. In an exemplary implementation, the display substrate according to the present disclosure may be applied to a display apparatus with a pixel drive circuit, such as an OLED, a quantum dot display (QLED), a light emitting diode display (Micro LED or Mini LED), or a Quantum Dot Light Emitting Diode display (QDLED), which is not limited here in the present disclosure.

The drawings of the embodiments of the present disclosure only involve structures involved in the embodiments of the present disclosure, and other structures may refer to a general design.

For the sake of clarity, a thickness and size of a layer or a micro structure are enlarged in the accompanying drawings used for describing the embodiments of the present disclosure. It may be understood that when an element such as a layer, film, region, or substrate is described as being “on” or “under” another element, the element may be “directly” located “on” or “under” the another element, or there may be an intermediate element.

Although the implementations of the present disclosure are disclosed above, the contents are only implementations used for ease of understanding of the present disclosure, but not intended to limit the present disclosure. Any of those skilled in the art of the present disclosure can make any modifications and variations in the implementation and details without departing from the spirit and scope of the present disclosure. However, the protection scope of the present disclosure should be subject to the scope defined by the appended claims.

1. A display substrate, comprising: a first region and a second region, wherein the first region is provided with pixel drive circuits arranged in an array, the second region is provided with a gate drive circuit configured to provide a drive signal to the pixel drive circuits, the gate drive circuit comprises: a plurality of shift registers, at least one stage of shift register comprises: a pre-circuit and a drive output circuit, the pre-circuit is electrically connected to a signal input terminal, a reset signal terminal and a cascaded output signal terminal respectively, the drive output circuit is electrically connected to N drive signal output terminals respectively, a signal input terminal of at least one stage of shift register is electrically connected to a cascaded output signal terminal of at least one stage of shift register, a reset signal terminal of at least one stage of shift register is electrically connected to a cascaded output signal terminal of at least one stage of shift register,
the drive output circuit comprises: N drive output sub-circuits, an n-th drive output sub-circuit is electrically connected to an n-th drive signal output terminal, in at least one display frame, a start time of a drive signal output from an N-th drive signal output terminal is later than a start time of a drive signal output from at least one of a first drive signal output terminal to an (N−1)-th drive signal output terminal, N>2, 1≤n≤N; and
an area of an N-th drive output sub-circuit is larger than an area of at least one of a first drive output sub-circuit to an (N−1)-th drive output sub-circuit.

2. The display substrate according to claim 1, comprising: a base substrate and a drive structure layer arranged on the base substrate, the gate drive circuit and the pixel drive circuits are located on the drive structure layer, the drive structure layer comprises: a semiconductor layer, a first conductive layer and a second conductive layer stacked sequentially on the base substrate, at least one drive output sub-circuit comprises: an output transistor, a noise reduction transistor and an output capacitor, a transistor comprises: an active pattern, a gate electrode, a first electrode and a second electrode, and the output capacitor comprises: a first plate and a second plate;
the semiconductor layer at least comprises: an active pattern of an output transistor and an active pattern of a noise reduction transistor located on at least one drive output sub-circuit;
the first conductive layer at least comprises: a second plate of an output capacitor located on at least one drive output sub-circuit; and
the second conductive layer at least comprises: a first plate of an output capacitor, a gate electrode, a first electrode and a second electrode of an output transistor, and a gate electrode, a first electrode and a second electrode of a noise reduction transistor located on at least one drive output sub-circuit.

3. The display substrate according to claim 2, wherein an area of an output transistor in the N-th drive output sub-circuit is larger than an area of an output transistor in at least one of the first drive output sub-circuit to an (N−1)-th drive output sub-circuit, and an area of an output capacitor in the N-th drive output sub-circuit is equal to an area of an output capacitor in at least one of the first drive output sub-circuit to the (N−1)-th drive output sub-circuit; or
wherein a width-to-length ratio of a channel region of an active pattern of the output transistor in the N-th drive output sub-circuit is greater than a width-to-length ratio of a channel region of an active pattern of an output transistor in at least one of the first drive output sub-circuit to the (N−1)-th drive output sub-circuit; or
wherein the first region is provided with at least one first signal line and at least one second signal line, the pixel drive circuit is electrically connected to the at least one first signal line and the at least one second signal line, the at least one first signal line at least partially extends in the first direction, and the at least one second signal line at least partially extends in the second direction;
the first signal line at least comprises: a scan signal line, the second signal line at least comprises: a first power supply line, a sensing signal line and a data signal line, and at least one drive output sub-circuit in the shift register is electrically connected to the at least one first signal line; and
the at least one first signal line is located on the first conductive layer, and the at least one second signal line is located on the second conductive layer.

4. (canceled)

5. The display substrate according to claim 3, wherein a width-to-length ratio of a channel region of an active pattern of an output transistor in the first drive output sub-circuit is greater than a width-to-length ratio of a channel region of an active pattern of an output transistor in at least one of a second drive output sub-circuit to the (N−1)-th drive output sub-circuit; or
wherein width-to-length ratios of channel regions of active patterns of output transistors in at least two of the second drive output sub-circuit to the (N−1)-th drive output sub-circuit are equal; or
wherein N=4, an output device in the first drive output sub-circuit is arranged symmetrically with an output device in the second drive output sub-circuit with respect to the second centerline, the output device in the second drive output sub-circuit is arranged symmetrically with an output device in a third drive output sub-circuit with respect to the first centerline, an output capacitor in a fourth drive output sub-circuit is arranged symmetrically with an output capacitor in the third drive output sub-circuit with respect to the second centerline, at least a portion of an output transistor in the fourth drive output sub-circuit is arranged symmetrically with an output transistor in the third drive output sub-circuit with respect to the second centerline, the output capacitor in the fourth drive output sub-circuit is arranged symmetrically with an output capacitor in the first drive output sub-circuit with respect to the first centerline, at least a portion of the output transistor in the fourth drive output sub-circuit is arranged symmetrically with the output transistor in the first drive output sub-circuit with respect to the first centerline, the output device comprises: an output transistor and an output capacitor, the first centerline is a centerline of an area occupied by the drive output circuit extending in a first direction, and the second centerline is a centerline of the area occupied by the drive output circuit extending in a second direction;
a noise reduction transistor of the first drive output sub-circuit and a noise reduction transistor of the second drive output sub-circuit are located on a side of the output device of the first drive output sub-circuit close to the first centerline, the noise reduction transistor of the second drive output sub-circuit is located on a side of the noise reduction transistor of the first drive output sub-circuit close to the first centerline, a noise reduction transistor of the third drive output sub-circuit and a noise reduction transistor of the fourth drive output sub-circuit are located on a side of the output device of the third drive output sub-circuit close to the first centerline, and the noise reduction transistor of the third drive output sub-circuit is located on a side of the noise reduction transistor of the fourth drive output sub-circuit close to the first centerline; and
the noise reduction transistor of the first drive output sub-circuit is arranged asymmetrically with the noise reduction transistor of the fourth drive output sub-circuit with respect to the first centerline, and the noise reduction transistor of the second drive output sub-circuit is arranged asymmetrically with the noise reduction transistor of the third drive output sub-circuit with respect to the first centerline.

6. (canceled)

7. The display substrate according to claim 2, wherein the area of the output capacitor in the N-th drive output sub-circuit is larger than the area of the output capacitor in at least one of the first drive output sub-circuit to the (N−1)-th drive output sub-circuit, and the area of the output transistor in the N-th drive output sub-circuit is equal to the area of the output transistor in at least one of the first drive output sub-circuit to the (N−1)-th drive output sub-circuit; or
wherein in at least one drive output sub-circuit, at least a portion of the gate electrode of the output transistor is of an annular structure, at least a portion of the first electrode of the output transistor is of an annular structure, the gate electrode of the output transistor surrounds the first electrode of the output transistor, and the second electrode of the output transistor surrounds at least one side of the gate electrode of the output transistor;
wherein in at least one drive output sub-circuit, the output capacitor is located on a side of the output transistor close to a second centerline, the noise reduction transistor is located on a side of the output transistor close to a first centerline, the first centerline is a centerline of an area occupied by the drive output circuit extending in a first direction, and the second centerline is a centerline of the area occupied by the drive output circuit extending in a second direction.

8-10. (canceled)

11. The display substrate according to claim 5, wherein a region where the drive output circuit is located is divided into a first region and a second region by the second centerline;
the output device of the first drive output sub-circuit and the output device of the fourth drive output sub-circuit are located in the first region, and the output device of the second drive output sub-circuit and the output device of the third drive output sub-circuit are located in the second region;
the noise reduction transistor of at least one of the first drive output sub-circuit to the fourth drive output sub-circuit is located in the first region and the second region, and an area of the noise reduction transistor in the first region is smaller than an area of the noise reduction transistor in the second region; and
areas of the noise reduction transistors of the first drive output sub-circuit and the second drive output sub-circuit in the first region are larger than areas of the noise reduction transistors of the third drive output sub-circuit and the fourth drive output sub-circuit in the first region, and areas of the noise reduction transistors of the first drive output sub-circuit and the second drive output sub-circuit in the second region are smaller than areas of the noise reduction transistors of the third drive output sub-circuit and the fourth drive output sub-circuit in the second region;
or,
wherein the first electrode of the output transistor of the fourth drive output sub-circuit comprises: a first electrode portion and a second electrode portion arranged at intervals;
the first electrode portion of the output transistor of the fourth drive output sub-circuit is arranged symmetrically with the first electrode of the output transistor of the first drive output sub-circuit with respect to the first centerline, and the first electrode portion of the output transistor of the fourth drive output sub-circuit is arranged symmetrically with the first electrode of the output transistor of the third drive output sub-circuit;
the first electrode portion and the second electrode portion comprise: a closed loop structure, an orthographic projection of the first electrode portion on the base substrate at least partially overlaps with orthographic projections of the first active portion and the second active pattern on the base substrate, and an orthographic projection of the second electrode portion on the base substrate at least partially overlaps with an orthographic projection of the second active portion on the base substrate; and
an area of the first electrode portion is larger than an area of the second electrode portion;
or,
wherein a virtual straight line extending in the first direction through the noise reduction transistor of the fourth drive output sub-circuit passes through the output transistor of the fourth drive output sub-circuit;
or,
wherein the second region further comprises: output connection lines, the output connection lines comprise: a first output connection line to a fourth output connection line; the first drive output sub-circuit is connected to the first output connection line, the second drive output sub-circuit is connected to the second output connection line, the third drive output sub-circuit is connected to the third output connection line, and the fourth drive output sub-circuit is connected to the fourth output connection line;
the first output connection line and the second output connection line are located between the output transistor of the first drive output sub-circuit and the noise reduction transistor of the first drive output sub-circuit, and the third output connection line and the fourth output connection line are located between the output transistor of the fourth drive output sub-circuit and the noise reduction transistor of the fourth drive output sub-circuit; and
the first output connection line and the second output connection line extend in the first direction, the third output connection line and the fourth output connection line are in a shape of a bend line and at least partially extend in the first direction, and the output connection lines are located on the second conductive layer.

12. (canceled)

13. The display substrate according to claim 11, wherein the first electrode of the output transistor of the fourth drive output sub-circuit comprises: a first electrode portion and a second electrode portion arranged at intervals;
the first electrode portion of the output transistor of the fourth drive output sub-circuit is arranged symmetrically with the first electrode of the output transistor of the first drive output sub-circuit with respect to the first centerline, and the first electrode portion of the output transistor of the fourth drive output sub-circuit is arranged symmetrically with the first electrode of the output transistor of the third drive output sub-circuit;
the first electrode portion and the second electrode portion comprise: a closed loop structure, an orthographic projection of the first electrode portion on the base substrate at least partially overlaps with orthographic projections of the first active portion and the second active pattern on the base substrate, and an orthographic projection of the second electrode portion on the base substrate at least partially overlaps with an orthographic projection of the second active portion on the base substrate; and
an area of the first electrode portion is larger than an area of the second electrode portion.

14. The display substrate according to claim 13, wherein the gate electrode of the output transistor of the fourth drive output sub-circuit comprises: a first gate electrode portion and a second gate electrode portion connected to each other;
the first gate electrode portion of the gate electrode of the output transistor of the fourth drive output sub-circuit is arranged symmetrically with the gate electrode of the output transistor of the first drive output sub-circuit with respect to the first centerline, and the first gate electrode portion of the gate electrode of the output transistor of the fourth drive output sub-circuit is arranged symmetrically with the gate electrode of the output transistor of the third drive output sub-circuit with respect to the second centerline;
the first gate electrode portion and the second gate electrode portion comprise: a closed loop structure, an orthographic projection of the first gate electrode portion on the base substrate at least partially overlaps with orthographic projections of the first active portion and the second active pattern on the base substrate, and an orthographic projection of the second gate electrode portion on the base substrate at least partially overlaps with an orthographic projection of the second active portion on the base substrate; and the first gate electrode portion surrounds the first electrode portion, and the second gate electrode portion surrounds the second electrode portion; and
an area of the first gate electrode portion is larger than an area of the second gate electrode portion.

15-16. (canceled)

17. The display substrate according to claim 11, wherein at least one of the third output connection line and the fourth output connection line comprises: a first output connection portion, a second output connection portion and a third output connection portion; the first output connection portion and the third output connection portion extend in the first direction, the second output connection portion extends in the second direction, and the second output connection portion is electrically connected to the first output connection portion and the third output connection portion respectively.

18. The display substrate according to claim 7, wherein N=4, the first drive output sub-circuit to the third drive output sub-circuit comprise: one output capacitor, and the fourth drive output sub-circuit comprises: two output capacitors;
the output device in the first drive output sub-circuit is arranged symmetrically with the output device in the second drive output sub-circuit with respect to the second centerline, the output device in the second drive output sub-circuit is arranged symmetrically the output device in the third drive output sub-circuit with respect to the first centerline, the output device in the fourth drive output sub-circuit is arranged symmetrically with the output device in the third drive output sub-circuit with respect to the second centerline, the output device in the fourth drive output sub-circuit is arranged symmetrically with the output device in the first drive output sub-circuit with respect to the first centerline, the output devices in the first drive output sub-circuit to the third drive output sub-circuit comprise: output transistors and output capacitors, the output device in the fourth drive output sub-circuit comprises: an output transistor and one of the output capacitors, the first centerline is a centerline of an area occupied by the drive output circuit extending in the first direction, and the second centerline is a centerline of the area occupied by the drive output circuit extending in the second direction;
the noise reduction transistor of the first drive output sub-circuit and the noise reduction transistor of the second drive output sub-circuit are located on a side of the output device of the first drive output sub-circuit close to the first centerline, the noise reduction transistor of the second drive output sub-circuit is located on a side of the noise reduction transistor of the first drive output sub-circuit close to the first centerline, the noise reduction transistor of the third drive output sub-circuit and the noise reduction transistor of the fourth drive output sub-circuit are located on a side of the output device of the third drive output sub-circuit close to the first centerline, the noise reduction transistor of the third drive output sub-circuit is located on a side of the noise reduction transistor of the fourth drive output sub-circuit close to the first centerline, and the other output capacitor of the fourth drive output sub-circuit is located on a side of the output device of the fourth drive output sub-circuit close to the first centerline; and
the noise reduction transistor of the first drive output sub-circuit is arranged symmetrically with the noise reduction transistor of the fourth drive output sub-circuit with respect to the first centerline, and the noise reduction transistor of the second drive output sub-circuit is arranged symmetrically with the noise reduction transistor of the third drive output sub-circuit with respect to the first centerline.

19. The display substrate according to claim 18, wherein a region where the drive output circuit is located is divided into a first region and a second region by the second centerline;
the output device of the first drive output sub-circuit and the output device and the other output capacitor of the fourth drive output sub-circuit are located in the first region, and the output device of the second drive output sub-circuit and the output device of the third drive output sub-circuit are located in the second region; and
the noise reduction transistor of at least one of the first drive output sub-circuit to the fourth drive output sub-circuit is located in the first region and the second region, and an area of the noise reduction transistor in the first region is smaller than an area of the noise reduction transistor in the second region;
or,
wherein the second region further comprises: output connection lines, the output connection lines comprise: a first output connection line to a fourth output connection line; the first drive output sub-circuit is connected to the first output connection line, the second drive output sub-circuit is connected to the second output connection line, the third drive output sub-circuit is connected to the third output connection line, and the fourth drive output sub-circuit is connected to the fourth output connection line;
the output connection lines extend in the first direction, the first output connection line and the second output connection line are located between the output device of the first drive output sub-circuit and the noise reduction transistor of the first drive output sub-circuit, the third output connection line and the fourth output connection line are located between the output device of the fourth drive output sub-circuit and the noise reduction transistor of the fourth drive output sub-circuit, and the other output capacitor and the noise reduction transistor of the fourth drive output sub-circuit are located on a same side of the third output connection line and the fourth output connection line; and
the first output connection line and the second output connection line are located on the second conductive layer.

20. The display substrate according to claim 19, wherein the area of the noise reduction transistor in the second region is within a range of 1 to 3 times the area of the noise reduction transistor in the first region.

21. (canceled)

22. The display substrate according to claim 19, wherein at least one of the third output connection line and the fourth output connection line comprises: a first output connection portion, a second output connection portion and a third output connection portion; the first output connection portion, the second output connection portion and the third output connection portion extend in the first direction, and the second output connection portion is electrically connected to the first output connection portion and the third output connection portion respectively; and
the first output connection portion and the third output connection portion are located on the second conductive layer, and the second output connection portion is located on the first conductive layer.

23. (canceled)

24. The display substrate according to claim 3, wherein the at least one first signal line comprises: a plurality of signal connection lines and a plurality of signal overlapping lines; the plurality of signal connection lines and the plurality of signal overlapping lines are arranged alternately in the first direction;
the signal connection lines are arranged in the first direction, and an orthographic projection of a signal overlapping line on the base substrate at least partially overlaps with an orthographic projection of at least one second signal line on the base substrate; and
a line width of a signal connection line of a first signal line connected to at least one of the first drive output sub-circuit to the (N−1)-th drive output sub-circuit in at least one stage of shift register is smaller than a line width of a signal connection line of a first signal line connected to the N-th drive output sub-circuit.

25. The display substrate according to claim 24, wherein for at least one stage of shift register, the line width of the signal connection line of the first signal line connected to the N-th drive output sub-circuit is within a range of 1.5 to 2 times the line width of the signal connection line of the first signal line connected to at least one of the first drive output sub-circuit to the (N−1)-th drive output sub-circuit;
or,
wherein for at least one stage of shift register, the signal overlapping lines of the first signal line connected to the first drive output sub-circuit to the N-th drive output sub-circuit are of an annular structure; and
for at least one first signal line, a length of a signal overlapping line in the first direction is greater than a line width of the at least one second signal line, and the length of the signal overlapping line in the second direction is greater than the line width of the signal connection line;
or,
wherein for at least one stage of shift register, signal overlapping lines of the first signal line connected to at least one of the first drive output sub-circuit to the (N−1)-th drive output sub-circuit are of an annular structure;
for first signal lines connected to the first drive output sub-circuit to the (N−1)-th drive output sub-circuit, a length of a signal overlapping line in the first direction is greater than the line width of the at least one second signal line, and a length of a signal overlapping line in the second direction is greater than a line width of the signal connection line; and
signal overlapping lines of the first signal line connected to the N-th drive output sub-circuit extend in the first direction, and at least one boundary is arc-shaped, and an average line width of the signal overlapping lines of the first signal line connected to the N-th drive output sub-circuit is smaller than the line width of the signal connection line of the first signal line connected to the N-th drive output sub-circuit;
or,
wherein the second region further comprises: a data unit, the data unit is electrically connected to output clock signal lines connected to N drive output sub-circuits of the at least one stage of shift register and configured to provide a first clock signal to output clock signal lines connected to a second drive output sub-circuit to an (N−1)-th drive output sub-circuit of the at least one stage of shift register, and to provide a second clock signal to an output clock signal line connected to an N-th drive output sub-circuit of the at least one stage of shift register, the first clock signal comprises: a first rising edge and a first falling edge, and the second clock signal comprises: a second rising edge, a third rising edge and a second falling edge;
in a time period where the first rising edge is located, a voltage of the first clock signal rises from a second voltage to a first voltage, and in a time period where the first falling edge is located, the voltage of the first clock signal falls from the first voltage to the second voltage;
in a time period where the second rising edge is located, a voltage of the second clock signal rises from a third voltage to the second voltage, in a time period where the third rising edge is located, the voltage of the second clock signal rises from the second voltage to the first voltage, and in a time period where the second falling edge is located, the voltage of the second clock signal falls from the first voltage to the third voltage; and
the first voltage is a positive voltage, the second voltage and the third voltage are negative voltages, and an absolute value of the second voltage is smaller than an absolute value of the third voltage.

26-27. (canceled)

28. A display substrate, comprising: a first region and a second region, wherein the first region is provided with pixel drive circuits arranged in an array, the second region is provided with a gate drive circuit configured to provide a drive signal to the pixel drive circuits, the gate drive circuit comprises: a plurality of shift registers, at least one stage of shift register comprises: a pre-circuit and a drive output circuit, the pre-circuit is electrically connected to a signal input terminal, a reset signal terminal and a cascaded output signal terminal respectively, the drive output circuit is electrically connected to N output clock signal terminals respectively, a signal input terminal of at least one stage of shift register is electrically connected to a cascaded output signal terminal of at least one stage of shift register, a reset signal terminal of at least one stage of shift register is electrically connected to a cascaded output signal terminal of at least one stage of shift register,
the drive output circuit comprises: N drive output sub-circuits, an n-th drive output sub-circuit is electrically connected to an n-th output clock signal terminal;
the second region is provided with M*N output clock signal lines, at least one output clock signal line at least partially extends in a second direction and is located on a side of the drive output circuit away from the first region, and a first output clock signal terminal to an N-th output clock signal terminal of the at least one stage of shift register are electrically connected to N output clock signal lines respectively, M≥2; and
for the at least one stage of shift register, a line width of an output clock signal line connected to the N-th output clock signal terminal is larger than a line width of an output clock signal line connected to at least one of the first output clock signal terminal to an (N−1)-th output clock signal terminal.

29. The display substrate according to claim 28, further comprising:
a base substrate and a drive structure layer arranged on the base substrate, wherein the gate drive circuit and the pixel drive circuit are located on the drive structure layer, the drive structure layer comprises: a semiconductor layer, a first conductive layer and a second conductive layer stacked sequentially on the base substrate; and
the output clock signal lines are located on the second conductive layer;
or,
wherein an n-th output clock signal terminal of the at least one stage of shift register is electrically connected to one of an n-th output clock signal line, and an (N+n)-th output clock signal line to an (M−1)*N+n-th output clock signal line; and
n-th output clock signal terminals of adjacent M stages of shift registers are connected to different output clock signal lines;
or,
wherein at least one output clock signal line is provided with a via;
a length in the first direction of a via in an output clock signal line connected to at least one of a first output clock signal terminal to an (N−1)-th output clock signal terminal of the at least one stage of shift register is smaller than a length in the first direction of a via in an output clock signal line connected to the N-th output clock signal terminal of the at least one stage of shift register; and
a via correlation distance of an output clock signal line connected to at least one of the first output clock signal terminal to the (N−1)-th output clock signal terminal of the at least one stage of shift register is equal to a via correlation distance of an output clock signal line connected to the N-th output clock signal terminal of the at least one stage of shift register, wherein the via correlation distance is a distance between a boundary of an output clock signal line and a boundary of a via of the output clock signal line;
or,
wherein the second region further comprises: a data unit, the data unit is electrically connected to output clock signal lines connected to N drive output sub-circuits of the at least one stage of shift register and configured to provide a fourth clock signal to output clock signal lines connected to a second drive output sub-circuit to an (N−1)-th drive output sub-circuit of the at least one stage of shift register, and to provide a fifth clock signal to an output clock signal line connected to an N-th drive output sub-circuit of the at least one stage of shift register; and
a duration of a time period where a falling edge of the fifth clock signal is located is smaller than a half of a duration of a time period where a falling edge of the fourth clock signal is located.

30-31. (canceled)

32. The display substrate according to claim 29, wherein the second region further comprises: a plurality of clock connection lines, the clock connection line comprise: a first clock connection line to an N-th clock connection line, the clock connection lines are located on the first conductive layer; and
the at least one stage of shift register is electrically connected to a connected n-th output clock signal line through an n-th clock connection line, and an orthographic projection of at least one clock connection line on the base substrate at least partially overlaps with an orthographic projection of a via of at least one output clock signal line on the base substrate; or
wherein the data unit is further configured to provide a third clock signal to an output clock signal line connected to a first drive output sub-circuit of the at least one stage of shift register, the third clock signal comprises: a fourth rising edge, a third falling edge and a fourth falling edge;
in a time period where the fourth rising edge is located, a voltage of the third clock signal rises from the second voltage to a fourth voltage, in a time period where the third falling edge is located, the voltage of the third clock signal falls from the fourth voltage to the first voltage. and in a time period where the fourth falling edge is located, the voltage of the third clock signal falls from the first voltage to the second voltage; and
the first voltage and the fourth voltage are positive voltages, the second voltage is a negative voltage, and the fourth voltage is greater than the first voltage.

33-35. (canceled)

36. The display substrate according to claim 29, wherein the data unit is further configured to provide a sixth clock signal to an output clock signal line connected to a first drive output sub-circuit of at least one stage of shift register; and
a duration of a time period where a rising edge of the sixth clock signal is located is smaller than a half of a duration of a time period where a rising edge of the fourth clock signal is located.

37. A display apparatus, comprising the display substrate according to claim 1.
